(19) United States
(12) Patent Application Publication
(10) Pub. No.: US 2014/0034360 A1
(43) Pub. Date: Feb. 6, 2014

(54) CONDUCTIVE MEMBER, PRODUCTION METHOD OF THE SAME, TOUCH PANEL, AND SOLAR CELL

(71) Applicant: FUJIFILM Corporation, Tokyo (JP)

(72) Inventors: Satoshi TANAKA, Ashigarakami-gun (JP); Kenji NAOI, Ashigarakami-gun (JP); Shinichi NAKAHIRA, Ashigarakami-gun (JP); Kenichi YAMAMOTO, Ashigarakami-gun (JP)

(73) Assignee: FUJIFILM Corporation, Tokyo (JP)

(21) Appl. No.: 14/049,379

(22) Filed: Oct. 9, 2013

Related U.S. Application Data
(63) Continuation of application No. PCT/JP2012/059266, filed on Apr. 4, 2012.

(30) Foreign Application Priority Data
Apr. 14, 2011 (JP) 2011-090346
Nov. 30, 2011 (JP) 2011-263073
Mar. 23, 2012 (JP) 2012-068214

(51) Int. Cl. H05K 1/02; H05K 3/10

(52) U.S. Cl. CPC H05K 1/02; H05K 1/0201; H05K 1/0283; H05K 3/10
USPC 174/251; 427/96.2

(57) ABSTRACT

A conductive member containing: a base material; a conductive layer provided on the base material, wherein the conductive layer includes a metallic nanowire having an average short axis length of 150 nm or less and a matrix; and a protective layer including a three-dimensional crosslinked structure represented by the following Formula (I), sequentially in this order, and which has a surface resistivity measured at a surface of the protective layer of 1,000 Ω/□ or less, a production method of the conductive member, and a touch panel and a solar cell, each of which uses the conductive member. The conductive member may provide high resistance against scratches and abrasion, excellent conductivity, excellent transparency, excellent heat resistance, excellent moisture and heat resistance, and excellent bendability.

-M¹-O-M¹- Formula (I):

In the Formula (I), M¹ represents an element selected from the group consisting of Si, Ti Zr and Al.

### CROSS-REFERENCE TO RELATED APPLICATION

This application is a continuation application of, and claims priority to, International Application No. PCT/JP/2012/059266, filed Apr. 4, 2012, which is incorporated herein by reference. Further, this application claims priority from Japanese Patent Application Nos. 2011-090346, filed Apr. 14, 2011, 2011-263073, filed Nov. 30, 2011, and 2012-068214, filed Mar. 23, 2012, which are incorporated herein by reference.

### BACKGROUND OF THE INVENTION

1. Technical Field

The present invention relates to a conductive member, a production method of the conductive member, a touch panel and a solar cell.

2. Background Art

Recently, a conductive member having a conductive layer including conductive fibers such as metallic nanowires has been proposed (for example, refer to Japanese Patent National Phase Publication No. 2009-505358). This conductive member has a conductive layer including plural metallic nanowires on a substrate. The conductive member can be easily processed into a conductive member having a conductive layer including a desired conductive area and a desired non-conductive area by, for example, containing a photocurable composition as a matrix in the conductive layer and carrying out pattern exposure and subsequent development. The conductive member processed as above can be used in, for example, touch panels or electrodes in solar cells.

The aforementioned conductive layer in the conducive member has weak film strength. Therefore, it has been also proposed to provide a hard coat on a surface of the conductive layer and use the conductive layer as a protective layer that reduces scratches and abrasion. In addition, examples of the hard coat include films of a synthetic polymer such as polyacrylic acid, epoxy, polyurethane, polysilane, silicone or poly(silicon-acryl) (for example, refer to paragraph 0071 in JP-A No. 2009-505358).

Furthermore, it has been proposed to provide a light absorption layer on the conductive layer in order to improve haze of the conductive layer containing metallic nanowires and a matrix of a photocurable acrylic resin cured by UV radiation. In addition, specific examples of the light absorption layer for which a photocurable acrylic resin cured by UV radiation is used as the matrix are listed (for example, refer to Example 1 in Japanese Patent Application Laid-Open (JP-A) No. 2011-29036).

However, when an attempt was made to reduce scratches and abrasion in the conductive layer by providing the hard coat, it was necessary to provide the hard coat as thick as approximately from 1 μm to 50 μm, and there was a problem in that the conduction decreased. On the other hand, in a case in which a hard coat thin enough to allow only a slight decrease in the conduction is provided, the hard coat could not sufficiently prevent scratches and abrasion in the conductive layer.

Furthermore, even in conductive members provided with a protective layer including a photocurable acrylic resin cured by UV on the surface of the conductive layer, scratches and abrasion in the conductive layer could not be sufficiently prevented, and, furthermore, the protective layer was not satisfactory in terms of heat resistance, moisture and heat resistance, and bendability.

As such, in conductive members having a conductive layer including a conductive fiber, it was difficult to reduce scratches and abrasion in the conductive layer and maintain a high conduction at the same time, and there was a demand for conductive members that satisfy both requirements.

### SUMMARY OF INVENTION

According to the invention, a conductive member which has a conductive layer including metallic nanowires with an average short axis length of 150 nm or less and a matrix, and a protective layer including a three-dimensional crosslinked structure represented by the following Formula (I) in this order on a base material, has a surface resistivity measured on the protective layer of 1,000Ω/□ or less, has high resistance against scratches and abrasion, is excellent in terms of conduction, and is excellent in terms of transparency, heat resistance, moisture and heat resistance and bendability; a production method of the conductive member; and a touch panel and a solar cell, each of which uses the conductive member, are provided.

-M¹-O-M¹- Formula (I):

(In the Formula (I), M¹ represents an element selected from a group consisting of Si, Ti, Zr and Al.)

### Technical Problem

The problem to be solved in the invention is to provide a conductive member exhibiting high resistance against scratches and abrasion, excellent conduction, excellent transparency, excellent heat resistance, excellent moisture and heat resistance and excellent bendability; a production method of the conductive member; and a touch panel and a solar cell each using the same.

### Solution to Problem

Exemplary embodiments of the present invention include the following.

<1> A conductive member including: a base material; a conductive layer provided on the base material, the conductive layer including a metallic nanowire having an average short-axis length of 150 nm or less and a matrix; and a protective layer including a three-dimensional crosslinked structure represented by the following Formula (I) sequentially in this order, and a surface resistivity of the conductive member measured at a surface of the protective layer being 1,000 Ω/□ or less,

-M¹-O-M¹- Formula (I):
wherein, in Formula (I), M′ represents an element selected from the group consisting of Si, Ti, Zr and Al.
   <2> The conductive member according to the item <1>, wherein the matrix is a cured product of a photopolymerizable composition or a sol-gel cured product obtained by hydrolysis and condensation of at least one alkoxide compound of an element selected from the group consisting of Si, Ti, Zr and Al.
   <3> The conductive member according to the item <1> or the item <2>, wherein the protective layer includes a sol-gel cured product obtained by hydrolysis and condensation of at least one alkoxide compound of an element selected from the group consisting of Si, Ti, Zr and Al.
   <4> The conductive member according to the item <3>, wherein the alkoxide compound in the protective layer includes at least one selected from the group consisting of a compound represented by the following Formula (II) and a compound represented by the following Formula (III),

M²(OR¹)₄ Formula (II):

M³(OR²)ₐR³₄₋ₐ Formula (III):

wherein, in Formula (II), M² represents an element selected from the group consisting of Si, Ti and Zr, and each of a plurality of R¹ independently represents a hydrogen atom or a hydrocarbon group, and in Formula (III), M³ represents an element selected from the group consisting of Si, Ti and Zr, and each of a plurality of R² and each of a plurality of R³ independently represents a hydrogen atom or a hydrocarbon group, and “a” represents an integer from 1 to 3.

<5> The conductive member according to the item <4>, wherein the alkoxide compound in the protective layer includes (i) at least one of the compound represented by Formula (II), and (ii) at least one of the compound represented by Formula (III).
<6> The conductive member according to the item <5>, wherein a mass ratio of the compound (ii) to the compound (i) (the compound (ii)/the compound (i)) is in a range of from 0.01/1 to 100/1.
<7> The conductive member according to any one of the items <4> to <6>, wherein both of M² in Formula (II) and M³ in Formula (III) are Si.
<8> The conductive member according to any one of the items <1> to <7>, wherein the metallic nanowire is a silver nanowire.
<9> The conductive member according to any one of the items <1> to <8>, wherein the surface resistivity of the conductive member after immersion for 120 seconds in an etching liquid having the following composition at a temperature of 25° C. is 10⁸Ω/□ or more, a percentage of a delta haze value, that is provided by subtraction of a haze value after the immersion from a haze value before the immersion, with respect to the haze value before the immersion is 0.4% or more, and the protective layer is not removed after the immersion,

etching liquid composition:

| | | |
|---|---|---|
| an ethylenediamine tetra acetic acid salt of iron | 2.5% | by mass |
| and ammonium | | |
| ammonium thiosulfate | 7.5% | by mass |
| ammonium sulfite | 2.5% | by mass |
| ammonium bisulfite | 2.5% | by mass |
| and water | 85% | by mass. |

<10> The conductive member according to any one of the items <1> to <9>, wherein the conductive layer includes a conductive region and a nonconductive region, and at least the conductive region includes the metallic nanowire.
<11> The conductive member according to any one of the items <1> to <10>, wherein a ratio of a surface resistivity of the conductive layer (Ω/□) after an abrasion treatment to a surface resistivity of the conductive layer (Ω/□) before an abrasion treatment is 100 or less, the abrasion treatment being performed with a continuous loading scratching intensity tester in a round trip of 50 times on the surface of the protective layer by using a 20 mm×20 mm-sized gauze piece with a load of 500 g thereon.
<12> The conductive member according to any one of the items <1> to <11>, wherein a ratio of a surface resistivity (Ω/□) of the conductive layer after a bending treatment to a surface resistivity (Ω/□) of the conductive layer before a bending treatment is 2 or less, the bending treatment being performed with a cylindrical mandrel bending tester to wind the conductive member 20 times onto a cylindrical mandrel having a diameter of 10 mm.
<13> A production method of the conductive member according to the item <1>, the method including:

(a) forming, on the base material, the conductive layer including a metallic nanowire having an average short-axis length of 150 nm or less and a matrix; (b) forming, on the conductive layer, a liquid film of an aqueous solution by applying an aqueous solution including a partial condensate product obtained by hydrolysis and condensation of at least one alkoxide compound of an element selected from the group consisting of Si, Ti, Zr and Al; and (c) forming a protective layer including a three-dimensional crosslinked structure represented by Formula (I) obtained by hydrolysis and condensation of the alkoxide compound in the liquid film of the aqueous solution.

<14> The production method according to the item <13>, further including drying the protective layer by heating after the process of (c).
<15> The production method according to the item <13> or the item <14>, wherein the matrix is a cured product of a photopolymerizable composition or a sol-gel cured product obtained by hydrolysis and condensation of at least one alkoxide compound of an element selected from the group consisting of Si, Ti, Zr and Al.
<16> The production method according to any one of the items <13> to <15>, wherein the alkoxide compound in the process (b) includes at least one selected from the group consisting of a compound represented by the following Formula (II) and a compound represented by the following Formula (III),

M²(OR¹)₄ Formula (II):

M³(OR²)ₐR³₄₋ₐ Formula (III):

wherein, in Formula (II), M² represents an element selected from the group consisting of Si, Ti and Zr, and each of a plurality of R¹ independently represents a hydrogen atom or a hydrocarbon group, and, in Formula (III), M³ represents an element selected from the group consisting of Si, Ti and Zr, and each of a plurality of R² and each of a plurality of R³ independently represent a hydrogen atom or a hydrocarbon group, and “a” represents an integer from 1 to 3.

<17> The production method according to the item <16>, wherein the alkoxide compound in the process (b) comprises (i) at least one selected from the compound represented by Formula (II), and (ii) at least one selected from the compound represented by Formula (III).
<18> The production method according to the item <17>, wherein a mass ratio of the compound (ii) to the compound (i) (the compound (ii)/the compound (i)) is in a range of from 0.01/1 to 100/1.
<19> The production method according to any one of the items <16> to <18>, wherein both of M² in Formula (II) and M³ in Formula (III) are Si.
<20> The production method according to any one of the items <13> to <19>, wherein a weight average molecular weight of the partial condensate product is in a range of from 4,000 to 90,000.
<21> The production method according to any one of the items <13> to <20>, further including forming, in the conductive layer, a conductive region and a nonconductive region during the process (a) and the process (b).
<22> A touch panel including the conductive member according to any one of the items <1> to <12>.
<23> A solar cell including the conductive member according to any one of the items <1> to <12>.

### Advantageous Effects of Invention

According to the invention, a conductive member which has high resistance against scratches and abrasion, is excellent in terms of conduction, and is excellent in terms of transparency, heat resistance, moisture and heat resistance and bendability; a production method of the conductive member; and a touch panel and a solar cell, each of which uses the conductive member, are provided.

### DESCRIPTION OF EMBODIMENTS

Hereinafter, a conductive member of the invention will be described in detail.

Hereinafter, the invention will be described based on a representative embodiment of the invention, but the invention is not limited to the described embodiment within the scope of the purpose of the invention.

Meanwhile, in the present specification, numeric ranges expressed using “to” include numeric values described before and after “to” as the lower limit value and the upper limit value.

Conceptually, the word “light” or “photo” used in the specification includes not only visible light rays but also high-energy rays such as ultraviolet rays, X-rays and gamma rays, particle rays such as electron beams, and the like.

In the specification, “(meth)acrylic acid” represents either or both of acrylic acid and methacrylic acid, and “(meth)acrylate” represents either or both of acrylate and methacrylate.

In addition, the content will be expressed by mass unless particularly otherwise described, % by mass represents the proportion of a composition in a total amount unless particularly otherwise described, and “solid content” refers to components of a composition except for a solvent.

<<<Conductive Member>>>

The conductive member of the invention has a conductive layer including metallic nanowires with an average short axis length of 150 nm or less and a matrix, and a protective layer including a three-dimensional crosslinked structure represented by the following Formula (I) in the above order on a base material, and has a surface resistivity measured on the protective layer of 1,000Ω/□ or less.

-M¹-O-M¹- Formula (I):

(In the Formula (I), M′ represents an element selected from a group consisting of Si, Ti, Zr and Al.)

<<Base Material>>

As the base material, a variety of base materials can be used depending on the purpose as long as the base material can bear the conductive layer. Generally, a plate-like base material or a sheet-like base material is used.

The base material may be transparent or opaque. Examples of a material that forms the base material include transparent glass such as white plate glass, blue plate glass and silica-coated blue plate glass; synthesis resins such as polycarbonates, polyethersulfones, polyesters, acrylic resins, vinyl chloride resins, aromatic polyamide resins, polyamide-imides and polyimides; metal such as aluminum, copper, nickel and stainless steel; additionally, ceramics, silicon wafers used for semiconductor substrates, and the like. A surface of the base material on which the conductive layer is formed can be subjected to a pretreatment such as a chemical treatment using a silane coupling agent or the like, a plasma treatment, ion plating, sputtering, a gas-phase reaction or vacuum deposition as desired.

A base material with a thickness in a desired range depending on the use may be used. The thickness is generally selected from a range of from 1 μm to 500 μm, more preferably from 3 μm to 400 and still more preferably from 5 μm to 300 μm.

In a case in which a transparent conductive member is required, a conductive member including a base material having a total visible light transmittance of 70% or more, more preferably 85% or more, and still more preferably 90% or more is selected. Meanwhile, the total light transmittance of the base material is measured based on JIS K 7361-1:1997.

<<Conductive Layer>>

The conductive layer includes metallic nanowires with an average short axis length of 150 nm or less and a matrix.

Here, the “matrix” is a collective term for substances that include metallic nanowires and form a layer.

The matrix has a function of stably maintaining the dispersion of the metallic nanowires, and may or may not be photosensitive.

Photosensitive matrices have an advantage of easy formation of fine patterns using exposure, development and the like.

<Metallic Nanowires with an Average Short Axis Length of 150 Nm or Less>

The conductive layer in the invention contains metallic nanowires with an average short axis length of 150 nm or less. The metal nanowire preferably has a solid structure.

From a viewpoint of easy formation of transparent conductive layers, the metallic nanowires preferably have an average short axis length of from 1 nm to 150 nm and an average long axis length of from 1 μm to 100 μm.

The average short axis length (average diameter) of the metallic nanowires is preferably 100 nm or less, more preferably 60 nm or less, still more preferably 50 nm or less, and particularly preferably 25 nm or less. In addition, from the viewpoint of oxidation resistance and climate resistance, the average short axis length of the metallic nanowires is preferably 1 nm or more, still more preferably 10 nm or more, and particularly preferably 15 nm or more. When the average short axis length is set to 1 nm or more, conductive members having favorable oxidation resistance and excellent climate resistance can be easily obtained. The average short axis length is preferably 5 μm or more. When the average short axis length exceeds 150 nm, there is a concern that conduction may decrease and optical characteristics may deteriorate due to light scattering and the like, which is not preferable.

The average long axis length of the metallic nanowires is preferably 1 μm to 40 μm, more preferably 3 μm to 35 μm, and still more preferably 5 μm to 30 μm. When the average long axis length of the metallic nanowires is 40 μm or less, it becomes easy to synthesize the metallic nanowires without agglomerates being generated. In addition, when the average long axis length is 1 μm or more, it becomes easy to obtain a sufficient conduction.

Here, the average short axis length (average diameter) and average long axis length of the metallic nanowires can be obtained by, for example, observing TEM images or optical microscopic images using a transmission electron microscope (TEM) or an optical microscope. Specifically, the average short axis length (average diameter) and average long axis length of the metallic nanowires can be obtained by measuring the short axis lengths and long axis lengths of 300 randomly-selected metallic nanowires using a transmission electron microscope (TEM; JEM-2000FX manufactured by JELO Ltd.) and computing the average values. Meanwhile, in a case in which the cross-section of the metallic nanowire in the short axis direction was not round, the length of the longest place in a measurement in the short axis direction was used as the short axis length. In addition, in a case in which the metallic nanowire was curved, a circle having the curve as an arc was considered, and the length of a circular arc computed from the radius and curvature of the circle was used as the long axis length.

In the invention, the proportion of the metallic nanowires having a short axis length (diameter) of 150 nm or less and a long axis length of from 5 μm to 500 μm in all of the metallic nanowires is preferably 50% by mass or more, more preferably 60% by mass, and still more preferably 75% by mass or more in terms of the amount of metal.

When the proportion of the metallic nanowires having a short axis length (diameter) of 150 nm or less and a long axis length of from 5 μm to 500 μm is 50% by mass or more, a sufficient conduction is obtained, voltage concentration is not easily caused, and the degradation of durability caused by voltage concentration can be suppressed, which is preferable. When non-fibrous conductive particles are included in the conductive layer, there is a concern that transparency decreases in a case in which plasmon absorption is strong.

A coefficient of variation of the short axis length (diameter) of the metallic nanowires used in the conductive layer in the invention is preferably 40% or less, more preferably 35% or less, and still more preferably 30% or less.

When the coefficient of variation exceeds 40%, there are cases in which durability deteriorates probably because voltage concentrates in wires with a small short axis length (diameter).

The coefficient of variation of the short axis length (diameter) of the metallic nanowires can be obtained by, for example, measuring the short axis lengths (diameters) of 300 nanowires on a transmission electron microscopic (TEM) image, and computing the standard deviation and average value.

(Aspect Ratio of the Metallic Nanowires)

An aspect ratio of the metallic nanowires that can be used in the invention is preferably 10 or more. Here, the aspect ratio refers to a ratio of the average long axis length to the average short axis length. The aspect ratio can be computed using the average long axis length and the average short axis length computed using the above method.

The aspect ratio of the metallic nanowires is not particularly limited as long as the aspect ratio is 10 or more, and can be appropriately selected depending on the purpose, but is preferably from 50 to 100,000, and more preferably from 100 to 100,000.

When the aspect ratio is set to 10 or more, a network in which the metal nanowires are in contact with each other is easily formed, and a conductive layer having a high conduction can be easily obtained. In addition, when the aspect ratio is set to 100,000 or less, for example, it is possible to obtain a coating liquid used when providing the conductive layer on the base material through coating which is quite stable that there is no concern that the metallic nanowires may tangle and agglomerate, and therefore it becomes easy to produce the conductive layer.

A content rate of the metallic nanowires having an aspect ratio of 10 or more included in the metallic nanowires is not particularly limited, but is preferably, for example, 70% by mass or more, more preferably 75% by mass or more, and even more preferably 80% by mass or more.

A shape of the metallic nanowire can be any shape such as a cylindrical shape, a cuboid shape or a columnar shape having a polygonal cross-section, but metallic nanowires having a cross-sectional shape that is a columnar shape or an pentagonal or more polygonal shape and has no sharp angle are preferable for use in which a high transparency is required.

The cross-sectional shape of the metallic nanowire can be detected by coating a metallic nanowire aqueous dispersion liquid on the base material, and observing the cross-section using a transmission electron microscope (TEM).

The metal of the metallic nanowires is not particularly limited, may be any metal or a combination of two kinds of metal, and also can be used in a form of an alloy. Among the above, metallic nanowires formed of metal or a metallic compound are preferable, and metallic nanowires formed of metal are more preferable.

The metal is preferably at least one kind of metal selected from a group consisting of Periods 4, 5 and 6 of the long-form periodic table (IUPAC 1991), more preferably at least one kind of metal selected from Groups 2 to 14, and still more preferably at least one kind of metal selected from Groups 2, 8, 9, 10, 11, 12, 13 and 14. The metal is particularly preferably included as a main component.

Specific examples of the metal include copper, silver, gold, platinum, palladium, nickel, tin, cobalt, rhodium, iridium, iron, ruthenium, osmium, manganese, molybdenum, tungsten, niobium, tantalum, titanium, bismuth, antimony, lead, alloys thereof and the like. Among the above, copper, silver, gold, platinum, palladium, nickel, tin, cobalt, rhodium, iridium or an alloy thereof is preferable, and palladium, copper, silver, gold, platinum, tin or an alloy thereof is more preferable, and silver or an alloy containing silver is particularly preferable.

From the viewpoint of a high conduction, the metallic nanowires included in the conductive layer preferably include silver nanowires, more preferably include silver nanowires having an average short axis length of from 1 nm to 150 nm and an average long axis length of from 1 μm to 100 μm, and still more preferably include silver nanowires having an average short axis length of from 5 nm to 30 nm and an average long axis length of from 5 μm to 30 μm. A content rate of the silver nanowires included in the metal nanowires is not particularly limited as long as the effects of the invention are not hindered. For example, the content rate of the silver nanowires in the metal nanowires is preferably 50% by mass or more, and more preferably 80% by mass or more, and the metallic nanowires are still more preferably substantially silver nanowires. Here, the “substantially silver nanowires” mean that silver nanowires may include metallic atoms other than silver which are inevitably mixed in.

(Production Method of the Metallic Nanowires)

The metallic nanowires are not particularly limited, and may be manufactured using any method, but are preferably produced by reducing metallic ions in a solvent in which a halogen compound and a dispersant are dissolved as described below. In addition, from the viewpoint of dispersibility and the stability of a photosensitive layer over time, it is preferable to form metallic nanowires and then carry out a desalination treatment using a normal method.

In addition, methods described in JP-A No. 2009-215594, JP-A No. 2009-242880, JP-A No. 2009-299162, JP-A No. 2010-84173, JP-A No. 2010-86714 and the like can be used as the production method of the metallic nanowires.

The solvent used for the production of the metallic nanowires is preferably a hydrophilic solvent, and examples thereof include water, alcohols, ethers, ketones and the like. One of the above solvents may be solely used, or two or more may be used in a combination.

Examples of the alcohols include methanol, ethanol, propanol, isopropanol, butanol, ethylene glycol and the like.

Examples of the ethers include dioxane, tetrahydrofuran and the like.

Examples of the ketones include acetone and the like.

In a case in which metallic nanowires are heated, the heating temperature is preferably 250° C. or lower, more preferably from 20° C. to 200° C., still more preferably from 30° C. to 180° C., and particularly preferably from 40° C. to 170° C. When the temperature is set to 20° C. or higher, the lengths of metallic nanowires being formed are in a range in which dispersion stability can be ensured, and, when the temperature is set to 250° C. or lower, the outer circumferences of the cross-sections of metallic nanowires have a smooth shape with no sharp angle, and thus the temperature of 250° C. or lower is preferably from the viewpoint of transparency.

Meanwhile, the temperature may be changed as necessary in a particle-forming process, and there are cases in which the change of the temperature in the middle of the process has effects of controlling the formation of nuclei, suppressing the regeneration of nuclei, and improving monodispersibility through acceleration of selective growth.

When metallic nanowires are heated, a reducing agent is preferably added.

The reducing agent is not particularly limited, can be appropriately selected from ordinarily-used reducing agents, and examples thereof include borane metallic salts, aluminum hydride salts, alkanolamines, aliphatic amines, heterocyclic amines, aromatic amines, aralkylamines, alcohols, organic acids, reducing sugars, sugar alcohols, sodium sulfite, hydrazine compounds, dextrins, hydroquinones, hydroxylamines, ethylene glycols, glutathiones, and the like. Among the above, reducing sugars, sugar alcohols as derivatives of the reducing sugars, and ethylene glycols are particularly preferable.

Among the reducing agents, there are compounds that function as a dispersant or a solvent, and the compounds can be preferably used in a substantially similar manner.

The metallic nanowires are preferably produced by adding a dispersant, a halogen compound or fine particles of a metal halide.

The dispersant and the halogen compound may be added before or after the addition of the reducing agent, or before or after the addition of metallic ions or fine particles of a metal halide; however, in order to obtain nanowires having a more favorable monodispersibility, the halogen compound is preferably added at two or more steps probably because the formation and growth of nuclei can be controlled.

A process of the addition of the dispersant is not particularly limited. The dispersant may be added before the preparation of the particles, added in the presence of dispersed polymers, or added in order to control the dispersion state after the preparation of the particles. When the dispersant is added in two or more steps, it is necessary to change the amount of the dispersant depending on the necessary length of metallic nanowires. This is considered to be because the lengths of metallic nanowires are dependent on the control of the amount of metallic particles which serve as nuclei.

Examples of the dispersant include amino group-containing compounds, thiol group-containing compounds, sulfide group-containing compounds, amino acids or derivatives thereof, peptide compounds, polysaccharides, macromolecules such as polysaccharide-derived natural macromolecules, synthetic macromolecules and synthetic macromolecule-derived gels, and the like. Among the above, a variety of macromolecular compounds that can be used as the dispersant are compounds included in polymers (b) described below.

Preferable examples of polymers preferably used as the dispersant include polymers having a hydrophilic group such as gelatin which is a protective colloidal polymer, polyvinyl alcohols (P-3), methyl celluloses, hydroxypropyl celluloses, polyalkyleneamines, partial alkylesters of polyacrylic acids, polyvinyl pyrrolidones, copolymers having a polyvinyl pyrrolidone structure, and polyacrylic acids having an amino group or a thiol group.

A polymer used as the dispersant has a GPC-measured weight-average molecular weight (Mw) of preferably from 3000 to 300000 and more preferably from 5000 to 100000.

Regarding the structures of the compounds that can be used as the dispersant, for example, “DICTIONARY OF DYES” (by Hiroyuki Ito, published by ASAKURA PUBLISHING Co., Ltd., 2000) can be referenced.

The shapes of metallic nanowires being obtained can be changed depending on the kind of the dispersant being used.

The halogen compound is not particularly limited as long as the compound includes bromine, chlorine and iodine, can be appropriately selected depending on the purpose, and preferable examples thereof include alkali halides such as sodium bromide, sodium chloride, sodium iodide, potassium iodide, potassium bromide and potassium chloride, or compounds that can be jointly used with a dispersion additive described below.

Some of the halogen compounds might be capable of functioning as a dispersion additive, and they can be preferably used in a substantially similar manner.

As an alternative of the halogen compound, fine particles of silver halide may be used, or the halogen compound and fine particles of silver halide may be jointly used.

In addition, as the dispersant and the halogen compound, a sole substance having both functions may be used. That is, when a halogen compound having a function of a dispersant is used, both functions as the dispersant and the halogen compound are developed using a compound.

Examples of the halogen compound having a function of a dispersant include hexadecyltrimethylammonium bromide (HTAB) including an amino group and bromide ions, hexadecyltrimethylammonium chloride (HTAC) including an amino group and chloride ions, compounds including an amino group and bromide ions or chloride ions such as dodecyltrimethylammonium bromide, dodecyltrimethylammonium chloride, stearyltrimethylammonium bromide, stearyltrimethylammonium chloride, decyltrimethylammonium bromide, decyltrimethylammonium chloride, dimethyldistearylammonium bromide, dimethyldistearylammonium chloride, dilauryldimethylammonium bromide, dilauryldimethylammonium chloride, dimethyldipalmitylammonium bromide, dimethyldipalmitylammonium chloride and the like.

Meanwhile, the desalination treatment after the formation of the metallic nanowires can be carried out using a method such as ultrafiltration, dialysis, gel filtration, decantation or centrifugal separation.

The metallic nanowires preferably include inorganic ions, such as alkali metal ions, alkali earth metal ions or halide ions, as little as possible. The electric conductivity of the metallic nanowires dispersed in water is preferably 1 mS/cm or less, more preferably 0.1 mS/cm or less, and still more preferably 0.05 mS/cm or less.

The viscosity of the metallic nanowires dispersed in water at 20° C. is preferably from 0.5 mPa·s to 100 mPa·s, and more preferably from 1 mPa·s to 50 mPa·s.

The electric conductivity and the viscosity are measured in a dispersion liquid in which the concentration of the metallic nanowires is 0.40% by mass.

An amount of the metallic nanowires included in the conductive layer is preferably in a range of from 1 mg/m² to 50 mg/m² since a conductive layer that is excellent in terms of conduction and transparency can be easily obtained. The amount is more preferably in a range of from 3 mg/m² to 40 mg/m², and still more preferably from 5 mg/m² to 30 mg/m².

<Matrix>

As described above, the conductive layer includes a matrix together with the metallic nanowires. When the conductive layer includes a matrix, the dispersion of the metallic nanowires in the conductive layer is stably maintained so that strong adhesion between the base material and the conductive layer is ensured even in a case in which the conductive layer is formed on a surface of the base material without an adhesive layer. Furthermore, when the conductive layer includes a matrix, the transparency of the conductive layer improves, and heat resistance, moisture and heat resistance, and bendability improve.

A content ratio of the matrix to the metallic nanowires is appropriately in a range of from 0.001/1 to 100/1 by mass ratio. When the content ratio is in the above range, a conductive member with an appropriate adhesive force of the conductive layer to the base material and an appropriate surface resistivity is obtained. The content ratio of the matrix to the metallic nanowires is more preferably in a range of from 0.005/1 to 50/1, and still more preferably in a range of from 0.01/1 to 20/1 by mass ratio.

The matrix may or may not be photosensitive as described above.

Examples of appropriate non-photosensitive matrix include organic macromolecular polymers. Specific examples of the organic macromolecular polymers include polyacrylics (for example, polyacrylic acid esters or polymethacrylic acid esters such as poly(methyl methacrylates) and poly(methyl acrylates), copolymers of a methyl methacrylate and acrylonitrile, polyacrylic acids and the like), polyvinyl alcohols, polyamides, polyesters (for example, polyethylene terephthalate (PET), polyethylene naphthalate, polycarbonates and the like), highly aromatic macromolecules such as phenol or cresol-formaldehyde (NOVOLACS (registered trademark)), polystyrene, polyvinyl toluene, polyvinyl xylene, aromatic polyimides, aromatic polyamide-imides, aromatic polyether imides, aromatic polysulfides, aromatic polysulfones, polyphenylene and polyphenyl ethers, polyurethane (PU), epoxy resins, polyolefins (for example, polypropylene, polymethyl pentene and cyclic olefins), acrylonitrile-butadiene-styrene copolymers (ABS), celluloses, silicones and other silicon-containing macromolecules (for example, polysilsesquioxane and polysilanes), polyvinyl chlorides (PVC), polyvinyl acetates, polynorbornenes, synthetic rubber (for example, EPR, SBR, EPDM), carbon fluoride polymers (for example, polyvinylidene fluoride, polytetrafluoroethylene (PTFE) and polyhexafluoropropylene, copolymers of fluoroolefins (for example, “LUMIFLON” (registered trademark) manufactured by ASAHI GLASS Co., Ltd.), and amorphous fluorocarbon polymers or copolymers (for example, “CYTOP” (registered trademark) manufactured by ASAHI GLASS Co., Ltd.), “TEFLON” (registered trademark) AF manufactured by Du Pont KABUSHIKI KAISHA, and the like).

Furthermore, examples of the non-photosensitive matrix include cured sol-gel substances.

Preferable examples of the cured sol-gel substances include substances (hereinafter, also referred to as “specific cured sol-gel substances”) obtained by hydrolyzing, polycondensing, furthermore, if desired, heating and drying an alkoxide compound of an element selected from a group consisting of Si, Ti, Zr and Al (hereinafter, also referred to as “specific alkoxide compound”). In a case in which the conductive member in the invention has a conductive layer including the specific cured sol-gel substance as the matrix, generally, the conducive member is excellent in terms of at least one of conduction, transparency, film strength, abrasion resistance, heat resistance, moisture and heat resistance and bendability compared with conductive members having a conductive layer including a matrix other than the specific cured sol-gel substance, which is preferable.

[Specific Alkoxide Compound]

The specific alkoxide compound is preferably at least one compound selected from a group consisting of compounds represented by the following Formula (II) and compounds represented by the following Formula (III) due to easy procurement.

M²(OR¹)₄ (II)

(In the Formula (II), M² represents an element selected from Si, Ti and Zr, a plurality of R¹ may be the same as or different from each other and each of R¹ independently represents a hydrogen atom or a hydrocarbon group.)

M³(OR²)ₐR³₄₋ₐ (III)

(In the Formula (III), M³ represents an element selected from Si, Ti and Zr, a plurality of R² and a plurality of R³ may be the same as or different from each other, and each of R² and each of R³ independently represent a hydrogen atom or a hydrocarbon group, and a represents an integer of 1 to 3.)

Preferable examples of the respective hydrocarbon groups for R¹ in the Formula (II) and for R² and R³ in the Formula (III) include alkyl groups or aryl groups.

In a case in which R′, R² and R³ represent an alkyl group, the number of carbon atoms is preferably 1 to 18, more preferably 1 to 8, and still more preferably 1 to 4. In addition, in a case in which R¹, R² and R³ represent an aryl group, a phenyl group is preferable.

The alkyl group or the aryl group may have a substituent, and examples of introducible substituents include halogen atoms, amino groups, mercapto groups and the like. Meanwhile, the compound is a low molecular compound, and the molecular weight is preferably 1000 or less.

M² in the Formula (II) and M³ in the Formula (III) are more preferably Si.

Hereinafter, specific examples of the compound represented by the Formula (II) will be described, but the invention is not limited thereto.

In a case in which M² is Si, that is, the compound including silicon in the specific alkoxide is, for example, tetramethoxysilane, tetraethoxysilane, tetrapropoxysilane, tetrabutoxysilane, methoxytriethoxysilane, ethoxytrimethoxysilane, methoxytripropoxysilane, ethoxytripropoxysilane, propoxytrimethoxysilane, propoxytriethoxysilane, dimethoxydiethoxysilane, or the like. Among the above, particularly preferable examples include tetramethoxysilane, tetraethoxysilane, and the like.

In a case in which M² is Ti, that is, the compound including titanium is, for example, tetramethoxy titanate, tetraethoxy titanate, tetrapropoxy titanate, tetraisopropoxy titanate, tetrabutoxy titanate, or the like.

In a case in which M² is Zr, that is, the compound including zirconium is, for example, a zirconate that corresponds to the compound exemplified as the compound including titanium.

Next, specific examples of the compound represented by the Formula (III) will be described, but the invention is not limited thereto.

In a case in which M³ is Si and a is 2, that is, a difunctional alkoxysilane is, for example, dimethyl dimethoxysilane, diethyl dimethoxysilane, propyl methyl dimethoxysilane, dimethyl diethoxysilane, diethyl diethoxysilane, dipropyl diethoxysilane, γ-chloropropyl methyl diethoxysilane, γ-chloropropyl methyl dimethoxysilane, (p-chloromethyl)phenyl methyl dimethoxysilane, γ-bromopropyl methyl dimethoxysilane, acetoxymethyl methyl diethoxysilane, acetoxymethyl methyl dimethoxysilane, acetoxy propyl methyl dimethoxysilane, benzoyloxypropyl methyl dimethoxysilane, 2-(carbomethoxy) ethyl methyl dimethoxysilane, phenyl methyl dimethoxysilane, phenyl ethyl diethoxysilane, phenyl methyl di-propoxysilane, hydroxymethyl methyl diethoxysilane, N-(methyl-diethoxysilyl-propyl)-O-polyethylene oxide urethane, N-(3-methyl-diethoxysilylpropyl)-4-hydroxy-butylamide, N-(3-methyl-diethoxysilylpropyl) gluconamide, vinyl methyl dimethoxysilane, vinyl methyl diethoxysilane, vinyl methyl dibutoxysilane, isopropenyl methyl dimethoxysilane, isopropenyl methyl diethoxysilane, isopropenyl methyl dibutoxysilane, vinyl methyl bis(2-methoxyethoxy)silane, allyl methyl dimethoxysilane, vinyldecyl methyl dimethoxysilane, vinyloctyl methyl dimethoxysilane, vinylphenyl methyl dimethoxysilane, isopropenylphenyl methyl dimethoxysilane, 2-(meth)acryloyloxyethyl methyl dimethoxysilane, 2-(meth)acryloyloxyethyl methyl diethoxysilane, 3-(meth)acryloyloxypropyl methyl dimethoxysilane, 3-(meth)acryloyloxypropyl methyl diethoxysilane, 3-(meth)acryloyloxypropyl methyl bis(2-methoxyethoxy)silane, 3-[2-(allyloxycarbonyl)phenylcarbonyloxy]propyl methyl dimethoxysilane, 3-(vinyl phenylamino)propyl methyl dimethoxysilane, 3-(vinylphenylamino)propyl methyl diethoxysilane, 3-(vinylbenzylamino)propyl methyl diethoxysilane, 3-(vinylbenzylamino)propyl methyl diethoxysilane, 3-[2-(N-vinylphenylmethylamino)ethyl amino]propyl methyl dimethoxysilane, 3-[2-(N-isopropenylphenylmethylamino)ethylamino]propyl methyl dimethoxysilane, 2-(vinyloxy)ethyl methyl dimethoxysilane, 3-(vinyloxy)propyl methyl dimethoxysilane, 4-(vinyloxy)butyl methyl diethoxysilane, 2-(isopropenyloxy)ethyl methyl dimethoxysilane, 3-(allyloxy)propyl methyl dimethoxysilane, 10-(allyloxycarbonyl)decyl methyl dimethoxysilane, 3-(isopropenylmethyloxy)propyl methyl dimethoxysilane, 10-(isopropenylmethyloxycarbonyl)decyl methyl dimethoxysilane, 3-[(meth)acryloyloxypropyl]methyl dimethoxysilane, 3-[(meth)acryloyloxypropyl]methyl diethoxysilane, 3-[(meth)acryloyloxymethyl]methyl dimethoxysilane, 3-[(meth)acryloyloxymethyl]methyl diethoxysilane, γ-glycidoxypropyl methyl dimethoxysilane, N-[3-(meth)acryloyloxy-2-hydroxypropyl]-3-aminopropyl methyl diethoxysilane, O-[(meth)acryloyloxyethyl]-N-(methyldiethoxysilylpropyl)urethane, γ-glycidoxypropyl methyl diethoxysilane, β-(3,4-epoxycyclohexyl)ethyl methyl dimethoxysilane, γ-aminopropyl methyl diethoxysilane, γ-aminopropyl methyl dimethoxysilane, 4-amino-butyl methyl diethoxysilane, 11-amino-undecyl methyl diethoxysilane, m-aminophenyl methyl dimethoxysilane, p-aminophenyl methyl dimethoxysilane, 3-aminopropyl methyl-bis(methoxyethoxy)silane, 2-(4-pyridylethyl)methyl diethoxysilane, 2-(methyldimethoxysilylethyl)pyridine, N-(3-methyldimethoxysilylpropyl)pyrrole, 3-(m-aminophenoxy)propyl methyl dimethoxysilane, N-(2-aminoethyl)-3-aminopropyl methyl dimethoxysilane, N-(2-aminoethyl)-3-aminopropyl methyl diethoxysilane, N-(6-aminohexyl)amino-methyl methyl diethoxysilane, N-(6-aminohexyl)aminopropyl methyl dimethoxysilane, N-(2-aminoethyl)-11-amino-undecyl methyl dimethoxysilane, (aminoethyl aminomethyl)phenethyl methyl dimethoxysilane, N-3-[(amino(polypropyleneoxy))]aminopropyl methyl dimethoxysilane, n-butylaminopropyl methyl dimethoxysilane, N-ethylaminoisobutyl methyl dimethoxysilane, N-methyl-aminopropyl methyl dimethoxysilane, N-phenyl-γ-amino-propyl methyl dimethoxysilane, N-phenyl-γ-aminomethyl methyl diethoxysilane, (cyclohexylaminomethyl) methyl diethoxysilane, N-cyclohexylaminopropyl methyl dimethoxysilane, bis(2-hydroxyethyl)-3-aminopropyl methyl diethoxysilane, diethylaminomethyl methyl diethoxysilane, diethylaminopropyl methyl dimethoxysilane, dimethylaminopropyl methyl dimethoxysilane,

N-3-methyldimethoxysilylpropyl-m-phenylenediamine, N,N-bis[3-(methyldimethoxysilyl)propyl]-ethylenediamine, bis(methyl-diethoxysilylpropyl)amine, bis(methyldimethoxysilylpropyl)amine, bis[(3-methyldimethoxysilyl)propyl]-ethylenediamine, bis[3-(methyldiethoxysilyl)propyl]urea, bis(methyldimethoxysilylpropyl)urea, N-(3-methyl-diethoxysilylpropyl)-4,5-dihydro-imidazole, ureidopropyl methyl diethoxysilane, ureidopropyl methyl dimethoxysilane, acetamidopropyl methyl dimethoxysilane, 2-(2-pyridylethyl)thiopropyl methyl dimethoxysilane, 2-(4-pyridylethyl)thiopropyl methyl dimethoxysilane, bis[3-(methyldiethoxysilyl)propyl]disulfide, 3-(methyldiethoxysilyl)propylsuccinic acid anhydride, γ-mercaptopropyl methyl dimethoxysilane, γ-mercaptopropyl methyl diethoxysilane, isocyanatopropyl methyl dimethoxysilane, isocyanatopropyl methyl diethoxysilane, isocyanatoethyl methyl diethoxysilane, isocyanatomethyl methyl diethoxysilane, carboxyethyl methylsilane diol sodium salt, N-(methyldimethoxysilylpropyl)ethylenediamine triacetic acid trisodium salt, 3-(methyl dihydroxysilyl)-1-propanesulfonic acid, diethyl phosphatoethyl methyl diethoxysilane, 3-methyl-dihydroxysilylpropyl methylphosphonate sodium salt, bis(methyldiethoxysilyl)ethane, bis(methyldimethoxysilyl)ethane, bis(methyldiethoxysilyl)methane, 1,6-bis(methyldiethoxysilyl)hexane, 1,8-bis(methyldiethoxysilyl)octane, p-bis(methyldimethoxysilylethyl)benzene, p-bis(methyldimethoxysilyl)benzene, 3-methoxypropyl methyl dimethoxysilane, 2-[methoxy(polyethyleneoxy)propyl]methyl dimethoxysilane, methoxytriethyleneoxypropyl methyl dimethoxysilane, tris(3-methyldimethoxysilylpropyl)isocyanurate, [hydroxy(polyethyleneoxy)propyl]methyl diethoxysilane, N,N′-bis(hydroxyethyl)-N,N′-bis(methyldimethoxysilylpropyl)ethylenediamine, bis-[3-(methyldiethoxysilylpropyl)-2-hydroxypropoxy]polyethylene oxide, bis[N,N′-(methyl-diethoxysilylpropyl)aminocarbonyl]polyethylene oxide, bis(methyldiethoxysilylpropyl)polyethylene oxide. Among the above, particularly preferable example include dimethyl dimethoxysilane, diethyl dimethoxysilane, dimethyl diethoxysilane, diethyl diethoxysilane, and the like from the viewpoints of easy procurement and adhesion to hydrophilic layers.

In a case in which M³ is Si and a is 3, that is, a trifunctional organo alkoxysilane can be, for example, methyl trimethoxysilane, ethyl trimethoxysilane, propyl trimethoxysilane, methyl triethoxysilane, ethyl triethoxysilane, propyl triethoxysilane, γ-chloropropyl triethoxysilane, γ-chloropropyl trimethoxysilane, chloromethyl triethoxysilane, (p-chloromethyl)phenyl trimethoxy silane, γ-bromopropyl trimethoxysilane, acetoxymethyl triethoxysilane, acetoxymethyl trimethoxysilane, acetoxypropyl trimethoxy silane, benzoyloxypropyl trimethoxysilane, 2-(carbomethoxy)ethyl trimethoxysilane, phenyl trimethoxysilane, phenyl triethoxysilane, phenyl tripropoxysilane, hydroxymethyl triethoxysilane, N-(triethoxysilylpropyl)-O-polyethylene oxido urethane, N-(3-triethoxysilylpropyl)-4-hydroxybutyl amide, N-(3-triethoxysilylpropyl)gluconamide, vinyl trimethoxysilane, vinyl triethoxysilane, vinyl tributoxysilane, isopropenyl trimethoxysilane, isopropenyl triethoxysilane, isopropenyl tributoxysilane, vinyl tris(2-methoxyethoxy)silane, allyl trimethoxysilane, vinyldecyl trimethoxy silane, vinyloctyl trimethoxysilane, vinylphenyl trimethoxysilane, isopropenylphenyl trimethoxysilane, 2-(meth)acryloyloxyethyl trimethoxysilane, 2-(meth)acryloyloxyethyl triethoxysilane, 3-(meth)acryloyloxypropyl trimethoxysilane, 3-(meth)acryloyloxypropyl trimethoxysilane, 3-(meth)acryloyloxypropyl tris(2-methoxyethoxy)silane, 3-[2-(allyloxycarbonyl)phenylcarbonyloxy]propyl trimethoxysilane, 3-(vinylphenylamino)propyl trimethoxysilane, 3-(vinylphenylamino)propyl triethoxysilane, 3-(vinylbenzylamino)propyl triethoxysilane, 3-(vinylbenzylamino)propyl triethoxysilane, 3-[2-(N-vinylphenylmethylamino)ethylamino]propyl trimethoxysilane,

3-[2-(N-isopropenylphenylmethylamino)ethylamino]propyl trimethoxysilane, 2-(vinyloxy)ethyl trimethoxysilane, 3-(vinyloxy)propyl trimethoxysilane, 4-(vinyloxy)butyl triethoxysilane, 2-(isopropenyloxy)ethyl trimethoxysilane, 3-(allyloxy)propyl trimethoxysilane, 10-(allyloxycarbonyl)decyl trimethoxysilane, 3-(isopropenyl methyloxy)propyl trimethoxysilane, 10-(isopropenylmethyloxycarbonyl)decyl trimethoxysilane, 3-[(meth)acryloyloxy]propyl trimethoxysilane, 3-[(meth)acryloyloxy]propyl triethoxysilane, (meth)acryloyloxymethyl trimethoxysilane, (meth)acryloyloxymethyl triethoxysilane, γ-glycidoxypropyl trimethoxysilane, N-[3-(meth)acryloyloxy-2-hydroxypropyl]-3-aminopropyl triethoxysilane, O-[(meth)acryloyloxyethyl]-N-(triethoxysilylpropyl)urethane, γ-glycidoxypropyl triethoxysilane, β-(3,4-epoxycyclohexyl)ethyl trimethoxysilane, γ-aminopropyl triethoxysilane, γ-aminopropyl trimethoxysilane, 4-aminobutyl triethoxysilane, 11-aminoundecyl triethoxysilane, m-aminophenyl trimethoxysilane, p-aminophenyl trimethoxysilane, 3-amino propyl tris(methoxyethoxyethoxy)silane, 2-(4-pyridyl)ethyl triethoxysilane, 2-(trimethoxysilylethyl)pyridine, N-(3-trimethoxysilylpropyl)pyrrole, 3-(m-amino-phenoxy)propyl trimethoxysilane, N-(2-aminoethyl)-3-aminopropyl trimethoxysilane, N-(2-aminoethyl)-3-aminopropyl triethoxysilane, N-(6-aminohexyl)aminomethyl triethoxy silane, N-(6-aminohexyl)aminopropyl trimethoxysilane, N-(2-aminoethyl)-11-aminoundecyl trimethoxysilane, (aminoethylaminomethyl)phenethyl trimethoxysilane, 3-N-[(amino (polypropyleneoxy))]aminopropyl trimethoxysilane, n-butylaminopropyl trimethoxy silane, N-ethylaminoisobutyl trimethoxy silane, N-methylaminopropyl trimethoxysilane,

N-phenyl-γ-aminopropyl trimethoxysilane, N-phenyl-γ-aminomethyl triethoxysilane, (cyclohexylaminomethyl)triethoxysilane, N-cyclohexylaminopropyl trimethoxysilane, bis(2-hydroxyethyl)-3-aminopropyl triethoxysilane, diethylaminomethyl triethoxysilane, diethylaminopropyl trimethoxy silane, dimethylaminopropyl trimethoxysilane, N-3-trimethoxysilylpropyl-m-phenylenediamine, N,N-bis[3-(trimethoxysilyl)propyl]ethylenediamine, bis(triethoxysilylpropyl)amine, bis(trimethoxysilylpropyl)amine, bis[(3-trimethoxysilyl)propyl]-ethylenediamine, bis[3-(triethoxysilyl)propyl]urea, bis(trimethoxysilylpropyl)urea, N-(3-triethoxysilylpropyl)-4,5-dihydroimidazole, ureidopropyltriethoxysilane, ureidopropyltrimethoxysilane, acetamidopropyl trimethoxysilane, 2-(2-pyridylethyl)thiopropyl trimethoxysilane, 2-(4-pyridylethyl)thiopropyl trimethoxysilane, bis[3-(triethoxysilyl)propyl]disulfide, 3-(triethoxysilyl)propylsuccinic acid anhydride, γ-mercaptopropyl trimethoxysilane, γ-mercaptopropyl triethoxysilane, isocyanatopropyl trimethoxysilane, isocyanatopropyl triethoxysilane, isocyanatoethyl triethoxysilane, isocyanatomethyl triethoxysilane, carboxyethylsilanetriol sodium salt, N-(trimethoxysilyl propyl)ethylenediamine triacetic acid trisodium salt, 3-(trihydroxysilyl)-1-propanesulfonic acid, diethyl phosphatoethyl triethoxysilane, 3-trihydroxysilylpropyl methyl phosphonate sodium salt, bis(triethoxysilyl)ethane, bis(trimethoxysilyl)ethane, bis(triethoxysilyl)methane, 1,6-bis(triethoxysilyl)hexane, 1,8-bis(triethoxysilyl)octane, p-bis(trimethoxysilylethyl)benzene, p-bis(trimethoxysilyl)methylbenzene, 3-methoxypropyl trimethoxysilane, 2-[methoxy(polyethyleneoxy)propyl]trimethoxysilane, methoxytriethyleneoxypropyl trimethoxysilane, tris(3-trimethoxysilylpropyl)isocyanurate, [hydroxy(polyethyleneoxy)propyl]triethoxysilane, N,N′-bis(hydroxyethyl)-N,N′-bis(trimethoxysilylpropyl)ethylenediamine, bis-[3-(triethoxysilylpropyl)-2-hydroxypropoxy]polyethylene oxide, bis[N,N′-(triethoxysilylpropyl)aminocarbonyl]polyethylene oxide, bis(triethoxysilylpropyl)polyethylene oxide. Among the above, methyl trimethoxysilane, ethyl trimethoxysilane, methyl triethoxysilane, ethyl triethoxysilane and the like are particularly preferable from the viewpoints of easy procurement and adhesion to a hydrophilic layer.

In a case in which M³ is Ti and a is 2, that is, a difunctional organo alkoxy titanate can be, for example, dimethyl dimethoxy titanate, diethyl dimethoxy titanate, propyl methyl dimethoxy titanate, dimethyl diethoxy titanate, diethyl diethoxy titanate, dipropyl diethoxy titanate, phenyl ethyl diethoxy titanate, phenyl methyl dipropoxy titanate, dimethyl dipropoxy titanate or the like.

In a case in which M³ is Ti and a is 3, that is, a trifunctional organo alkoxy titanate can be, for example, methyl trimethoxy titanate, ethyl trimethoxy titanate, propyl trimethoxy titanate, methyl triethoxy titanate, ethyl triethoxy titanate, propyl triethoxy titanate, chloromethyl triethoxy titanate, phenyl trimethoxy titanate, phenyltriethoxy titanate, phenyl tripropoxy titanate or the like.

In a case in which M³ is Zr, that is, the compound including zirconium is, for example, a zirconate that corresponds to the compound exemplified as the compound including titanium.

In addition, examples of alkoxide compounds of Al that are not included in any of the Formulae (II) and (III) include trimethoxy aluminate, triethoxy aluminate, tripropoxy aluminate, tetraethoxy aluminate and the like.

The specific alkoxide can be easily procured from commercially available products, or can be obtained using a well-known synthesis method, for example, a reaction between each of the metal chlorides and an alcohol.

As the specific alkoxide, one compound may be solely used, or a combination of two or more compounds may be used.

Examples of the combination include a combination of (i) at least one compound selected from the compounds represented by the Formula (II) and (ii) at least one compound selected from the compounds represented by the Formula (III). For a conductive layer including, as the matrix, a cured sol-gel substance obtained by hydrolyzing and polycondensing a combination of two specific alkoxide compounds, the properties can be modified using the mixing ratio.

Furthermore, both M² in the Formula (II) and M³ in the Formula (III) are preferably Si.

The content ratio of the compound (ii)/the compound (i) is appropriately in a range of from 0.01/1 to 100/1, and more preferably in a range of from 0.05/1 to 50/1 by mass ratio.

A conductive layer including the metallic nanowires and the specific cured sol-gel substance as the matrix can be provided on the base material by coating an aqueous solution including a metallic nanowire-dispersed liquid (for example, an aqueous solution containing dispersed silver nanowires) and the specific alkoxide compound as a coating liquid (hereinafter, also referred to as “sol-gel coating liquid for the metallic nanowires”) on the base material so as to form a coated film, causing reactions of hydrolysis and polycondensation of the specific alkoxide compound in the coated film, and, furthermore, as necessary, heating and evaporating water which is used as a solvent, thereby drying the coated film.

In addition, as another method, a conductive layer including the metallic nanowires and the specific cured sol-gel substance as the matrix is formed on a transfer support in advance in a manner substantially similar to what has been described above, and then the conductive layer is transferred to a base material, whereby the conductive layer can be formed on the base material.

In order to accelerate the hydrolysis and polycondensation reactions, it is practically preferable to jointly use an acidic catalyst or a basic catalyst since the reaction efficiency increases. Hereinafter, the catalyst will be described.

[Catalyst]

Any substance can be used as the catalyst as long as the substance accelerates the hydrolysis and polycondensation reactions of the alkoxide compound.

Examples of the catalyst include acidic compounds and basic compounds. The acidic compounds and the basic compounds can be used as they are, and may be used in a state in which the compounds are dissolved in a solvent such as water or an alcohol (hereinafter, also referred to as acidic catalysts and basic catalyst respectively including the compounds dissolved in a solvent).

The concentration of the acidic compound or the basic compound dissolved in the solvent is not particularly limited, and may be appropriately selected depending on the characteristics of the acidic compound or the basic compound being used, the desired content of the catalyst and the like. Here, in a case in which the concentration of the acidic or basic compound that constitutes the catalyst is high, there is a tendency of the rate of the hydrolysis and polycondensation increasing. However, when a basic catalyst with an excessively high concentration is used, since there are cases in which sediment is generated and appears as defects in a layer, in a case in which the basic catalyst is used, the concentration is desirably 1 N or less in terms of the concentration in a liquid composition.

The kind of the acidic catalyst or the basic catalyst is not particularly limited; however, in a case in which it is necessary to use a catalyst having a high concentration, it is preferable to select a catalyst made of an element that rarely remains in the conductive layer. Specific examples of the acidic catalyst include hydrogen halides such as hydrochloric acid; inorganic acids such as nitric acid, sulfuric acid, sulfurous acid, hydrogen sulfide, perchloric acid, hydrogen perchloride and carbonic acid; carboxylic acids such as formic acid and acetic acid; substituted carboxylic acids in which R in a structural formula represented by RCOOH has a substituent; sulfonic acids such as benzenesulfonic acid; and the like, and specific examples of the basic catalyst include quaternary ammonium salt compounds such as ammonia water and tetramethylammonium hydroxide; organic amines such as ethylamine and aniline; and the like.

Here, R represents a hydrocarbon group. The hydrocarbon group represented by R has the same definition as the hydrocarbon group in the Formula (II), and has the same preferable embodiments.

As the catalyst, Lewis acid catalysts made of a metallic complex can also be preferably used. Particularly preferable catalysts are metallic complex catalysts, and examples thereof include metallic complexes made up of a metallic element selected from Groups 2A, 3B, 4A and 5A of the periodic table and a ligand that is an oxo or hydroxy]oxygen-containing compound selected from a group consisting of β-diketones, ketoesters, hydroxylcarboxylic acids or esters thereof, almino alcohols and enolic active hydrogen compounds.

Among the constituent metallic elements, elements belonging to Group 2A such as Mg, Ca, St and Ba; elements belonging to Group 3B such as Al and Ga; elements belonging to Group 4A such as Ti and Zr; and elements belonging to Group 5A such as V, Nb and Ta are preferable, and each of the above elements forms a complex having an excellent catalytic effect. Among the above, complexes including a metallic element selected from a group consisting of Zr, Al and Ti are excellent and preferable.

Specific examples of the oxo or hydroxyloxygen-containing compound that forms the ligand of the metallic complex include β-diketones such as acetylacetone (2,4-pentanedione) and 2,4-heptanedione; keto esters such as methyl acetoacetate, ethyl acetoacetate, and butyl acetoacetate; hydroxylcarboxylic acids such as lactic acid, methyl lactate, salicylic acid, ethyl salicylate, phenyl salicylate, malic acid, tartaric acid and methyl tartrate; keto alcohols such as 4-hydroxy-4-methyl-2-pentanone, 4-hydroxy-2-pentanone, 4-hydroxy-4-methyl-2-heptanone and 4-hydroxy-2-heptanone; amino alcohols such as monoethanolamine, N,N-dimethylethanolamine, N-methylmonoethanolamine, diethanolamine and triethanolamine; enolic active compounds such as methylolmelamine, methylolurea, methylolacrylamide and diethyl malonate ester; acetylacetone derivatives having a substituent at a methyl group, a methylene group or carbonyl carbon of acetylacetone (2,4-pentanedione); and the like.

A preferable ligand is an acetylacetone derivative. Here, the acetylacetone derivative refers to a compound having a substituent at a methyl group, a methylene group or carbonyl carbon of acetylacetone. Examples of the substituent that substitutes the methyl group of acetylacetone include linear or branched alkyl groups, acyl groups, hydroxyalkyl groups, carboxyalkyl groups, alkoxy groups and alkoxyalkyl groups all of which have 1 to 3 carbon atoms; examples of the substituent that substitutes the methylene group of acetylacetone include linear or branched carboxyalkyl groups and hydroxyalkyl groups all of which have 1 to 3 carbon atoms, and examples of the substituent that substitutes the carbonyl carbon of acetylacetone include alkyl groups having 1 to 3 carbon atoms, in which a hydrogen atom is added to the carbonyl oxygen so as to form a hydroxyl group.

Specific examples of preferable acetylacetone derivatives include ethylcarbonylacetone, n-propylcarbonylacetone, i-propylcarbonylacetone, di-acetylacetone, 1-acetyl-1-propionyl-acetylacetone, hydroxyethylcarbonylacetone, hydroxypropylcarbonyl acetone, acetoacetic acid, acetopropionic acid, diacetoacetic acid, 3,3-diacetopropionic acid, 4,4-diacetobutyric acid, carboxyethylcarbonylacetone, carboxypropylcarbonylacetone, and diacetone alcohol. Among the above, acetylacetone and diacetylacetone are particularly preferable. The acetylacetone derivatives and the complexes of the above metallic element are mononuclear complexes in which one metallic element is coordinated with 1 to 4 acetylacetone derivatives, and, in a case in which the number of possible coordinate bonds of the metallic element is larger than the total number of possible coordinate bonds of the acetylacetone derivatives, the metallic element may be coordinated with ligands that are ordinarily used in complexes, such as water molecules, halogen ions, nitro groups and ammonio groups.

Preferable examples of the metallic complex include tris(acetylacetonato) aluminum complex salts, di(acetylacetonato) aluminum.aquo complex salts, mono(acetylacetonato) aluminum.chloro complex salts, di(diacetylacetonato) aluminum complex salts, ethyl acetoacetate aluminum diisopropylate, aluminum tris(ethyl acetoacetate), cyclic aluminum oxide isopropylate, tris(acetylacetonato) barium complex salts, di(acetylacetonato) titanium complex salts, tris(acetylacetonato) titanium complex salts, di-i-propoxy-bis(acetylacetonato) titanium complex salts, zirconium tris(ethyl acetoacetate), zirconium tris(benzoic acid) complex salts, and the like. The above metallic complexes are excellent in terms of stability in aqueous coating liquids and a gelation acceleration effect in sol-gel reactions during heating and drying, and, among the above, ethyl acetoacetate aluminum diisopropylate, aluminum tris(ethyl acetoacetate), di(acetylacetonato) titanium complex salts, zirconium tris(ethyl acetoacetate) are particularly preferable.

The counter ions of the above metallic complexes will not be described in detail. The kind of counter ion is arbitrary as long as the counter ion forms a water-soluble salt that can maintain the electrical neutrality of the complex compound, and, for example, nitrate, halogen acid salts, sulfate, phosphate and the like can be used in a form of a salt that can ensure stoichiometric neutrality.

The behaviors of the metallic complexes in silica sol-gel reactions are described in detail in J. Sol-Gel. Sci. and Tec., Vol. 16, pp. 209 to 220 (1999). The following scheme is assumed as a reaction mechanism. That is, in a liquid composition, the metallic complex is stable in a coordinate structure. In a dehydration condensation reaction which begins in a natural drying or heating and drying process after the conductive layer is supplied to the base material, it is considered that crosslinking is accelerated in a mechanism similar to that of the acidic catalyst. In any cases, the use of the metallic complex enables the obtainment of a matrix that is excellent in terms of the stability of the liquid composition over time, and the coat surface qualities and high durability of the conductive layer.

The metallic complex catalyst can be easily procured from commercially available products, or can be obtained using a well-known synthesis method, for example, a reaction between each of the metal chlorides and an alcohol.

The catalyst according to the invention is used in the sol-gel coating liquid for the metallic nanowires in a range of preferably from 0% by mass to 50% by mass and more preferably from 5% by mass to 25% by mass with respect to non-volatile components. The catalyst may be solely used, or a combination of two or more catalysts may be used.

[Solvent]

An organic solvent may be included as desired in the sol-gel coating liquid for the metallic nanowires in order to ensure the uniform formability of a coating liquid film on the conductive layer.

Examples of the organic solvent include ketone-based solvents such as acetone, methyl ethyl ketone and diethyl ketone; alcohol-based solvents such as methanol, ethanol, 2-propanol, 1-propanol, 1-butanol and tert-butanol; chlorine-based solvents such as chloroform and methylene chloride; aromatic solvents such as benzene and toluene; ester-based solvents such as ethyl acetate, butyl acetate and isopropyl acetate; ether-based solvents such as diethyl ether, tetrahydrofuran and dioxane; glycol ether-based solvents such as ethylene glycol monomethyl ether and ethylene glycol dimethyl ether; and the like.

In this case, the addition of the organic solvent is effective as long as volatile organic solvent (VOC)-related problems do not occur, and the organic solvent is added in a range of preferably 50% by mass or less and more preferably 30% by mass or less with respect to the total mass of the sol-gel coating liquid for the metallic nanowires.

In the coating liquid film of the sol-gel coating liquid for the metallic nanowires formed on the base material or the transfer support, the hydrolysis and condensation reaction of the specific alkoxide compound is caused, and the coating liquid film is preferably heated and dried in order to accelerate the reaction. The heating temperature for accelerating the sol-gel reaction is appropriate in a range of from 30° C. to 200° C., and more preferably in a range of from 50° C. to 180° C. The heating and drying time is preferably from 10 seconds to 300 minutes, and more preferably from 1 minute to 120 minutes.

The reason why conductive members for which at least one of conduction, transparency, abrasion resistance, heat resistance, moisture and heat resistance and bending resistance are improved can be obtained in a case in which the conductive layer includes the specific cured sol-gel substance as the matrix is not clear, but conductive members are assumed to be obtained for the following reason.

That is, when the conductive layer includes the metallic nanowires and the specific cured sol-gel substance obtained by hydrolyzing and polycondensing the specific alkoxide compound as the matrix, since a dense conductive layer with a few voids is formed even when a small proportion of the matrix is included in the conductive layer compared with a conductive layer including a general organic macromolecular resin (for example, an acrylic resin, a vinyl polymer-based resin or the like) as the matrix, a conductive layer that is excellent in terms of abrasion resistance, heat resistance, and moisture and heat resistance can be obtained. Furthermore, it is assumed that a polymer having a hydrophilic group which is used as a dispersant when preparing silver nanowires hinders the contact between the silver nanowires at least to some extent; however, in the step of forming the cured sol-gel substance, the dispersant that covers the silver nanowires is separated, and, furthermore, condensed when the specific alkoxide compound is polycondensed, and therefore the contact points between a number of silver nanowires increase. Therefore, the contact points between the silver nanowires increase so that a high conduction is obtained, and, also, a high transparency is obtained. In addition, when the protective layer is configured to include a three-dimensional bond represented by the Formula (I) or, particularly, the protective layer includes the specific cured sol-gel substance obtained by hydrolyzing and polycondensing the specific alkoxide compound as described below, an interaction between the protective layer and the matrix included in the conductive layer occurs so that effects of conduction and transparency being maintained, abrasion resistance, heat resistance, and moisture and heat resistance being excellent, and bending resistance being excellent can be obtained.

Next, the photosensitive matrix will be described.

Examples of the photosensitive matrix include photoresist compositions that are preferable for lithographic processes. In a case in which a photoresist composition is included as the matrix, a conductive layer having a conductive area and a non-conductive area in a pattern shape can be formed using a lithographic process, which is preferable. Among the photoresist compositions, photopolymerizable compositions are particularly preferable since conductive layers that are excellent in terms of transparency, flexibility and adhesion with the base material can be obtained. Hereinafter, the photopolymerizable composition will be described.

<Photopolymerizable Composition>

The photopolymerizable composition includes (a) an addition polymerizable unsaturated compound and (b) a photopolymerization initiator that generates radicals when irradiated with light as basic components. The photopolymerizable composition may further include (c) a binder and/or (d) additives other than the components (a) to (c) as desired.

Hereinafter, the components will be described.

[(a) Addition Polymerizable Unsaturated Compound]

The addition polymerizable unsaturated compound (hereinafter, also referred to as “polymerizable compound”) of the component (a) is a compound polymerized by causing an addition polymerization reaction in the presence of a radical, and, generally, a compound having at least one, preferably two or more, more preferably four or more, and still more preferably six or more ethylenically unsaturated double bonds at the molecular terminal is used.

The compound has a chemical form, for example, a monomer, a prepolymer, that is, a dimer, a trimer or an oligomer, or a mixture thereof.

A variety of polymerizable compounds are known, and the compounds can be used as the component (a).

Among the above, the polymerizable compound is particularly preferably trimethylol propane tri(meth)acrylate, pentaerythritol tetra(meth)acrylate, dipentaerythritol hexa(meth)acrylate, dipentaerythritol penta(meth)acrylate from the viewpoint of film strength.

The content of the component (a) is preferably from 2.6% by mass to 37.5% by mass, and more preferably from 5.0% by mass to 20.0% by mass with respect to the total mass of the solid content of the photopolymerizable composition including the metallic nanowires.

[(b) Photopolymerization Initiator]

The photopolymerization initiator of the component (b) is a compound that generates radicals when irradiated with light. Examples of the photopolymerization initiator include compounds that generate acidic radicals that eventually become acids by light radiation, compounds that generate other radicals, and the like. Hereinafter, the former will be called “photo acid-generating agent” and the latter will be called “photo radical-generating agent”.
—Photo Acid-Generating Agent—

The photo acid-generating agent can be appropriately selected and used from photoinitiators of photo-cationic polymerization, photoinitiators of photo-radical polymerization, photo-decoloring agents of colorants, photo-discoloring agents, well-known compounds that generate acidic radicals by the radiation of actinic light rays or radioactive rays used for microresist and the like, and mixtures thereof.

The photo acid-generating agent is not particularly limited, and can be appropriately selected depending on the purpose. Examples thereof include triazines having at least one di-or tri-halomethyl group, 1,3,4-oxadiazole, naphthoquinone-1,2-diazide-4-sulfonyl halide, diazonium salts, phosphonium salts, sulfonium salts, iodonium salts, imide sulfonate, oxime sulfonate, diazodisulfone, disulfone, o-nitrobenzyl sulfonate, and the like. Among the above, imide sulfonate, oxime sulfonate, and o-nitrobenzyl sulfonate, which are compounds that generate a sulfonic acid, are particularly preferable.

In addition, compounds having a group that generates an acidic radical by the radiation of actinic light rays or radioactive rays or a compound introduced into a major chain or a side chain of a resin, for example, compounds described in the specification of U.S. Pat. No. 3,849,137, the specification of German Patent No. 3914407, respective publications of JP-A No. S63-26653, JP-A No. S55-164824, JP-A No. S62-69263, JP-A No. S63-146038, JP-A No. S63-163452, JP-A No. S62-153853, JP-A No. S63-146029 and the like can be used.

Furthermore, compounds described in the respective specifications of U.S. Pat. No. 3,779,778, European Patent No. 126,712, and the like can also be used as the acid-generating agent.

Examples of the triazine-based compound include 2-(4-methoxyphenyl)-4,6-bis(trichloromethyl)-s-triazine, 2-(4-methoxynaphthyl)-4,6-bis(trichloromethyl)-s-triazine, 2-(4-ethoxynaphthyl)-4,6-bis(trichloromethyl)-s-triazine, 2-(4-ethoxycarbonyl naphthyl)-4,6-bis(trichloromethyl)-s-triazine, 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bis(trichloromethyl)-s-triazine, 2-(3,4-epoxy phenyl)-4,6-bis(trichloromethyl)-s-triazine, 2-(p-chlorophenyl)-4,6-bis(trichloromethyl)-s-triazine, 2-[1-(p-methoxyphenyl)-2,4-butadienyll-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(p-i-propyloxystyryl)-4,6-bis(trichloromethyl)-s-triazine, 2-(p-tolyl)-4,6-bis(trichloromethyl)-s-triazine, 2-(4-methoxynaphthyl)-4,6-bis(trichloromethyl)-s-triazine, 2-phenylthio-4,6-bis(trichloromethyl methyl)-s-triazine, 2-benzylthio-4,6-bis(trichloromethyl)-s-triazine, 4-(o-bromo-p-N,N-bis(ethoxycarbonylamino)phenyl)-2,6-di(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine, 2-methoxy-4,6-bis(tribromomethyl)-s-triazine, and the like. The triazine-based compound may be solely used, or two or more triazine-based compounds may be used in a combination.

In the invention, among the photo acid-generating agents (1), compounds that generate a sulfonic acid are preferable, and an oxim sulfonate compound illustrated below is particularly preferably from the viewpoint of a high sensitivity.

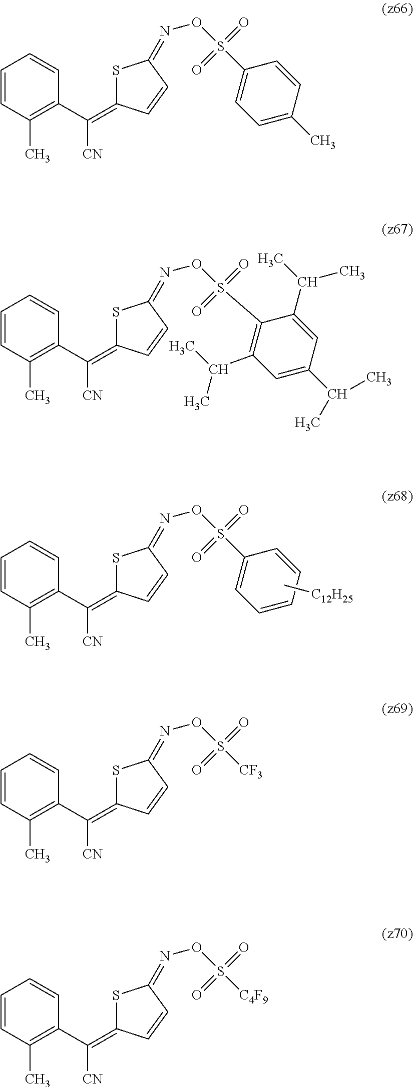

—Photo Radical-Generating Agent—

The photo radical-generating agent is a compound having a function of directly absorbing light or sensing light so as to cause a decomposition reaction or a hydrogen-extracting reaction, thereby generating radicals. The photo radical-generating agent preferably absorbs light in a wavelength range of from 300 nm to 500 nm.

A number of compounds are known as the photo radical-generating agent, and examples thereof include carbonyl compounds, ketal compounds, benzoin compounds, acridine compounds, organic peroxide compounds, azo compounds, coumarin compounds, azide compounds, metallocene compounds, hexaarylbiimidazole compounds, organic borate compounds, disulfone compounds, oxim ester compounds and acyl phosphine (oxide) compounds, all of which are described in JP-A No. 2008-268884. The photo radical-generating agent can be appropriately selected depending on the purpose. Among the above, benzophenone compounds, acetophenone compounds, hexaaryl biimidazole compounds, oxim ester compounds and acyl phosphine (oxide) compounds are particularly preferable from the viewpoint of exposure sensitivity.

Examples of the benzophenone compounds include benzophenone, Michler's ketone, 2-methylbenzophenone, 3-methylbenzophenone, N,N-diethylaminobenzophenone, 4-methylbenzophenone, 2-chlorobenzophenone, 4-bromobenzophenone, 2-carboxybenzophenone and the like. The benzophenone compound may be solely used, or two or more benzophenone compounds may be used in a combination.

Examples of the acetophenone compounds include 2,2-dimethoxy-2-phenyl acetophenone, 2,2-diethoxyacetophenone, 2-(dimethylamino)-2-[(4-methylphenyl)methyl]-1-[4-(4-morpholinyl)phenyl]-1-butanone, 1-hydroxycyclohexyl phenyl ketone, α-hydroxy-2-methylphenyl propanone, 1-hydroxy-1-methylethyl (p-isopropylphenyl) ketone, 1-hydroxy-1-methylethyl (p-dodecylphenyl) ketone, 2-methyl-1-(4-methylthiophenyl)-2-morpholinopropan-1-one, 1,1,1-trichloromethyl (p-butylphenyl) ketone, 2-benzyl-2-dimethyl amino-1-(4-morpholinophenyl)-butanone-1 and the like. Specific examples of commercially available products include IRGACURE 369 (registered trademark), IRGACURE 379 (registered trademark), IRGACURE 907 (registered trademark), all of which are manufactured by BASF Japan Ltd. The acetophenone compound may be solely used, or two or more acetophenone compounds may be used in a combination.

Examples of the hexaarylbiimidazole compounds include a variety of compounds described in the respective specifications of Japanese Patent Application Publication (JP-B) No. H6-29285, U.S. Pat. No. 3,479,185, U.S. Pat. No. 4,311,783, U.S. Pat. No. 4,622,286 and the like, and specific examples include 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, 2,2′-bis(o-trifluorophenyl)-4,4′,5,5′-tetraphenylbiimidazole, and the like. The hexaarylbiimidazole compound may be solely used, or two or more hexaarylbiimidazole compounds may be used in a combination.

Examples of the oxim ester compounds include compounds described in J.C.S. Perkin II (1979) 1653-1660, J.C.S. Perkin II (1979) 156-162, Journal of Photopolymer Science and Technology (1995) 202 to 232, the respective specifications of JP-A No. 2000-66385, JP-A No. 2000-80068, Japanese Patent National Phase Publication No. 2004-534797 and the like. Specific examples of preferable oxim ester compounds include IRGACURE (registered trademark) OXE-01, IRGACURE (registered trademark) OXE-02, all of which are manufactured by BASF Japan Ltd., and the like. The oxim ester compound may be solely used, or two or more oxim ester compounds may be used in a combination.

Examples of the acylphosphine (oxide) compounds include IRGACURE (registered trademark) 819, DAROCUR (registered trademark) 4265, DAROCUR (registered trademark) TPO, all of which are manufactured by BASF Japan Ltd., and the like.

The photo radical-generating agent is particularly preferably 2-(dimethylamino)-2-[(4-methylphenyl)methyl]-1-[4-(4-morpholinyl)phenyl]-1-butanone, 2-benzyl-2-dimethylamino-1-(4-morpholinophenyl)-butanone-1,2-methyl-1-(4-methylthiophenyl)-2-morpholinopropan-1-one, 2,2′-bis(2-chlorophenyl)-4,4′,5,5′-tetraphenylbiimidazole, N,N-diethylaminobenzophenone, or 1-[4-(phenylthio)phenyl]-1,2-octanedione-2-(O-benzoyl oxime) from the viewpoint of exposure sensitivity and transparency.

The photopolymerization initiator of the component (b) may be solely used, or two or more photopolymerization initiators may be used in a combination. The content of the photopolymerization initiator in the conductive layer is preferably from 0.1% by mass to 50% by mass, more preferably from 0.5% by mass to 30% by mass, and still more preferably from 1% by mass to 20% by mass with respect to the total mass of the solid content of the photopolymerizable composition including the metallic nanowires. In a case in which a pattern including a conductive area and a non-conductive area, which will be described below, is formed in the conductive layer in the above numeric range, a favorable sensitivity and a pattern formability may be obtained.

[(c) Binder]

The binder can be appropriately selected from alkali soluble resins which are linear organic macromolecular polymers and have at least one group that accelerates alkali solubility (for example, a carboxylic group, a phosphoric acid group, a sulfonic acid group, or the like) in molecules (preferably molecules including acrylic copolymers and styrene-based copolymers as the main chains).

Among the above, alkali soluble resins that are soluble in organic solvent and in alkali aqueous solutions are preferable, and alkali soluble resins that have an acid dissociable group and become soluble in alkali when the acid dissociable group is dissociated due to the action of an acid are particularly preferable. An acid value of the alkali soluble resin is preferably in a range of from 10 mgKOH/g to 250 mgKOH/g, and more preferably in a range of from 20 mgKOH/g to 200 mgKOH/g.

Here, the acid dissociable group refers to a functional group that can be dissociated in the presence of an acid.

In the production of the binder, for example, a method for which a well-known radical polymerization method is used can be applied. Polymerization conditions such as the temperature and pressure when an alkali soluble resin is produced using the radical polymerization method, the kind and amount of the radical initiator, and the kind of the solvent can be easily set by a person skilled in the art, and the conditions can be experimentally specified.

The linear organic macromolecular polymer is preferably a polymer having a carboxylic acid at a side chain.

Examples of the polymer having a carboxylic acid at a side chain include mathacrylic acid copolymers, acrylic acid copolymers, itaconic acid copolymers, crotonic acid copolymers, maleic acid copolymers, partially esterified maleic acid copolymers, and the like as described in the respective publications of JP-A No. S59-44615, JP-B No. S54-34327, JP-B No. 558-12577, JP-B No. S54-25957, JP-A No. S59-53836 and JP-A No. S59-71048, acidic cellulose derivatives having a carboxylic acid at a side chain, polymers obtained by adding an acid anhydride to a polymer having a hydroxy group, and, furthermore, macromolecular polymers having a (meth)acryloyl group at a side chain can also be included in preferable examples thereof.

Among the above, benzyl (meth)acrylate/(meth)acrylic acid copolymers and multi-component copolymers made of benzyl (meth)acrylate/(meth)acrylic acid/other monomers are particularly preferable.

Furthermore, macromolecular polymers having a (meth)acryloyl group at a side chain or multi-component copolymers made of (meth)acrylic acid/glycidyl (meth)acrylate/other monomers are also included in useful examples thereof. The polymers can be mixed in at an arbitrary amount and used.

In addition to the above, 2-hydroxypropyl (meth)acrylate/polystyrene macromonomer/benzyl methacrylate/methacrylic acid copolymer, 2-hydroxy-3-phenoxypropyl acrylate/polymethyl methacrylate macromonomer/benzyl methacrylate/methacrylic acid copolymer, 2-hydroxyethyl methacrylate/polystyrene macromonomer/methyl methacrylate/methacrylic acid copolymer, 2-hydroxyethyl methacrylate/polystyrene macromonomer/benzyl methacrylate/methacrylic acid copolymer, all of which are described in the publication of JP-A No. H7-140654, and the like are included in the useful examples.

Specific constituent unit of the alkali soluble resin is preferably a (meth)acrylic acid and other monomers that can be copolymerized with the (meth)acrylic acid.

Examples of the monomers that can be copolymerized with the (meth)acrylic acid include alkyl (meth)acrylates, aryl (meth)acrylates, vinyl compounds, and the like. In the monomers, the hydrogen atoms in the alkyl and aryl groups may be substituted by a substituent.

Examples of the alkyl (meth)acrylates or the aryl (meth)acrylates include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, dicyclopentanyl (meth)acrylate, dicyclopentenyl (meth)acrylate, dicyclopentenyloxyethyl (meth)acrylate, glycidyl methacrylate, tetrahydrofurfuryl methacrylate, polymethyl methacrylate macromonomer, and the like. The alkyl (meth)acrylate or the aryl (meth)acrylate may be solely used, or two or more may be used in a combination.

Examples of the vinyl compounds include styrene, α-methyl styrene, vinyl toluene, acrylonitrile, vinyl acetate, N-vinyl pyrrolidone, polystyrene macromonomers, CH₂═CR¹R² [here, R¹ represents a hydrogen atom or an alkyl group having 1 to 5 carbon atoms, and R² represents an aromatic hydrocarbon ring having 6 to 10 carbon atoms], and the like. The vinyl compound may be solely used, or two or more vinyl compounds may be used in a combination.

The weight average molecular weight of the binder is preferably from 1,000 to 500,000, more preferably from 3,000 to 300,000, and still more preferably from 5,000 to 200,000 from viewpoints of alkali dissolution rate, film properties and the like. Furthermore, the ratio of the weight average molecular weight to the number average molecular weight (Mw/Mn) is preferably from 1.00 to 3.00, and more preferably from 1.05 to 2.00.

Here, the weight average molecular weight is measured using gel permeation chromatography, and can be obtained using the standard polystyrene calibration curve.

A content of the binder of the component (c) in the conductive layer is preferably from 5% by mass to 90% by mass, more preferably from 10% by mass to 85% by mass, and still more preferably from 20% by mass to 80% by mass with respect to the total mass of the solid content of the photopolymerizable composition which includes the metallic nanowires. When the content is in the preferable range, both developability and the conduction of the metallic nanowires can be satisfied.

[(d) Additives Other than the Components (a) to (c)]

Examples of additives other than the components (a) to (c) include a variety of additives such as a chain-transfer agent, a crosslinking agent, a dispersant, a solvent, a surfactant, an antioxidant, a sulfuration inhibitor, a metal corrosion inhibitor, a viscosity adjuster, a preservative and the like.

(d-1) Chain Transfer Agent

The chain-transfer agent is used to improve the exposure sensibility of the photopolymerizable composition. Examples of the chain transfer agent include N,N-dialkylamino benzoic acid alkyl ester such as N,N-dimethylaminobenzoic acid ethyl ester; mercapto compounds having a heterocyclic ring such as 2-mercaptobenzothiazole, 2-mercaptobenzoxazole, 2-mercaptobenzimidazole, N-phenyl-mercaptobenzimidazole and 1,3,5-tris(3-mercaptobutyloxyethyl)-1,3,5-triazine-2,4,6(1H,3H,5H)-trione; aliphatic polyfuncational mercapto compounds such as pentaerythritol tetrakis(3-mercaptopropionate), pentaerythritol tetrakis(3-mercaptobutylate) and 1,4-bis(3-mercaptobutyloxy)butane; and the like. The chain transfer agent may be solely used, or two or more chain transfer agents may be used in a combination.

A content of the chain transfer agent in the conductive layer is preferably 0.01% by mass to 15% by mass, more preferably 0.1% by mass to 10% by mass, and still more preferably 0.5% by mass to 5% by mass with respect to the total mass of the solid content of the photopolymerizable composition which includes the metallic nanowires.

(d-2) Crosslinking Agent

The crosslinking agent is a compound that forms a chemical bond using a free radical or an acid and heat and cures the conductive layer. Examples thereof include melamine-based compounds, guanamine-based compounds, glycol uryl-based compounds, urea-based compounds, phenol-based compounds, ether compounds of phenol, which are substituted by at least one group selected from methylol groups, alkoxy methyl groups and acyloxy methyl groups, epoxy-based compounds, oxetane-based compounds, thioepoxy-based compounds, isocyanate-based compounds, azide-based compounds, compounds having an ethylenically unsaturated group including a methacryloyl group, an acryloyl group or the like, and the like. Among the above, epoxy-based compounds, oxetane-based compounds and compounds having an ethylenically unsaturated group are particularly preferable from viewpoints of film properties, heat resistance and solvent resistance.

In addition, the oxetane-based compound can be solely used, or can be used as a mixture with the epoxy-based compound. Particularly, a case in which the oxetane-based compound is used in a combination with the epoxy-based compound is preferable since the reactivity is high, and film properties improve.

Meanwhile, in a case in which the compound having an ethylenically unsaturated double-bonded group is used as the crosslinking agent, the crosslinking agent is also included in examples of the polymerizable compound (c), and thus the content thereof is also supposed to be included in the content of the polymerizable compound (c) in the invention.

The content of the crosslinking agent in the conductive layer is preferably from 1 part by mass to 250 parts by mass, and more preferably from 3 parts by mass to 200 parts by mass when the total mass of the solid content of the photopolymerizable composition including the metallic nanowires is 100 parts by mass.

(d-3) Dispersant

The dispersant is used in order to prevent the agglomeration of the metallic nanowires and to disperse the metallic nanowires in the photopolymerizable composition. The dispersant is not particularly limited as long as the dispersant can disperse the metallic nanowires, and can be appropriately selected depending on the purpose. For example, a commercially available dispersant can be used as a pigment dispersant, and a macromolecular dispersant having a property of being adsorbed to the metallic nanowires is particularly preferable. Examples of the macromolecular dispersant include polyvinyl pyrrolidones, BYK series (manufactured by BYK JAPAN K.K.), SOLSPERSE series (manufactured by the LUBRIZOL Corporation), AJISPER series (manufactured by AJINOMOTO Co., Inc.) and the like.

Meanwhile, in a case in which the macromolecular dispersant is further added separately as the dispersant in addition to the macromolecular dispersant used for the production of the metallic nanowires, the macromolecular dispersant is also included in examples of the binder of the component (c), and thus the content thereof is also supposed to be included in the content of the component (c).

A content of the dispersant is preferably from 0.1 parts by mass to 50 parts by mass, more preferably from 0.5 parts by mass to 40 parts by mass, and particularly preferably from 1 part by mass to 30 parts by mass with respect to 100 parts by mass of the binder of the component (c).

When the content of the dispersant is 0.1 parts by mass or more, the agglomeration of the metallic nanowires in the dispersion liquid is effectively suppressed, and, when the content is 50 parts by mass or less, stable liquid coats are fanned in a coating step, and the occurrence of coating unevenness is suppressed, which is preferable.

(d-4) Solvent

The solvent is a component used to form the photopolymerizable composition including the metallic nanowires into a coating liquid for a film shape on the surface of the base material, and can be appropriately selected depending on the purpose. Examples thereof include propylene glycol monomethyl ether, propylene glycol monomethyl ether acetate, ethyl 3-methoxypropionate, methyl 3-ethoxypropionate, ethyl lactate, 3-methoxybutanol, water, 1-methoxy-2-propanol, isopropyl acetate, methyl lactate, N-methylpyrrolidone (NMP), γ-butyrolactone (GBL), propylene carbonate and the like. The solvent may be solely used, or two or more solvents may be used in a combination.

A concentration of the solid content of the coating liquid including the solvent is preferably in a range of from 0.1% by mass to 20% by mass.

(d-5) Metal Corrosion Inhibitor

The photopolymerizable composition preferably contains a metal corrosion inhibitor of the metallic nanowires. The metal corrosion inhibitor is not particularly limited, and can be appropriately selected depending on the purpose. Preferable examples thereof include thiols, azoles and the like.

When the photopolymerizable composition contains the metal corrosion inhibitor, a superior antirust effect can be exhibited. The metal corrosion inhibitor can be supplied to compositions for forming photosensitive layers by being added in a state of being dissolved in an appropriate solvent or in a powder form, or by manufacturing a conductive film using a coating liquid for the conductive layer, which will be described below, and then immersing the conductive film in a metal corrosion inhibitor bath.

In a case in which the metal corrosion inhibitor is added, the metal corrosion inhibitor is preferably contained in from 0.5% by mass to 10% by mass with respect to the metallic nanowires.

Additionally, for the matrix, the macromolecular compound used as the dispersant when producing the metallic nanowires can be used as at least a part of components that form the matrix.

In the conductive layer in the invention, in addition to the metallic nanowires, other conductive materials such as fine conductive particles can be jointly used as long as the effects of the invention are not impaired, and, from the viewpoint of the effects, a proportion of the metallic nanowires having an aspect ratio of 10 or more is preferably 50% or more, more preferably 60% or more, and particularly preferably 75% or more in the composition for forming photosensitive layers by volume ratio. Hereinafter, the proportion of the metallic nanowires will be sometimes called “ratio of the metallic nanowires”.

When the ratio of the metallic nanowires is set to 50%, a dense network is formed among the metallic nanowires, and a conductive layer having a high conduction can be easily obtained. Particles having a shape other than metallic nanowires do not significantly contribute to conduction, in addition that the particles exhibit light absorption, which is not preferable. Particularly, in a case in which the conductive material is metal and made of spherical particles such that plasmon absorption is strong, there are cases in which transparency deteriorates.

Here, the ratio of the metallic nanowires can be obtained by, for example, in a case in which the metallic nanowires are silver nanowires, filtering a silver nanowire aqueous dispersion liquid so as to separate silver nanowires and other particles, and measuring the amount of silver remaining on filtration paper and the amount of silver that has penetrated the filtration paper respectively using an inductively coupled plasma (ICP) atomic emission spectrometer. The ratio of the metallic nanowires is detected by observing the metallic nanowires remaining on the filtration paper using a TEM, observing the short axis lengths of 300 metallic nanowires, and investigating the distribution thereof.

The method for measuring the average short axis length and average long axis length of the metallic nanowires is as described above.

The conductive layer can be formed on the base material using a general coating method, the method for forming the conductive layer on the base material is not particularly limited, and can be appropriately selected depending on the purpose. Examples thereof include a roll coating method, a bar coating method, a dip coating method, a spin coating method, a casting method, a die coating method, a blade coating method, a gravure coating method, a curtain coating method, a spray coating method, a doctor coating method and the like.

<<Intermediate Layer>>

At least one intermediate layer is preferably provided between the base material and the conductive layer. When the intermediate layer is provided between the base material and the conductive layer, it becomes possible to improve at least one of adhesion between the base material and the conductive layer, the light transmittance of the conductive layer, the haze of the conductive layer, and the film strength of the conductive layer.

Examples of the intermediate layer include an adhesive layer for improving the adhesive force between the base material and the conductive layer, a functional layer that improves functionality derived from interactions with the components included in the conductive layer, and the like, and any of the intermediate layers are appropriately provided depending on the purpose.

A material used for the intermediate layer is not particularly limited as long as the material improves at least any one of the above characteristics.

For example, in a case in which an adhesive layer is provided as the intermediate layer, examples of the material include polymers used for adhesives and materials selected from silane coupling agents, titanium coupling agents, sol-gel films obtained by hydrolyzing and polycondensing an alkoxide compound of Si, and the like.

In addition, it is preferable that the intermediate layer in contact with the conductive layer be a functional layer including a compound having functional groups that can interact with the metallic nanowires included in the conductive layer since conductive layers that are excellent in terms of light transmittance, inhibition of haze and film strength can be obtained.

The functional group in the functional layer including functional groups that can interact with the metallic nanowires is preferably, in a case in which the metallic nanowires are silver nanowires, at least one selected from a group consisting of amido groups, amino groups, mercapto groups, carboxylic acid groups, sulfonic acid groups, phosphate groups, phosphonic acid groups and salts thereof, more preferably an amino group, a mercapto group, a phosphate group, a phosphonic acid group or a salt thereof, and most preferably an amino group.

Another method for forming the conductive layer on the base material include a method in which a laminate for forming the conductive layer in which the conductive layer has been formed on the surface of a transfer base material is separately prepared, and the conductive layer in the laminate is transferred to an arbitrary surface of the base material.

The laminate for forming the conductive layer has a basic configuration in which the conductive layer is formed on the transfer base material as described above, but may have a configuration in which a cushion layer, the intermediate layer or both layers are formed in the above order between the transfer base material and the conductive layer, or a configuration in which a cover film may be further formed on the conducive layer.

The conductive layer can be formed on the surface of the transfer base material using the same method as the method for forming the conductive layer on the base material which has been described above.

<Transfer Base Material>

A shape, structure, size and the like of the transfer base material are not particularly limited, and can be appropriately selected depending on the purpose. Examples of the shape include a film shape, a sheet (film) shape, a plate shape and the like. Examples of the structure include a monolayer structure, a laminate structure and the like. The size thereof can be appropriately selected depending on the use and the like.

A material for the transfer base material is not particularly limited, and can be appropriately selected depending on the purpose. Examples thereof include transparent glass, synthetic resins, metal, ceramics, silicon wafers used as semiconductor substrates, and the like. On the surface of the transfer base material, as desired, a pretreatment such as a chemical treatment using a silane coupling agent, a plasma treatment, ion plating, sputtering, a gas-phase reaction or vacuum deposition may be carried out.

Examples of the transparent glass include white plate glass, blue plate glass, silica-coated blue plate glass, and the like. In the case of a transfer base material for which the transparent glass has been used, the transfer base material may be a thin layer glass plate having a thickness of 10 μm to several hundreds μm.

Examples of the synthetic resins include polyethylene terephthalate (PET), polycarbonates, triacetyl celluloses (TAC), polyether sulfones, polyesters, acrylic resins, vinyl chloride resins, aromatic polyamide resins, polyamide-imides, polyimides and the like.

Examples of the metal include aluminum, copper, nickel, stainless steel and the like.

Visible light transmittance of the transfer base material is preferably 70% or more, more preferably 85% or more, and still more preferably 90% or more. When the visible light transmittance is less than 70%, there are cases in which the transmittance is low such that practical problems are caused.

Meanwhile, in the invention, transfer base materials colored within the scope of the purpose of the invention can be also used.

An average thickness of the transfer base material is not particularly limited, and can be appropriately selected depending on the purpose. The average thickness is preferably from 1 μm to 500 μm, more preferably from 3 μm to 400 μm, and still more preferably from 5 μm to 300 μm.

When the average thickness is in the above range, the transfer base material is favorably handled, and excellent in terms of flexibility so that transfer uniformity becomes favorable.

<Cushion Layer>

The laminate for forming the conductive layer may include a cushion layer between the transfer base material and the conductive layer in order to improve transfer properties. A shape, structure, size and the like of the cushion layer are not particularly limited, and can be appropriately selected depending on the purpose. Examples of the shape include a film shape, a sheet shape, and the like.

Examples of the structure include a monolayer structure, a laminate structure and the like, and the size and thickness can be appropriately selected depending on the use and the like.

The cushion layer is a layer that plays a role of improving the transfer properties with transfer targets, contains at least a polymer, and further contains other components as necessary.

The polymer used in the cushion layer is not particularly limited as long as the polymer is a thermoplastic resin that softens during heating, and can be appropriately selected depending on the purpose. Examples thereof include acrylic resins, styrene-acryl copolymers, polyvinyl alcohols, polyethylene, ethylene-vinyl acetate copolymers, ethylene-ethyl acrylate copolymers, ethylene-methacrylic acid copolymers; gelatin; cellulose esters such as cellulose nitrate, cellulose triacetate, cellulose diacetate, cellulose acetate butyrate, cellulose acetate propionate; homopolymers or copolymers including vinylidene chloride, vinyl chloride, styrene, acrylonitrile, vinyl acetate, alkyl (having 1 to 4 carbon atoms) acrylate, vinyl pyrrolidone or the like; soluble polyesters, polycarbonates, soluble polyamides and the like. The polymer may be solely used, or two or more polymers may be used in a combination.

The polymer used in the cushion layer is preferably a thermoplastic resin that is softened by heating. The glass transition temperature of the cushion layer is preferably from 40° C. to 150° C. When the glass transition temperature is lower than 40° C., there are cases in which the polymer becomes too soft at room temperature such that the handling properties deteriorate, and when the glass transition temperature is higher than 150° C., there are cases in which the cushion layer does not soften in a heat laminate manner, and the transfer properties of the conductive layer deteriorate. In addition, the glass transition temperature may be adjusted through addition of a plasticizer or the like.

Other components that can be included in the cushion layer are not particularly limited, and can be appropriately selected depending on the purpose. Examples of the components include a variety of additive such as filler, a surfactant, an antioxidant, a sulfuration inhibitor, a metal corrosion inhibitor, a viscosity adjuster, a preservative and the like. In addition, the examples include organic macromolecular substances described in Paragraph [0007] and later in JP-A No. 115-72724, a variety of plasticizers for adjusting the adhesive force with the transfer base material, supercooled substances, an adhesion promotor, a surfactant, a mold release agent, a thermopolymerization inhibitor, a solvent and the like.

The cushion layer can be formed by coating a coating liquid for the cushion layer containing the polymer and, as necessary, the above other components on the transfer base material, and drying the coating liquid.

An average thickness of the cushion layer is preferably from 1 μm to 50 μm, more preferably from 1 μm to 30 μm, and more preferably from 5 μm to 20 μm. When the average thickness of the cushion layer is in the above range, uniform transfer properties can be obtained, and the curl balance of transfer materials becomes favorable.

Furthermore, the ratio (S/N) of the total average thickness S of the conductive layer and the cushion layer to the average thickness N of the transfer base material preferably satisfies the following Formula (4).

S/N=0.01 to 0.7 Formula (4)

S/N is more preferably in a range of from 0.02 to 0.6. When S/N is set to 0.01 or more, the transfer uniformity to transfer targets becomes favorable, and, when S/N is set to 0.7 or less, the curl balance become favorable.

The conductive member preferably includes the intermediate layer in a case in which the conductive layer contains a photoresist composition as the matrix. The intermediate layer is preferably made of a polyvinyl alcohol, a polyvinyl pyrrolidone or the like, and the thickness thereof is appropriately in a range of from 0.1 μm to 5 μm.

Since the conductive member in the invention includes the protective layer having a three-dimensional crosslinked structure represented by the Formula (I), the conductive member exhibits high resistance against scratches and abrasion even when a thickness of the conductive layer is thin. Specifically, the film thickness (average thickness) of the conductive layer is preferably from 0.005 μm to 0.5 μm, more preferably from 0.007 μm to 0.3 μm, more preferably from 0.008 μm to 0.2 μm, and still more preferably from 0.01 μm to 0.1 μm. When the film thickness of the conductive layer is set in a range of from 0.001 μm to 5.0 μm, sufficient durability and a sufficient film strength can be obtained, and, furthermore, conductive fibers in the non-conductive area can be fully removed when the conductive member having a non-patterned conductive layer is patterned into conductive portions and non-conductive portions. Particularly, when the film thickness is set in a range of from 0.01 μm to 0.1 μm, a production allowance range is ensured, which is preferable.

In addition, it is preferable to adjust the amount of the metallic nanowires included in the conductive layer depending on the kind of the metallic nanowires so that the desired values of the surface resistivity, light transmittance and haze of the conductive member can be obtained. For example, in the case of silver nanowires, the amount of the metallic nanowires is selected from a range of from 0.001 g/m² to 0.100 g/m², preferably from 0.002 g/m² to 0.050 g/m², and more preferably from 0.003 g/m² to 0.040 g/m².

A cover film is provided for the purpose of protecting the conductive layer from being contaminated or damaged when the laminate for forming the conductive layer is handled as a single body. The cover film is detached before the laminate is laminated on the base material.

Preferable examples of the cover film include polyethylene films, polypropylene films and the like, and a thickness thereof is appropriately in a range of from 20 μm to 200 μm.

<Shape of the Conductive Layer>

When observed from a vertical direction to the surface of the base material, the shape of the conductive member in the invention may be any one of a first aspect in which the entire area of the conductive layer is a conductive area (hereinafter, the conductive layer will be also called “non-patterned conductive layer”) and a second aspect in which the conductive layer includes a conductive area and a non-conductive area (hereinafter, the conductive layer will be also called “patterned conductive layer”). In the case of the second aspect, the metallic nanowires may or may not be included in the non-conductive area. In a case in which the metallic nanowires are included in the non-conductive area, the metallic nanowires included in the non-conductive area are not connected to each other.

The conductive member according to the first aspect may be used as, for example, transparent electrodes for solar cells.

In addition, the conductive member according to the second aspect may be used in a case in which, for example, tough panels are manufactured. In this case, the conductive area and the non-conductive area are formed in desired shapes.

[Conductive Layer Including the Conductive Area and the Non-Conductive Area (Patterned Conductive Layer)]

The patterned conductive layer is produced using, for example, the following patterning method.

(1) A patterning method in which a non-patterned conductive layer is formed in advance, high-energy laser rays such as carbonate gas laser or YAG laser are radiated on metallic nanowires included in desired areas in the non-patterned conductive layer so as to cut or remove some of the metallic nanowires, thereby forming a non-conductive area in the desired areas. This method is described in, for example, JP-A No. 2010-4496.

(2) A patterning method in which a photoresist layer is provided on a previously-formed non-patterned conductive layer, desired pattern exposure and development are carried out on the photoresist layer so as to form a resist in the pattern, and then a wet process for treating the resist using an etchant (etching liquid) that can etch metallic nanowires is carried out, or metallic nanowires in the conductive layer not protected by the resist are etched and removed using a dry process such as reactive ion etching. This method is described in, for example, Japanese Patent National Phase Publication No. 2010-507199 (particularly, Paragraphs [0212] to [0217]).

(3) A patterning method in which a conductive layer including metallic nanowires and a photoresist composition as a matrix is formed, the conductive layer is exposed in a desired pattern and, subsequently, developed using a development liquid for the photoresist so as to remove the photoresist composition in a non-conductive area (in the case of a positive-type photoresist, an exposed area during the pattern exposure, and, in the case of a negative-type photoresist, a non-exposed area during the pattern exposure), metallic nanowires present in the non-conductive area are put into an exposed state in which the metallic nanowires are not protected by the photoresist composition (when considered in a metallic nanowire, the exposed state is a state of minutely-exposed areas in which a portion of the metallic nanowire is exposed), and then the metallic nanowires are treated using flowing water, high-pressure water washing or an etchant that can etch the metallic nanowires, thereby cutting the portions of the metallic nanowires present in the non-conductive area in the exposed state.

The patterning methods of the above (1) to (3) can be applied to any of non-patterned conductive layers on the base material and non-patterned conductive layers on the transfer base material.

Furthermore, in any of the above cases, the patterning method may be applied before the protective layer described below is formed or after the formation of the protective layer, but the patterning method is advantageously carried out before the protective layer is formed since target conductive members according to the second aspect can be produced at a low cost with a high yield.

Meanwhile, in a case in which the formation of the patterned conductive layer is carried out on the transfer base material, the patterned conductive layer is transferred onto the base material.

A light source used for the pattern exposure is selected in consideration of the photosensitive range of the photoresist composition, and, in general, ultraviolet rays such as g rays, h rays, i rays or j rays are preferably used. In addition, a blue LED may be used.

The pattern exposure method is also not particularly limited, and may be carried out through surface exposure using a photomask or through scanning exposure using laser beams or the like. At this time, the pattern exposure method may be refraction exposure using a lens or reflection exposure using a reflecting mirror, and exposure methods such as contact exposure, proximity exposure, reduction projection exposure, and reflection projection exposure can be used.

As the development liquid, an appropriate liquid is selected depending on the photoresist composition. For example, in a case in which the photoresist composition is a photopolymerizable composition containing an alkali-soluble resin as a binder, an alkali aqueous solution is preferable.

The alkali included in the alkali aqueous solution is not particularly limited, and can be appropriately selected depending on the purpose. Examples thereof include tetramethylammonium hydroxide, tetraethylammonium hydroxide, 2-hydroxyethyltrimethylammonium hydroxide, sodium carbonate, sodium hydrogen carbonate, potassium carbonate, potassium hydrogen carbonate, sodium hydroxide, potassium hydroxide and the like.

Methanol, ethanol or a surfactant may be added to the development liquid for the purpose of the reduction of development residue or the optimization of pattern shapes. The surfactant can be selected from, for example, anionic surfactants, cationic surfactants and nonionic surfactants. Among the above, when a nonionic polyoxyethylene alkyl ether is added, resolution increases, which is preferable.

The supply method using the alkali solution is not particularly limited, and can be appropriately selected depending on the purpose. Examples thereof include coating, immersion, spraying and the like. Specific examples include dip development in which a base material or substrate having an exposed photosensitive layer is immersed in an alkali solution, paddle development in which a development liquid is stirred during immersion, shower development in which a development is made to flow using shower or spraying, a development method in which a surface of a photosensitive layer is rubbed using sponge, a fiber lump or the like soaked with an alkali solution, and the like. Among the above, the method in which a base material is immersed in an alkali solution is particularly preferable.

The immersion time of the alkali solution is not particularly limited, and can be appropriately selected depending on the purpose, but is preferably from 10 seconds to 5 minutes.

Furthermore, as a patterning method (4) other than the methods (1) to (3), in which the protective layer described below is farmed on a non-patterned conductive layer, and then the non-patterned conductive layer is formed into a patterned conductive layer, there is a method in which a solution that dissolves the metallic nanowires is supplied in a pattern shape to a conductive film from the top of the protective layer, and metallic nanowires present in the conductive layer in areas to which the solution has been supplied are cut, thereby forming a non-conductive area.

The solution that dissolves the metallic nanowires can be appropriately selected depending on the kind of metallic nanowires. For example, in a case in which the metallic nanowires are silver nanowires, a bleach-fixing solution, a strong acid, an oxidant, hydrogen peroxide or the like which are mainly used in the bleaching and fixing step of photographic paper of silver halide color photosensitive materials in the so-called photographic science field can be selected. Among the above, a bleach-fixing solution, diluted nitric acid, and hydrogen peroxide are particularly preferable. Meanwhile, in the dissolution of silver nanowires using the solution that dissolves the metallic nanowires, silver nanowires in portions to which the solution has been supplied may not be fully dissolved, and some of the silver nanowires may remain if the remaining silver nanowires are not conductive.

A concentration of the diluted nitric acid is preferably from 1% by mass to 20% by mass.

A concentration of the hydrogen peroxide is preferably from 3% by mass to 30% by mass.

As the bleach-fixing solution, treatment materials or treatment methods described in, for example, Row 1 in the lower right column on Page 26 to Row 9 in the upper right column on Page 34 in JP-A No. H2-207250 and Row 17 in the upper left column on Page 5 to Row 20 in the lower right column on Page 18 in JP-A No. H4-97355 can be preferably applied.

A bleach-fixing time is preferably 180 seconds or less, practically more preferably from 1 second to 120 seconds, practically more preferably from 2 seconds to 60 seconds, and practically most preferably from 5 seconds to 30 seconds. In addition, the water washing or stabilizing time is preferably 180 seconds or less, and more preferably from 1 second to 120 seconds.

The bleach-fixing liquid is not particularly limited as long as the bleach-fixing liquid is for photographic use, and can be appropriately selected depending on the purpose. Examples thereof include CP-48S, CP-49E (all trade name, bleach-fixing agents for color paper) manufactured by FUJIFILM Corporation, EKTACOLOR RA; trade name, bleach-fixing solution manufactured by KODAK Corporation, bleach-fixing solutions D-J2P-02-P2, D-30P2R-01, D-22P2R-01; all trade name, manufactured by DAI NIPPON PRINTING Co., Ltd. and the like. Among the above, CP-48S and CP-49E are particularly preferable.

A viscosity of the solution that dissolves the metallic nanowires is preferably from 5 mPa·s to 300,000 mPa·s, and more preferably from 10 mPa·s to 150,000 mPa·s at 25° C. When the viscosity is set to 5 mPa·s, it becomes easy to control the diffusion of the solution in a desired range so that formation of a pattern having a clear boundary between a conductive area and a non-conductive area is ensured, and, on the other hand, when the viscosity is set to 300,000 mPa·s or less, it is possible to ensure the printing of the solution with no load and to adjust the treatment time necessary for the dissolution of the metallic nanowires in a desired time range.

A method for supplying the solution that dissolves the metallic nanowires in a pattern shape is not particularly limited as long as the solution can be supplied in a pattern shape, and can be appropriately selected depending on the purpose. Examples thereof include screen printing, ink jet printing, methods in which an etching mask is formed in advance using a resist agent or the like, and the solution is coater-coated, roller-coated, dip-coated or spray-coated on the etching mask, and the like. Among the above, screen printing, ink jet printing, coater coating and dip (immersion) coating are particularly preferable.

As the ink jet printing, for example, any of piezo methods and thermal methods can be used.

In a case in which the conductive layer is patterned using the patterning method (4), the following member is preferable as the conductive member that has not yet been patterned due to excellent patterning performance.

That is, the conductive member is preferably a conductive member which has a surface resistivity of 10⁸Ω/□ or more after the immersion and a haze difference, which is a degree of reduction from the haze before the immersion to the haze after the immersion, of 0.4% or more, and maintains the protective layer after the immersion when immersed in an etchant having the following composition at 25° C. for 120 seconds.

The composition of the etchant: an aqueous solution containing ferric ammonium ethylenediamine tetraacetate (2.5% by mass), ammonium thiosulfate (7.5% by mass), ammonium sulfite (2.5% by mass) and ammonium bisulfite (2.5% by mass)

The etchant is a representative etchant used to dissolve silver nanowires in the conductive layer so as to make the conductive layer be non-conductive. In a case in which the conductive layer is etched using the etchant, it can be confirmed that the conductive layer becomes non-conductive from the surface resistivity of the conductive member after the etching becoming 10⁸Ω/□ or more. Furthermore, it can be confirmed that the silver nanowires present in the conductive layer are dissolved and removed from the haze difference, which is a degree of reduction from the haze before the immersion to the haze after the immersion, of 0.4% or more. Therefore, it can be confirmed that, when both requirements are satisfied, the conductive layer can be said to be “non-conductive”. In addition, when the protective layer is not removed even after the immersion treatment, a conductive member that is also excellent in terms of scratch and abrasion resistance can be obtained.

Therefore, regarding the treatment time for making the conductive layer in the conductive member be non-conductive, in a case in which the conductive member is immersed in the etchant at 25° C. for 120 seconds, if the surface resistivity of the conductive member is 10⁸Ω/□ or more, the haze difference, which is a degree of reduction from the haze before the immersion to the haze after the immersion, is 0.4% or more, and the protective layer is not removed after the immersion, it can be said that the above parameters mean that a conductive patterned member that is excellent in terms of patterning properties and is excellent in twins of scratch and abrasion resistance is obtained.

A kind of the pattern is not particularly limited, and can be appropriately selected depending on the purpose. Examples thereof include letters, symbols, designed patterns, figures, wiring patterns and the like.

A size of the pattern is not particularly limited, can be appropriately selected depending on the purpose, and may be any one in a range of nanometer size to millimeter size.

<<Protective Layer>>

The protective layer in the conductive member in the invention includes a three-dimensional crosslinked structure represented by the following Formula (I).

-M¹-O-M¹- Formula (I):

(In the Formula (I), M′ represents an element selected from a group consisting of Si, Ti, Zr and Al.)

The protective layer is preferably made of a cured sol-gel substance obtained by hydrolyzing, polycondensing, furthermore, if desired, heating and drying an alkoxide compound of an element selected from a group consisting of Si, Ti, Zr and Al (hereinafter, also referred to as “specific alkoxide compound”) since conductive members that are excellent in terms of conduction and transparency and are excellent in terms of film strength, abrasion resistance, heat resistance, moisture and heat resistance and bendability can be easily produced.

Here, the valence of M¹ included in the three-dimensional crosslinked structure including the bond represented by the Formula (I) becomes 4 in a case in which M¹ in the Formula (I) is any one of Si, Ti and Zr, and becomes 3 in a case in which M′ is Al.

M¹ in the Formula (I) is preferably selected from Si, Ti and Zr, and is more preferably Si.

[Specific Alkoxide Compound]

The specific alkoxide compound is preferably at least one compound selected from a group consisting of compounds represented by the Formula (II) and compounds represented by the Formula (III) which have been described in the description of the matrix in the conductive layer due to easy procurement. In addition, specific examples of the compounds represented by the Formula (II) and the compounds represented by the Formula (III) have been also described in the description of the matrix in the conductive layer, and thus will not be described again.

Furthermore, both M² in the Formula (II) and M³ in the Formula (III) are preferably Si.

Preferable examples of the specific alkoxide compound include tetramethoxysilane, tetraethoxysilane, tetrapropoxy titanate, tetraisopropoxy titanate, tetraethoxy zirconate, tetrapropoxy zirconate, 3-glycidoxypropyltrimethoxysilane, 2-(3,4-epoxycyclohexyl)ethyl trimethoxysilane, ureidopropyltriethoxysilane, diethyldiethoxysilane, propyl triethoxy titanate, ethyl triethoxy zirconate, and the like.

The protective layer is formed by coating an aqueous solution including the specific alkoxide compound as a coating liquid (hereinafter, also referred to as “sol-gel coating liquid”) on the conductive layer (the conductive layer may be any one of a case in which the entire area of the conductive layer is conductive and a case in which the conductive layer includes a conductive area and a non-conductive area) provided on the base material so as to form a coating liquid film, causing reactions of the hydrolysis and polycondensation of the specific alkoxide compound in the coating liquid film, and, furthermore, as necessary, heating and evaporating water which is used as a solvent, thereby drying the coating liquid film.

A use of an acidic catalyst or a basic catalyst in order to accelerate the hydrolysis and polycondensation reaction is practically preferable since the reaction efficiency can be increased. Since the catalysts that accelerate the reactions of the hydrolysis and polycondensation of the alkoxide compound which have been described for the cured sol-gel substance as the matrix in the conducive layer can be used as the catalyst, and, herein, the catalyst will not be described.

The specific alkoxide compound is heated in the sol-gel coating liquid in the presence of the catalyst so as to be hydrolyzed, but a dehydration polycondensation reaction also partially proceeds, thereby forming a partial condensate. The weight average molecular weight (Mw) of the partial condensate can be measured using GPC, and the weight average molecular weight (Mw) of the partial condensate of the specific alkoxide compound is preferably in a range of from 4,000 to 90,000, more preferably in a range of from 9,600 to 90,000, and most preferably in a range of from 37,000 to 87,000. When the weight average molecular weight (Mw) of the partial condensate of the specific alkoxide compound is in a range of from 4,000 to 90,000, conductive fibers in non-conductive portions can be removed with no residue in patterning the conductive member including a non-patterned conductive layer into conductive portions and non-conductive portions, and, when the weight average molecular weight is in a range of from 37,000 to 87,000, the etching time can be shortened. The reason why conductive members that are excellent in terms of etchability can be obtained is not clear, but conductive members are assumed to be obtained for the following reason.

The specific alkoxide compound is partially dehydrated and polycondensated in the sol-gel coating liquid, thereby forming partial condensates. The partial condensates form three-dimensional bonds at a certain proportion and turn into fine particles in the sol-gel coating liquid. When the sol-gel coating liquid is coated and a film is formed, films having a low crosslinking density are formed, and the crosslinking density decreases as the weight average molecular weight of the partial condensate increases. When a protective layer having a low crosslinking density is formed, since an etchant can easily intrude, conductive members having excellent etchability can be provided. For the above reason, conductive members that are excellent in terms of film strength, abrasion resistance and etchability can be provided by setting the weight average molecular weight (Mw) of the partial condensate of the specific alkoxide compound in the above range.

[Solvent]

The sol-gel coating liquid for forming the protective layer may contain an organic solvent as desired in order to ensure the uniform formability of coating liquid films on the conductive layer.

Examples of the organic solvent include ketone solvents such as acetone, methyl ethyl ketone and diethyl ketone; alcohol-based solvents such as methanol, ethanol, 2-propanol, 1-propanol, 1-butanol and tert-butanol; chlorine-based solvents such as chloroform and methylene chloride; aromatic solvents such as benzene and toluene; ester-based solvents such as ethyl acetate, butyl acetate, and isopropyl acetate; ether-based solvents such as diethyl ether, tetrahydrofuran and dioxane; glycol ether-based solvents such as ethylene glycol monomethyl ether and ethylene glycol dimethyl ether; and the like.

In this case, the addition of the organic solvent is effective as long as volatile organic solvent (VOC)-related problems do not occur, and the organic solvent is added in a range of preferably 50% by mass or less and more preferably 30% by mass or less with respect to the total mass of the sol-gel coating liquid.

In the coating liquid film of the sol-gel coating liquid formed on the conductive layer, the hydrolysis and condensation reaction of the specific alkoxide compound is caused, and the coating liquid film is preferably heated and dried in order to accelerate the reaction. The heating temperature for accelerating the sol-gel reaction is appropriate in a range of from 30° C. to 200° C., and more preferably in a range of from 50° C. to 180° C. The heating and drying time is preferably from 10 seconds to 300 minutes, and more preferably from 1 minute to 120 minutes.

A thickness of the protective layer in the invention is preferably from 0.001 μm to 0.5 μm, more preferably from 0.002 μm to 0.3 μm, even more preferably from 0.003 μm to 0.25 μm, and still more preferably from 0.005 μm to 0.2 μm. When the thickness is set in a range of from 0.001 μm to 0.5 sufficient durability and a sufficient film strength can be obtained, dense films that are absent of defects as the protective layer can be obtained, and, furthermore, conductive fibers in the non-conductive area can be fully removed when the conductive member having a non-patterned conductive layer is patterned into conductive portions and non-conductive portions. Particularly, when the thickness is set in a range of from 0.005 μm to 0.2 μm, a production allowance range is ensured, which is preferable.

The conductive member in the invention is excellent in terms of the transparency of the conductive layer. Here, transparency is evaluated using light transmittance and haze, the light transmittance is measured based on JIS K 7361-1:1997, and the haze is measured based on JIS K 7165:1981.

The conductive member in the invention is adjusted so that the surface resistivity becomes 1,000Ω/□ or less.

The surface resistivity is a value obtained by measuring the surface of the protective layer on the opposite side to the base material side in the conductive member in the invention using a four-point probe method. The method for measuring the surface resistivity using the four-point probe method can be carried out based on JIS K 7194:1994 (Testing method for resistivity of conductive plastics with a four-point probe array) and the like, and the surface resistivity can be easily measured using a commercially available surface resistivity meter. In order to set the surface resistivity to 1,000Ω/□ or less, it is necessary to adjust at least one of the kind and content of the metallic nanowires in the conductive layer and the kind and content of the matrix.

The surface resistivity of the conductive member in the invention is more preferably in a range of from 0.1Ω/□ to 900 Ω/□.

The conductive member in the invention has excellent abrasion resistance. The abrasion resistance can be evaluated using, for example, the following method (1) or (2).

(1) When an abrasion resistance test in which a surface of the conductive layer is reciprocally rubbed 50 times with a load of 500 g using a continuous loading scratching intensity tester (for example, a continuous loading scratching intensity tester type 18s manufactured by SHINTO SCIENTIFIC Co., Ltd.) and a 20 mm×20 mm-sized gauze piece (for example, FC gauze manufactured by HAKUJUJI Co., Ltd.) is carried out, a ratio of the surface resistivity (Ω/□) of the conductive layer after the abrasion resistance test to the surface resistivity (Ω/□) of the conductive layer before the abrasion resistance test is 100 or less, more preferably 50 or less, and still more preferably 20 or less.

(2) When a bending test is carried out on the conductive member 20 times on a cylindrical mandrel having a diameter of 10 mm using a cylindrical mandrel bending tester (for example, a bending test manufactured by COTEC Corporation), a ratio of the surface resistivity (Ω/□) of the conductive layer after the bending test to the surface resistivity (SZP) of the conductive layer before the bending test is 2.0 or less, more preferably 1.8 or less, and still more preferably 1.5 or less.

When having the protective layer including the bond represented by the Formula (I), the conductive member in the invention exhibits a unique effect of a low surface resistivity compared with conductive members which have no protective layer and only have the conductive layer on the base material.

The reason is not clear, but it is assumed that, since the protective layer including the bond represented by the Formula (I) has a high crosslinking density, the conductive member which has a high film strength even when the film thickness is thin, is excellent in terms of abrasion resistance, and is excellent in terms of heat resistance and moisture and heat resistance can be obtained. Furthermore, since the protective layer has a thin film thickness, it is assumed that conductive members that are excellent in terms of conduction and transparency, and also excellent in terms of bending resistance can be obtained. Particularly, in a case in which the protective layer in the invention includes the cured sol-gel substance obtained by coating an aqueous solution including the specific alkoxide compound as a coating liquid on the conductive layer, and hydrolyzing and polycondensing the specific alkoxide compound included in in the coating liquid film, conductive members are considered to exhibit effects of superior conduction and transparency, excellent abrasion resistance, heat resistance, and moisture and heat resistance, and, at the same time, excellent bending resistance.

In addition, in a case in which the protective layer includes the cured sol-gel substance obtained by hydrolyzing and polycondensing a substance including at least one of the compounds represented by the Formula (II) and at least one of the compounds represented by the Formula (III), compared with the protective layer including the cured sol-gel substance obtained by hydrolyzing and polycondensing at least one of the compounds represented by the Formula (II), since the crosslinking density of the protective layer including the bonds represented by the Formula (I) is adjusted to be in an appropriate range, conductive members become appropriately flexible, and, consequently, it is considered that the conductive members having superior bending resistance can be obtained. In addition, the conductive members have well-balanced transmittance of substances such as oxygen, ozone, moisture and the like so that it is considered that conductive members having excellent heat resistance and moisture and heat resistance can be obtained. As a result, for example, in a case in which the conductive member is used in touch panels, the occurrence of malfunction is reduced while handling touch panels, and the yield can be improved so that tough panels can be freely bent, and the aptitude for the conductive member to be processed into 3D tough panel displays, spherical displays, and the like can be supplied.

The conductive member in the invention is excellent in terms of transparency, abrasion resistance, heat resistance, moisture and heat resistance and bending resistance, and also has a low surface resistivity, and thus can be widely applied to tough panels, display electrodes, electromagnetic wave shields, organic EL display electrodes, inorganic EL display electrodes, electronic paper, flexible display electrodes, integrated solar cells, liquid crystal displays, touch panel function-embedded display apparatuses, and a variety of other devices. Among the above, the conductive member is particularly preferably applied to touch panels and solar cells.

<<Touch Panel>>

The conductive member in the invention is applied to, for example, surface capacitive-type touch panels, projected capacitive-type touch panels, resistive-type touch panels and the like. Here, examples of the touch panel include so-called touch sensors and touch pads.

A layer configuration of the touch panel sensor electrode portion in the touch panel is preferably any of an attachment method in which two transparent electrodes are attached, a method in which transparent electrodes are provided on both surfaces of a base material, a single surface jumper or through hole method, and a single surface lamination method.

The surface capacitive-type touch panels are described in, for example, Japanese Patent National Phase Publication No. 2007-533044.

<<Solar Cell>>

The conductive member in the invention is useful as a transparent electrode in integrated solar cells (hereinafter, also referred to as solar cell devices).

The integrated solar cell is not particularly limited, and solar cells that are generally used as solar cell devices can be used. Examples thereof include single crystalline silicon-based solar cell devices, polycrystalline silicon-based solar cell devices, amorphous silicon-based solar cell devices configured in a single junction, tandem structure or the like, semiconductor solar cell devices of Group III-V compounds such as gallium arsenide (GaAs) or indium phosphide (InP), semiconductor solar cell devices of Group II-VI compounds such as cadmium telluride (CdTe), semiconductor solar cell devices of Group compounds such as copper/indium/selenium-based compounds (so-called CIS-based compounds), copper/indium/gallium/selenium-based compounds (so-called GIGS-based compounds) and copper/indium/gallium/selenium/sulfur-based compounds (so-called CIGSS-based compounds), dye-sensitized solar cell devices, organic solar cell devices, and the like. Among the above, in the invention, the solar cell device is preferably an amorphous silicon-based solar cell device configured in a tandem structure or the like, or a semiconductor solar cell device of Group compounds such as copper/indium/selenium-based compounds (so-called CIS-based compounds), copper/indium/gallium/selenium-based compounds (so-called GIGS-based compounds) and copper/indium/gallium/selenium/sulfur-based compounds (so-called CIGSS-based compounds).

In the case of the amorphous silicon-based solar cell configured in a tandem structure or the like, amorphous silicon, a fine crystalline silicon thin film layer, a thin film including Ge in amorphous silicon or a fine crystalline silicon thin film layer, or, furthermore, two or more layers of the above in a tandem structure is used as a photoelectric conversion layer. Films thereof are formed using plasma CVD or the like.

The conductive member in the invention can be applied to all of the above solar cell devices. The conductive member may be included in any portion of the solar cell device, but is preferably included so that the conductive layer or the protective layer is disposed adjacent to the photoelectric conversion layer. The positional relationship with the photoelectric conversion layer is preferably one of the following configurations, but is not limited thereto. In addition, the following configurations do not describe all portions of the solar cell device, and describe portions as simply as the positional relationship of the transparent conductive layer can be clear. Here, configurations included in parenthesis correspond to the conductive member in the invention.

(A) [base material-conductive layer-protective layer]-photoelectric conversion layer

(B) [base material-conductive layer-protective layer]-photoelectric conversion layer-[protective layer-conductive layer-base material]

(C) substrate-electrode-photoelectric conversion layer-[protective layer-conductive layer-base material]

(D) rear surface electrode-photoelectric conversion layer-[protective layer-conductive layer-base material]

The details of the above solar cell are described in, for example, JP-A No. 2010-87105.

### EXAMPLES

Hereinafter, examples of the invention will be described, but the invention is not limited to the examples. Meanwhile, “%” and “parts” in the examples, which indicate content rates, are all by mass.

In the following examples, the average diameter (average short axis length) and average long axis length of metallic nanowires, the coefficient of variation of the short axis length, and the proportion of silver nanowires having an aspect ratio of 10 or more were measured in the following manners.

<The Average Diameter (Average Short Axis Length) and Average Long Axis Length of Metallic Nanowires>

The diameters (short axis lengths) and long axis lengths of 300 metallic nanowires randomly selected from metallic nanowires magnified using a transmission electron microscope (TEM, JEM-2000FX; trade name, manufactured by JELO Ltd.) were measured, and the average diameter (average short axis length) and average long axis length of the metallic nanowires was obtained from the average values.

<The Coefficient of Variation of the Short Axis Length (Diameter) of the Metallic Nanowires>

The short axis lengths (diameters) of 300 nanowires randomly selected from the transmission electron microscopic (TEM) image were measured, and a standard deviation and an average value of the 300 nanowires were computed, thereby obtaining the coefficient of variation.

<The Proportion of Silver Nanowires Having an Aspect Ratio of 10 or More>

The short axis lengths of 300 silver nanowires were observed using a transmission electron microscope (TEM, JEM-2000FX; trade name, manufactured by JELO Ltd.), the amount of silver that had penetrated filtration paper was measured, and silver nanowires having a short axis length of 50 nm or less and a long axis length of 5 μm or more were obtained as the proportion (%) of silver nanowires having an aspect ratio of 10 or more.

Meanwhile, when the ratio of the silver nanowires was obtained, the silver nanowires were separated using a membrane filter (FALP 02500; trade name, manufactured by NIHON MILLIPORE K.K., pore diameter of 1.0 μm).

[Abbreviation for Synthesis Examples]

The meanings of the abbreviations for components used in the following synthesis examples are as follows.

AA: acrylic acid

MAA: methacrylic acid

MMA: methyl methacrylate

CHMA: cyclohexyl methacrylate

St: styrene

GMA: glycidyl methacrylate

DCM: dicyclopentanyl methacrylate

BzMA: benzyl methacrylate

AIBN: azobisisobutyronitrile

PGMEA: propylene glycol monomethyl ether acetate

MFG: 1-methoxy-2-propanol

THF: tetrahydrofuran

### Synthesis Example 1

<The Synthesis of a Binder (A-1)>

AA (9.64 g) and BzMA (35.36 g) were used as monomer components that form a copolymer, AIBN (0.5 g) was used as a radical polymerization initiator, and AA, BzMA and AIBN were made to cause a polymerization reaction in a solvent PGMEA (55.00 g), thereby obtaining a PGMEA solution (solid content concentration: 45% by mass) of a binder (A-1). Meanwhile, the polymerization temperature was adjusted to a temperature of from 60° C. to 100° C.

As a result of measuring the molecular weight using gel permeation chromatography (GPC), the weight average molecular weight (Mw) in terms of polystyrene was 11,000, the molecular weight distribution (Mw/Mn) was 1.72, and the acid value was 155 mgKOH/g.

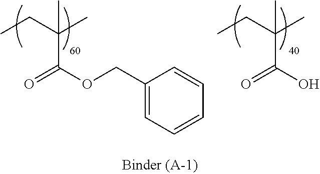

### Synthesis Example 2

<The Synthesis of a Binder (A-2)>

MFG (7.48 g, manufactured by NIPPON NYUKAZAI Co., Ltd.) was added in advance to a reaction container, heated to 90° C., and a solution mixture made up of MAA (14.65 g), MMA (0.54 g) and CHMA (17.55 g) as monomer components, AIBN (0.50 g) as a radical polymerization initiator and MFG (55.2 g) was added dropwise to the reaction container in a nitrogen gas atmosphere at 90° C. over 2 hours. After the dropwise addition, the components were reacted for 4 hours, thereby obtaining an acrylic resin solution.

Next, hydroquinone monomethyl ether (0.15 g) and tetraethylammonium bromide (0.34 g) were added to the obtained acrylic resin solution, and then GMA (12.26 g) were added dropwise over 2 hours. After the dropwise addition, the components were reacted for 4 hours at 90° C. while blowing air into the reaction container, and then PGMEA was added so that the solid content concentration became 45%, thereby obtaining a solution (solid content concentration: 45% by mass) of a binder (A-2).

As a result of measuring the molecular weight using gel permeation chromatography (GPC), the weight average molecular weight (Mw) in terms of polystyrene was 31,300, the molecular weight distribution (Mw/Mn) was 2.32, and the acid value was 74.5 mgKOH/g.

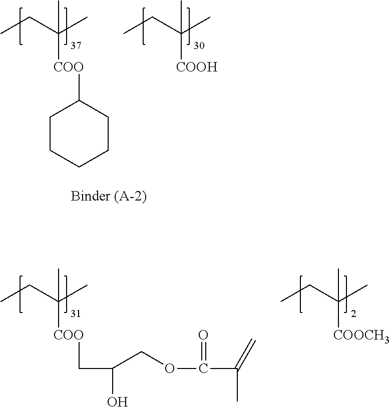

### Preparation Example 1

—The Preparation of a Silver Nanowire Aqueous Dispersion Liquid (1)—

The following addition liquids A, G and H were prepared in advance.

[Addition Liquid A]

Silver nitrate powder (0.51 g) was dissolved in pure water (50 mL). After that, 1N ammonia water was added until the solution became transparent. In addition, pure water was added so that the total amount became 100 mL.

[Addition Liquid G]

Glucose powder (0.5 g) was dissolved in pure water (140 mL), thereby preparing an addition liquid G.

[Addition Liquid H]

Hexadecyltrimethylammonium bromide (HTAB) powder (0.5 g) was dissolved in pure water (27.5 mL), thereby preparing an addition liquid H.

Next, a silver nanowire aqueous dispersion liquid was prepared in the following manner.

Pure water (410 mL) was put into a three-neck flask, and the addition liquid H (82.5 mL) and the addition liquid G (206 mL) were added while being stirred at 20° C. (first step). The addition liquid A (206 mL) was added to the above solution at a flow rate of 2.0 mL/min and a stiffing rate of 800 rpm (second step). After 10 minutes, the addition liquid H (82.5 mL) was added (third step). After that, the solution was heated at 3° C./minute until the inner temperature reached 73° C. After that, the stirring rate was reduced to 200 rpm, and the solution was heated for 5.5 hours.

After the obtained aqueous dispersion liquid was cooled, an ultrafiltration module SIP1013 (trade name, manufactured by ASAHI KASEI Corporation, cutoff molecular weight of 6,000), a magnetic pump and a stainless steel cup were connected using silicone tubes, thereby preparing an ultrafiltration apparatus.

The silver nanowire dispersion liquid (aqueous solution) was put into the stainless steel cup, and ultrafiltration was carried out by operating the pump. When a filtration from the module reached 50 mL, distilled water (950 mL) was added to the stainless steel cup, and the stainless steel cup was washed. After the washing was repeated until the conductivity became 50 μS/cm or less, condensation was carried out, thereby obtaining a 0.8% by mass silver nanowire aqueous dispersion liquid.

For the obtained silver nanowires of Preparation Example 1, the average short axis length, the average long axis length, the proportion of silver nanowires having an aspect ratio of 10 or more, and the coefficient of variation of the short axis lengths of the silver nanowires were measured.

As a result, silver nanowires having an average short axis length of 17.2 nm, an average long axis length of 34.2 μm, and a coefficient of variation of 17.8% were obtained. In the obtained silver nanowires, the proportion of silver nanowires having an aspect ratio of 10 or more was 81.8%. Hereinafter, the “silver nanowire aqueous dispersion liquid (1)” indicates the silver nanowire aqueous dispersion liquid (1) obtained using the above method.

### Preparation Example 2

—Preparation of the PGMEA Dispersion Liquid (1) of Silver Nanowires—

Polyvinyl pyrrolidone (1 part, K-30; trade name, manufactured by TOKYO CHEMICAL INDUSTRY Co., Ltd.) and n-propanol (100 parts) were added to the silver nanowire aqueous dispersion liquid (1) (100 parts) prepared in Preparation Example 1, and condensed 10 times using a crossflow filter (manufactured by NGK Insulators, Ltd.) for which a ceramic filter was used. Next, n-propanol (100 parts) and ion exchanged water (100 parts) were added, and, again, an operation for condensing the components 10 times using the crossflow filter was repeated three times. Furthermore, the binder (A-1) (1 part) and n-propanol (10 parts) were added, centrifugally separated, and then a supernatant solvent was removed using decantation, PGMEA was added, re-dispersion was carried out, the operation of centrifugal separation through re-dispersion was repeated three times, and, finally, PGMEA was added, thereby obtaining a PGMEA dispersion liquid of silver nanowires. The amount of the lastly-added PGMEA was adjusted so that the content of silver became silver 2%. The content of a polymer used as a dispersant was 0.05%. Silver nanowires having an average short axis length of 16.7 mm, an average long axis length of 29.1 μm and a coefficient of variation of 18.2% were obtained. In the obtained silver nanowires, the proportion of silver nanowires having an aspect ratio of 10 or more was 80.2%. Hereinafter, the “silver nanowire PGMEA dispersion liquid (1)” indicates the silver nanowire PGMEA dispersion liquid (1) obtained using the above method.

### Preparation Example 3

—Pretreatment of a Glass Substrate—

First, a 0.7 mm-thick alkali-free glass substrate that had been immersed in a 1% sodium hydroxide aqueous solution was irradiated with ultrasonic waves for 30 minutes using an ultrasonic washer, subsequently, washed using ion exchanged water for 60 seconds, and then subjected to a heating treatment at 200° C. for 60 minutes. After that, a silane coupling liquid (N-β-(aminoethyl)-γ-aminopropyl trimethoxysilane 0.3% aqueous solution, product name: KBM603; trade name, manufactured by SHIN-ETSU CHEMICAL Co., Ltd.) was showered for 20 seconds, and pure water shower washing was carried out. Hereinafter, the “glass substrate” indicates an alkali-free glass substrate obtained using the pretreatment.

### Preparation Example 4

—Pretreatment of a PET Substrate—

An adhesion solution 1 was prepared in the following composition.

[Adhesion solution 1]

| | |
|---|---|
| TAKELAC WS-4000 | 5.0 parts |
| (trade name, manufactured by MITSUI CHEMICALS, Inc., | |
| solid content concentration 30%) | |
| Surfactant | 0.3 parts |
| (NALOACTY HN-100; trade name, manufactured by | |
| SANYO CHEMICALS INDUSTRIES, Ltd.) | |
| Surfactant | 0.3 parts |
| (SUNDET BL; trade name, manufactured by MITSUI | |
| CHEMICALS, Inc., solid content concentration 43%,) | |
| Water | 94.4 parts |

A corona discharge treatment was carried out on one surface of a 125 μm-thick PET substrate. The adhesion solution was coated on the corona discharge-treated surface, and dried at 120° C. for 2 minutes, thereby forming a 0.11 μm-thick adhesion layer 1.

An adhesion solution 2 was prepared in the following composition.

[Adhesion solution 2]

| | | |
|---|---|---|
| Tetraethoxysilane | 5.0 | parts |
| (KBE-04; trade name, manufactured by SHIN-ETSU | | |
| CHEMICAL Co., Ltd.) | | |
| 3-Glycidoxypropyltrimethoxysilane | 3.2 | parts |
| (KBM-403; trade name, manufactured by SHIN-ETSU | | |
| CHEMICAL Co., Ltd.) | | |
| 2-(3,4-epoxycyclohexyl)ethyltrimethoxysilane | 1.8 | parts |
| (KBM-303; trade name, manufactured by SHIN-ETSU | | |
| CHEMICAL Co., Ltd.) | | |
| Aqueous solution of acetic acid (acetic acid concentration = | 10.0 | parts |
| 0.05%, pH = 5.2) | | |
| Curing agent | 0.8 | parts |
| (boric acid, manufactured by Wako Pure Chemical Indus- | | |
| tries) | | |
| Colloidal silica | 60.0 | parts |
| (SNOWTEX O; trade name, manufactured by NISSAN | | |
| CHEMICALS INDUSTRIES, Ltd., average particle | | |
| diameter 10 nm to 20 nm, solid content concentration 20%, | | |
| pH = 2.6) | | |
| Surfactant | 0.2 | parts |
| (NALOACTY HN-100; trade name, manufactured by | | |
| SANYO CHEMICALS INDUSTRIES, Ltd.) | | |
| Surfactant | 0.2 | parts |
| (SUNDET BL; trade name, manufactured by MITSUI | | |
| CHEMICALS, Inc., solid content concentration 43%) | | |

The adhesion solution 2 was prepared using the following method. 3-Glycidoxypropyltrimethoxysilane was added dropwise over 3 minutes to the aqueous solution of acetic acid while violently stirring the aqueous solution of acetic acid. Next, 2-(3,4-epoxycyclohexyl)ethyl trimethoxysilane was added over 3 minutes while strongly stirring the aqueous solution of acetic acid. Next, tetraethoxysilane was added over 5 minutes while strongly stirring the aqueous solution of acetic acid, and then the solution was stirred for 2 hours. Next, the colloidal silica, the curing agent and the surfactants were sequentially added, thereby preparing the adhesion solution 2.

The adhesion solution 2 was coated on the corona discharge-treated adhesion layer 1 using a bar coating method, heated and dried at 170° C. for 5 minutes, thereby forming a 4.1 inn-thick adhesion layer 2. After that, a corona discharge treatment was carried out on the adhesion layer 2, thereby obtaining a pretreated PET substrate. Hereinafter, the “PET substrate” indicates the PET substrate obtained using the above pretreatment.

### Example 1

<Formation of a Conductive Layer>>

A photopolymerizable composition having the following composition was prepared.

<Photopolymerizable Composition>

| | | |
|---|---|---|
| Polymer: (the binder (A-1) obtained in the synthesis | 44.50 | parts |
| example, a PGMEA solution with a solid content of | | |
| 45%) | | |
| Polymer: (the binder (A-2) obtained in the synthesis | 44.50 | parts |
| example, a PGMEA, MFG solution mixture with a solid | | |
| content of 45%) | | |
| Polymerizable compound: dipentaerythritol hexaacrylate | 8.01 | parts |
| Photopolymerization initiator: 2,4-bis(trichloromethyl)- | 0.79 | parts |
| 6-[4-N,N-bis(ethoxycarbonylmethyl)amino-3- | | |
| bromophenyl]-s-triazine | | |
| Polymerization inhibitor: phenothiazine | 0.062 | parts |
| Surfactant: MEGAFAC F784F (trade name, manufac- | 2.70 | parts |
| tured by DIC Corporation) | | |
| Surfactant: SOLSPERSE 20000 (trade name, manufac- | 1.00 | part |
| tured by the LUBRIZOL Corporation) | | |
| Solvent (PGMEA) | 48.42 | parts |
| Solvent (MEK) | 100.00 | parts |

The obtained photopolymerizable composition (3.21 parts), the silver nanowire PGMEA dispersion liquid (1) (6.41 parts) and the solvent (PGMEA/MEK=1/1) (40.38 parts) were stirred and mixed, thereby obtaining a photopolymerizable conductive layer coating liquid.

The photopolymerizable conductive layer coating liquid obtained above was bar-coated on the PET substrate so that the coating amount of the solid content of the photopolymerizable composition became 0.175 g/m² and the amount of silver became 0.035 g/m², and dried at room temperature for 5 minutes, thereby providing a photosensitive conductive layer. The thickness of the photosensitive conductive layer was 0.12 μm.

Here, the thickness was measured using the following method. The thicknesses of layers other than the photosensitive conductive layer were also measured in a substantially similar manner.

After a protective layer of carbon and Pt was formed on a conductive member, a specimen with a width of approximately 10 μm and a thickness of approximately 100 nm was prepared in an FB-2100; trade name, focused ion beam system manufactured by HITACHI, Ltd., and a cross-section of the conductive layer was observed using an HD-2300 STEM (applied voltage 200 kV); trade name, manufactured by Hitachi, Ltd., thereby measuring the thickness of the conductive layer. Meanwhile, regarding the film thickness, there is a simple method in which the film thickness is measured from the difference in thickness between a conductive layer-formed portion and a conductive layer-removed portion using a stylus type surface profiler DEKTAK 150 (trade name, manufactured by ULVAC, Inc.), however, in the present method, there was a concern that some of the base material may be removed when removing the conductive layer, and, furthermore, there was a problem in that the conductive layer is a thin film and therefore an error may be easily caused. Therefore, in the present specification, values obtained through the direct observation of the cross-section of the conductive layer using the electronic microscope, which is a more accurate method for measuring film thicknesses, are described.

<Exposure Step>

The photosensitive conductive layer on the substrate was exposed in a nitrogen atmosphere using i rays (365 nm) from an ultrahigh pressure mercury lamp through a mask at an exposure value of 40 mJ/cm². Here, the exposure was carried out through a mask, and the mask had a uniformly exposed portion for evaluating conduction, optical characteristics and film strength and a stripe pattern (line/space=50 μm/50 μm) for evaluating patterning properties.

<Development Step>

The exposed photosensitive conductive layer was shower-developed at 20° C. for 30 seconds with a conic nozzle pressure of 0.15 MPa using a sodium carbonate-based development liquid (containing 0.06 mole/liter of sodium hydrogen carbonate, the same concentration of sodium carbonate, 1% sodium dibutylnaphthalene sulfonate, an anionic surfactant, a defoamer and a stabilizer, trade name: T-CD1, manufactured by FUJIFILM Corporation) so as to remove the photosensitive conductive layer in non-exposed portions, and dried at room temperature. Next, a heat treatment was carried out at 100° C. for 15 minutes. Thereby, a conductive layer including a conductive area and a non-conductive area was formed. The thickness of the conductive area was 0.010 μm.

<<Formation of a Protective Layer>>

It was confirmed that a sol-gel coating liquid having the following composition was stirred at 60° C. for 1 hour so as to become homogeneous. The obtained sol-gel coating liquid was diluted using distilled water, coated on the conductive layer including the conductive area and the non-conductive area using an applicator coater so that the coating amount of the solid content became 0.50 g/m², then, dried at 140° C. for 1 minute, and a sol-gel reaction was caused so as to form a protective layer, thereby obtaining a conductive member of Example 1. The thickness of the protective layer was 0.13 μm.

<Sol-Gel Coating Liquid>

| | |
|---|---|
| 3-Glycidoxypropyltrimethoxysilane | 5.9 parts |
| (KBM-403; trade name, manufactured by SHIN-ETSU | |
| CHEMICAL Co., Ltd.) | |
| Tetraethoxysilane | 6.8 parts |
| (KBM-04; trade name, manufactured by SHIN-ETSU | |
| CHEMICAL Co., Ltd.) | |
| 1% aqueous solution of acetic acid | 15.0 parts |

### Examples 2 to 16

Conductive members of Examples 2 to 16 were obtained in a manner substantially similar to the preparation of the conductive member in Example 1 except that both 3-glycidoxypropyltrimethoxysilane and tetraethoxysilane were changed to (one or two) compounds described below with changed amounts. The thicknesses of the protective layers in the obtained conductive members will also be described below.

| | | |
|---|---|---|
| Example 2: 3-glycidoxypropyltrimethoxysilane | 12.7 | parts |
| (thickness: 0.14 μm) | | |
| Example 3: tetraethoxysilane | 12.7 | parts |
| (thickness: 0.12 μm) | | |
| Example 4: 3-glycidoxypropyltrimethoxysilane | 0.6 | parts |
| tetraethoxysilane | 12.1 | parts |
| (thickness: 0.13 μm) | | |
| Example 5: 3-glycidoxypropyltrimethoxysilane | 1.3 | parts |
| tetraethoxysilane | 11.4 | parts |
| (thickness: 0.13 μm) | | |
| Example 6: 3-glycidoxypropyltrimethoxysilane | 3.8 | parts |
| tetraethoxysilane | 8.9 | parts |
| (thickness: 0.13 μm) | | |
| Example 7: 3-glycidoxypropyltrimethoxysilane | 6.35 | parts |
| tetraethoxysilane | 6.35 | parts |
| (thickness: 0.13 μm) | | |
| Example 8: 3-glycidoxypropyltrimethoxysilane | 10.2 | parts |
| tetraethoxysilane | 2.5 | parts |
| (thickness: 0.13 μm) | | |
| Example 9: 3-glycidoxypropyltrimethoxysilane | 12.5 | parts |
| tetraethoxysilane | 0.2 | parts |
| (thickness: 0.13 μm) | | |
| Example 10: tetrapropoxy titanate | 12.7 | parts |
| (thickness: 0.12 μm) | | |
| Example 11: tetraethoxy zirconate | 12.7 | parts |
| (thickness: 0.12 μm) | | |
| Example 12: 2-(3,4-epoxycyclohexyl)ethyltrimethosysilane | 5.9 | parts |
| tetramethoxysilane | 6.8 | parts |
| (thickness: 0.14 μm) | | |
| Example 13: ureidopropyltriethoxysilane | 5.9 | parts |
| tetraethoxysilane | 6.8 | parts |
| (thickness: 0.14 μm) | | |
| Example 14: diethyldimethoxysilane | 5.9 | parts |
| tetraethoxysilane | 6.8 | parts |
| (thickness: 0.13 μm) | | |
| Example 15: propyl triethoxy titanate | 5.9 | parts |
| tetraisopropoxy titante | 6.8 | parts |
| (thickness: 0.12 μm) | | |
| Example 16: ethyl triethoxy zirconate | 5.9 | parts |
| tetrapropoxy zirconate | 6.8 | parts |
| (thickness: 0.12 μm) | | |

### Examples 17 to 21

Conductive members of Examples 17 to 21 were obtained in a manner substantially similar to the preparation of the conductive member in Example 1 except that the coating amount of the solid content of the sol-gel coating liquid for forming the protective layer in Example 1 was changed as follows in Examples 17 to 21. The thicknesses of the respective protective layers were as described below.

Example 17: 1.00 g/m² (thickness: 0.250 μm)

Example 18: 0.35 g/m² (thickness: 0.092 μm)

Example 19: 0.15 g/m² (thickness: 0.040 μm)

Example 20: 0.10 g/m² (thickness: 0.026 μm)

Example 21: 0.05 g/m² (thickness: 0.013 μm)

### Examples 22 to 26

Conductive members of Examples 22 to 26 were obtained in a manner substantially similar to the preparation of the conductive member in Example 3 except that the coating amount of the solid content of the sol-gel coating liquid for forming the protective layer in Example 3 was changed as follows in Examples 22 to 26. The thicknesses of the respective protective layers were as described below.

Example 22: 1.00 g/m² (thickness: 0.245 μm)

Example 23: 0.35 g/m² (thickness: 0.090 μm)

Example 24: 0.15 g/m² (thickness: 0.039 μm)

Example 25: 0.10 g/m² (thickness: 0.025 μm)

Example 26: 0.05 g/m² (thickness: 0.013 μm)

### Examples 27 to 30

Conductive members of Examples 27 to 30 were obtained in a manner substantially similar to the preparation of the conductive member in Example 1 except that the coating amount of the solid content of the photopolymerizable composition and the amount of silver were changed as follows using the photopolymerizable conductive layer coating liquid used in Example 1. The thicknesses of the respective conductive layers after the exposure step and the development step were as follows. The thicknesses of the protective layers were all 0.13

Example 27: the coating amount of the solid content: 0.500 g/m², the amount of silver: 0.100 g/m² (thickness: 0.029 μm)

Example 28: the coating amount of the solid content: 0.100 g/m², the amount of silver: 0.020 g/m² (thickness: 0.006 μm)

Example 29: the coating amount of the solid content: 0.050 g/m², the amount of silver: 0.010 g/m² (thickness: 0.003 μm)

Example 30: the coating amount of the solid content: 0.025 g/m², the amount of silver: 0.005 g/m² (thickness: 0.001 μm)

### Examples 31 to 36

Conductive members of Examples 31 to 36 were obtained in a manner substantially similar to the preparation of the conductive member in Example 1 except that the mixing ratio of the photopolymerizable composition, the silver nanowire PGMEA dispersion liquid (1) and the solvent (PGMEA/MEK=1/1), which were used in Example 1 was appropriately changed, and the coating amount of the solid content of the photopolymerizable composition and the amount of silver were changed as follows in Examples 31 to 36. The thicknesses of the respective conductive layers after the exposure step and the development step were as follows. The thicknesses of the protective layers were all 0.13 μm.

Example 31: the coating amount of the solid content: 0.280 g/m², the amount of silver: 0.035 g/m² (thickness: 0.016 μm)

Example 32: the coating amount of the solid content: 0.210 g/m², the amount of silver: 0.035 g/m² (thickness: 0.012 μm)

Example 33: the coating amount of the solid content: 0.160 g/m², the amount of silver: 0.020 g/m² (thickness: 0.009 μm)

Example 34: the coating amount of the solid content: 0.120 g/m², the amount of silver: 0.020 g/m² (thickness: 0.007 μm)

Example 35: the coating amount of the solid content: 0.120 g/m², the amount of silver: 0.015 g/m² (thickness: 0.007 μm)

Example 36: the coating amount of the solid content: 0.090 g/m², the amount of silver: 0.015 g/m² (thickness: 0.005 μm)

### Example 37

A conductive member of Example 37 was obtained in a manner substantially similar to the preparation of the conductive member in Example 1 except that the PET substrate in Example 1 was changed to a glass substrate in Example 37. The thickness of the conductive layer after the exposure step and the development step was 0.010 μm, and the thickness of the protective layer was 0.13

### Examples 38 to 45

Conductive members of Examples 38 to 45 were obtained in a manner substantially similar to the preparation of the conductive member in Example 1 except that the silver nanowire PGMEA dispersion liquid (1) used in Example 1 was respectively changed to the silver nanowire PGMEA dispersion liquids (2) to (9) having the average long axis lengths and average short axis lengths of silver nanowires described in Table 1 in Examples 38 to 45.

TABLE 1

| Example | Silver nanowire PGMEA dispersion | | |
|---|---|---|---|
| Number | Number | Long axis Length (μm) | Short axis Length (nm) |
| 38 | (2) | 21.5 | 30.5 |
| 39 | (3) | 24.4 | 42.8 |
| 40 | (4) | 17.9 | 61.1 |
| 41 | (5) | 15.1 | 20.0 |
| 42 | (6) | 7.9 | 17.9 |
| 43 | (7) | 10.2 | 28.9 |
| 44 | (8) | 8.8 | 45.1 |
| 45 | (9) | 8.6 | 59.3 |

### Comparative Example 1

A conductive member of Comparative Example 1 was obtained in a manner substantially similar to the preparation of the conductive member in Example 1 except that the protective layer in Example 1 was changed to the following protective layer C1 in Comparative Example 1.

A coating liquid A with the following composition was coated so that the solid content amount became 0.50 g/m², and exposed in a nitrogen atmosphere using i rays (365 nm) from an ultrahigh pressure mercury lamp at an exposure value of 40 mJ/cm², thereby forming a protective layer C1.

<Coating Liquid A>

| | |
|---|---|
| Dipentaerythritol hexaacrylate | 8.01 parts |
| Photopolymerization initiator: 2,4-bis(trichloromethyl)- | 0.79 parts |
| 6-[4-N,N-bis(ethoxycarbonylmethyl)amino-3-bromo- | |
| phenyl]-s-triazine | |
| Surfactant: MEGAFAC F784F (trade name, manufac- | 2.70 parts |
| tured by DIC Corporation) | |
| Solvent (PGMEA) | 356.54 parts |

<<Evaluation>>

For the obtained respective conductive members, the surface resistivity, optical characteristics (light transmittance, haze), film strength, abrasion resistance, heat resistance, moisture and heat resistance and bendability were evaluated.

<Surface Resistivity>

The surface resistivity of the conductive area in the conductive member was measured using LORESTA-GP MCP-T600; trade name, manufactured by MITSUBISHI CHEMICAL Corporation, and rated using the following ranks based on the value.
Rank 5: the surface resistivity of less than 100Ω/□, an extremely outstanding level
Rank 4: the surface resistivity of from 100Ω/□ to less than 150Ω/□, an outstanding level
Rank 3: the surface resistivity of from 150Ω/□ to less than 200Ω/□, an allowable level
Rank 2: the surface resistivity of from 200Ω/□ to less than 1000Ω/□, a slightly problematic level
Rank 1: the surface resistivity of 1000Ω/□ or more, a problematic level

<Optical Characteristics (Light Transmittance)>

The light transmittance (%) of a portion corresponding to the conductive area of the conductive member and the light transmittance (%) of the PET substrates 101 (Examples 1 to 36) or the glass substrate (Example 37) on which the conductive layer 20 was not yet to be formed were measured using a HAZE-GARD PLUS; trade name, manufactured by GARTNER, Inc., the transmittance of a transparent conductive film was converted from the ratio, and rated using the following ranks. The measurement was made with respect to CIE luminosity function y under a C light source at a measurement angle of 0°, and the transmittance was rated using the following ranks.
Rank A: the transmittance of 90% or more, a favorable level
Rank B: the transmittance of from 85% to less than 90%, a slightly problematic level

<Optical Characteristics (Haze)>

The haze of the portion corresponding to the conductive area of the conductive member was measured using a HAZE-GARD PLUS; trade name, manufactured by GARTNER, Inc., and rated using the following ranks.
Rank A: the haze of less than 1.5%, an outstanding level
Rank B: the haze of from 1.5% to less than 2.0%, a favorable level
Rank C: the haze of from 2.0% to less than 2.5%, a slightly problematic level
Rank D: the haze of 2.5% or more, a problematic level

<Film Strength>

After specimens were scratched 10 mm under a condition of a load of 500 g using a pencil scratching hardness tester (manufactured by TOYO SEIKI SEISAKU-SHO, Ltd., NP type) set with Japan Paint Inspection and Testing Association-certified pencils for pencil scratching (hardness HB and hardness B) according to JIS K 5600-5-4, exposure and development thereof were carried out under the following conditions, the scratched portions were observed using a digital microscope (VHX-600; trade name, manufactured by KEYENCE Corporation, magnification of 2,000 times), and rated using the following ranks. Meanwhile, there was no cut metallic nanowire observed in the conductive layer of Level 3 or higher, and thus Level 3 or higher were problem-free levels at which practical conduction can be ensured.

[Evaluation Criteria]
Rank 5: no observed scratch after scratching by a pencil with a hardness of 2H, an extremely outstanding level
Rank 4: metallic nanowires were cut by scratching by a pencil with a hardness of 2H, and scratches were observed, but metallic nanowires remained, and there was no exposed surface of the base material, an outstanding level
Rank 3: there were surfaces of the base material exposed by scratching by a pencil with a hardness of 2H, but metallic nanowires remained after scratching by a pencil with a hardness of HB, and there was no exposed surface of the base material, a favorable level
Rank 2: the conductive layer was cut by a pencil with a hardness of HB, and exposed surfaces of the base material were partially observed, a problematic level
Rank 1: the conductive layer was cut by a pencil with a hardness of HB, and almost all the surface of the base material was exposed, a problematic level

<Abrasion Resistance>

An abrasion treatment in which a surface of the protective layer in the conductive member was reciprocally rubbed 50 times with a load of 500 g using a 20 mm×20 mm-sized gauze piece, the generation of scratches after the treatment was observed, and the change rate of the surface resistivity (the surface resistivity after the abrasion treatment/the surface resistivity before the abrasion treatment) was computed. In the abrasion test, a continuous loading scratching intensity tester TYPE 18S; trade name, manufactured by SHINTO SCIENTIFIC Co., Ltd. was used, and the surface resistivity was measured using LORESTA-GP MCP-T600; trade name, manufactured by MITSUBISHI CHEMICAL Corporation. Conductive members with no scratch and a smaller change rate of the surface resistivity (approaching to 1) are excellent in terms of abrasion resistance.

<Heat Resistance>

A heating treatment in which the conductive member was heated at 150° C. for 60 minutes was carried out, and the change rate of the surface resistivity (the surface resistivity after the heating treatment/the surface resistivity before the heating treatment) and the change degree of the haze (the haze after the heating treatment—the haze before the heating treatment) were computed. The surface resistivity was measured using LORESTA-GP MCP-T600; trade name, manufactured by MITSUBISHI CHEMICAL Corporation, and the haze was measured using a HAZE-GARD PLUS; trade name, manufactured by Gartner, Inc. As the change rate of the surface resistivity approaches to 1, and the change degree of the haze decreases, the heat resistance is excellent.

<Moisture and Heat Resistance>

A moisture and heat treatment in which the conductive member was left to stand for 240 hours at 60° C. under an environment of 90RH % was carried out, and the change rate (the surface resistivity after the moisture and heat treatment/the surface resistivity before the moisture and heat treatment) of the surface resistivity and the change degree (the haze after the moisture and heat treatment—the haze before the moisture and heat treatment) of the haze were computed. The surface resistivity was measured using LORESTA-GP MCP-T600 manufactured by MITSUBISHI CHEMICAL Corporation, and the haze was measured using a HAZE-GARD PLUS; trade name, manufactured by GARTNER, Inc. As the change rate of the surface resistivity approaches to 1, and the change degree of the haze decreases, the moisture and heat resistance is excellent.

<Bendability>

A bending treatment in which the conductive member was bent 20 times on a cylindrical mandrel having a diameter of 10 mm using a cylindrical mandrel bending tester (for example, a bending tester manufactured by COTEC Corporation) was carried out, the presence of cracks before and after the bending treatment was observed, and the change rate of the surface resistivity (the surface resistivity after the bending treatment/the surface resistivity before the bending treatment) was carried out. The presence of cracks was checked visually using an optical microscope, and the surface resistivity was measured using LORESTA-GP MCP-T600; trade name, manufactured by MITSUBISHI CHEMICAL Corporation. Conductive members with no crack and the change rate of the surface resistivity approaching 1 are excellent in terms of bendability.

The evaluation results are described in Tables 2 and 3.

Meanwhile, Tables 2 and 3 describe the evaluation ranks of the surface resistivity of the respective conductive members before the formation of the protective layer as reference data.

TABLE 2

| | Performance Evaluation | | | | | | | | | | |
|---|---|---|---|---|---|---|---|---|---|---|---|
| Example | S.R. | | | | Film | Abr. | Heat Resistance | | Moist. Heat Resistance | | Bend- |
| Number | (B.F.P.L.) | S.R. | L. Trans. | Haze | Strength | Resist. | C.R.S.R. | C.D. Haze | C.R.S.R. | C.D. Haze | ability |
| 1 | 4 | 5 | A | A | 5 | 1.14 | 1.26 | 0.20 | 1.23 | 0.29 | 1.03 |
| 2 | 4 | 5 | A | A | 5 | 1.17 | 1.25 | 0.21 | 1.25 | 0.26 | 1.05 |
| 3 | 4 | 5 | A | A | 5 | 1.09 | 1.22 | 0.19 | 1.19 | 0.21 | 1.02 |
| 4 | 4 | 5 | A | A | 5 | 1.19 | 1.28 | 0.21 | 1.27 | 0.28 | 1.01 |
| 5 | 4 | 5 | A | A | 5 | 1.15 | 1.26 | 0.18 | 1.24 | 0.24 | 1.01 |
| 6 | 4 | 5 | A | A | 5 | 1.11 | 1.21 | 0.18 | 1.22 | 0.20 | 1.04 |
| 7 | 4 | 5 | A | A | 5 | 1.12 | 1.20 | 0.20 | 1.22 | 0.23 | 1.01 |
| 8 | 4 | 5 | A | A | 5 | 1.12 | 1.20 | 0.19 | 1.27 | 0.24 | 1.05 |
| 9 | 4 | 5 | A | A | 5 | 1.10 | 1.18 | 0.20 | 1.22 | 0.21 | 1.03 |
| 10 | 4 | 5 | A | A | 5 | 1.18 | 1.22 | 0.18 | 1.30 | 0.27 | 1.00 |
| 11 | 4 | 5 | A | A | 5 | 1.17 | 1.25 | 0.21 | 1.31 | 0.28 | 1.01 |
| 12 | 4 | 5 | A | A | 5 | 1.15 | 1.23 | 0.20 | 1.28 | 0.24 | 1.04 |
| 13 | 4 | 5 | A | A | 5 | 1.16 | 1.23 | 0.21 | 1.24 | 0.24 | 1.00 |
| 14 | 4 | 5 | A | A | 5 | 1.20 | 1.29 | 0.22 | 1.29 | 0.29 | 1.03 |
| 15 | 4 | 5 | A | A | 5 | 1.21 | 1.32 | 0.26 | 1.28 | 0.28 | 1.04 |
| 16 | 4 | 5 | A | A | 5 | 1.19 | 1.28 | 0.24 | 1.27 | 0.28 | 1.03 |
| 17 | 4 | 5 | A | A | 5 | 0.99 | 1.15 | 0.20 | 1.14 | 0.18 | 1.03 |
| 18 | 4 | 5 | A | A | 5 | 1.19 | 1.27 | 0.22 | 1.21 | 0.25 | 1.01 |
| 19 | 4 | 5 | A | A | 5 | 1.25 | 1.28 | 0.25 | 1.26 | 0.27 | 1.04 |
| 20 | 4 | 5 | A | A | 5 | 1.35 | 1.27 | 0.25 | 1.30 | 0.29 | 1.03 |
| 21 | 4 | 5 | A | A | 5 | 1.49 | 1.32 | 0.26 | 1.34 | 0.31 | 1.03 |
| 22 | 4 | 5 | A | A | 5 | 0.98 | 1.13 | 0.17 | 1.13 | 0.17 | 1.02 |
| 23 | 4 | 5 | A | A | 5 | 1.12 | 1.23 | 0.21 | 1.22 | 0.20 | 1.05 |

TABLE 3

| | Performance Evaluation | | | | | | | | | | |
|---|---|---|---|---|---|---|---|---|---|---|---|
| Example | S.R. | | | | Film | Abr. | Heat Resistance | | Moist. Heat Resistance | | Bend- |
| Number | (B.F.P.L.) | S.R. | L. Trans. | Haze | Strength | Resist. | C.R.S.R. | C.D. Haze | C.R.S.R. | C.D. Haze | ability |
| 24 | 4 | 5 | A | A | 5 | 1.18 | 1.22 | 0.23 | 1.25 | 0.24 | 1.02 |
| 25 | 4 | 5 | A | A | 5 | 1.27 | 1.25 | 0.24 | 1.26 | 0.29 | 1.03 |
| 26 | 4 | 5 | A | A | 5 | 1.44 | 1.28 | 0.24 | 1.32 | 0.31 | 1.04 |
| 27 | 5 | 5 | B | B | 5 | 1.12 | 1.18 | 0.20 | 1.21 | 0.23 | 1.00 |
| 28 | 4 | 5 | A | A | 5 | 1.15 | 1.19 | 0.22 | 1.22 | 0.28 | 1.03 |
| 29 | 3 | 4 | A | A | 5 | 1.27 | 1.30 | 0.23 | 1.30 | 0.27 | 1.04 |
| 30 | 2 | 3 | A | A | 5 | 1.34 | 1.35 | 0.25 | 1.38 | 0.31 | 1.05 |
| 31 | 4 | 5 | A | A | 5 | 1.12 | 1.20 | 0.19 | 1.22 | 0.24 | 1.04 |
| 32 | 4 | 5 | A | A | 5 | 1.12 | 1.21 | 0.20 | 1.24 | 0.26 | 1.06 |
| 33 | 4 | 4 | A | A | 5 | 1.16 | 1.26 | 0.23 | 1.26 | 0.25 | 1.04 |
| 34 | 4 | 4 | A | A | 5 | 1.19 | 1.25 | 0.25 | 1.25 | 0.25 | 1.04 |
| 35 | 3 | 4 | A | A | 5 | 1.18 | 1.31 | 0.25 | 1.28 | 0.28 | 1.02 |
| 36 | 3 | 4 | A | A | 5 | 1.23 | 1.29 | 0.27 | 1.29 | 0.27 | 1.03 |
| 37 | 4 | 5 | A | B | 5 | 1.13 | 1.28 | 0.20 | 1.24 | 0.26 | 1.03 |
| 38 | 4 | 5 | A | C | 5 | 1.11 | 1.36 | 0.30 | 1.22 | 0.21 | 1.04 |
| 39 | 3 | 3 | A | C | 5 | 1.12 | 1.32 | 0.22 | 1.23 | 0.25 | 1.03 |
| 40 | 4 | 4 | A | B | 5 | 1.08 | 1.28 | 0.19 | 1.22 | 0.24 | 1.01 |
| 41 | 4 | 4 | A | A | 5 | 1.13 | 1.25 | 0.20 | 1.29 | 0.26 | 1.02 |
| 42 | 4 | 4 | A | B | 5 | 1.11 | 1.38 | 0.27 | 1.28 | 0.26 | 1.01 |
| 43 | 4 | 4 | A | C | 5 | 1.15 | 1.35 | 0.23 | 1.27 | 0.26 | 1.04 |
| 44 | 3 | 3 | A | C | 5 | 1.10 | 1.32 | 0.18 | 1.23 | 0.23 | 1.04 |
| 45 | 4 | 4 | A | B | 5 | 1.13 | 1.26 | 0.16 | 1.22 | 0.22 | 1.01 |
| Co. Ex. 1 | 4 | 1 | A | B | 3 | 30.7 | 8.59 | 0.65 | 5.88 | 0.45 | 2.69 |

In Tables 2 and 3, the abbreviation “Co. Ex.” denotes “Comparative Example number”, the abbreviation “S.R.” denotes “Surface resistivity”, the abbreviation “B.F.P.L.” denotes “before formation of Protective layer”, the abbreviation “L. Trans.” denotes “Light transmittance”, the abbreviation “Abr. Resist.” denotes “Abrasion resistance”, the abbreviation “Moist. Heat Resistance” denotes “Moisture and heat resistance”, the abbreviation “C.R.S.R.” denotes “Change rate of surface resistivity”, and the abbreviation “C.D. Haze” denotes “Change degree of haze”.

From the results described in Tables 2 and 3, it can be understood that the conductive member in the invention is excellent in terms of conduction and transparency, excellent in terms of abrasion resistance, heat resistance, and moisture and heat resistance, and excellent in terms of bending resistance. Particularly, it is revealed that, when the protective layer is provided, significant effects that not only does the film strength significantly increase, but the surface resistivity also remains similar or improves to a lower value compared with conductive members not provided with the protective layer are exhibited.

### Example 46

<<Preparation of a Laminate Body for Forming the Conductive Layer>>

<Formation of a Cushion Layer>

A coating liquid for thermoplastic resin layers produced according to the following formulation 1 was coated on a transfer base material (a 75 μm-thick polyethylene terephthalate film), dried at 100° C. for 2 minutes, and then, furthermore, dried at 120° C. for 1 minute, thereby forming a cushion layer made of a thermoplastic resin layer with a dried layer thickness of 16.5 μm. Here, the temperatures “100° C.” and “120° C.” in the drying conditions are all the substrate temperature. This shall apply to temperatures in the following drying conditions.

<Formulation 1 of the Coating Liquid for Thermoplastic Resin Layers>

| | | |
|---|---|---|
| Methyl methacrylate/2-ethylhexyl acrylate/benzyl methacry- | 58.4 | parts |
| late/methacrylic acid copolymer | | |
| (=55/11.7/4.5/28.8 [molar ratio], weight average molecular | | |
| weight 90,000) | | |
| Styrene/acrylic acid copolymer | 136 | parts |
| (63/37 [molar ratio], weight average molecular weight | | |
| 8,000) | | |
| 2,2-bis[4-(methacryloxy polyethoxy)phenyl]propane | 90.7 | parts |
| Surfactant MEGAFAC F-780-F | 5.4 | parts |
| (trade name, manufactured by DIC Corporation) | | |
| Methanol | 111 | parts |
| 1-methoxy-2-propanol | 63.4 | parts |
| Methyl ethyl ketone | 534 | parts |

Next, a coating liquid for intermediate layers produced according to the following formulation 2 was coated on the formed cushion layer, dried at 80° C. for 1 minute, and then, furthermore, dried at 120° C. for 1 minute, thereby forming an intermediate layer with a dried layer thickness of 1.6 μm.

<Formulation 2 of the Coating Liquid for Intermediate Layers >

| | | |
|---|---|---|
| Polyvinyl alcohol | 3.22 | parts |
| (PVA-205, trade name, manufactured by KURARAY Co., | | |
| Ltd., saponification value 88%) | | |
| Polyvinyl pyrrolidone | 1.49 | parts |
| (PVP K-30, trade name, manufactured by ISP JAPAN Co., | | |
| Ltd.) | | |
| Methanol | 42.9 | parts |
| Distilled water | 52.4 | parts |

A photosensitive conductive layer was formed by coating and drying the same coating liquid as the photopolymerizable conductive layer coating liquid used in Example 1 on the intermediate layer, thereby preparing a laminate body for forming conductive layers. Here, the amount of silver in a non-patterned conductive layer was 0.035 g/m², and the coating amount of the solid content of the photopolymerizable composition was 0.175 g/m².

For the obtained laminate body, the value of the ratio S/N of the average value S of the total layer thickness of the photosensitive conductive layer including a photosensitive matrix and the cushion layer to the average value N of the thickness of the transfer base material was 0.223.

<<Manufacturing of a Conductive Member>>

A conductive member having a patterned conductive layer on the base material was prepared by carrying out the transferring step, exposure step, development step and post basking step using the laminate body for forming conductive layers.

(Transferring Step)

The PET substrate obtained in Preparation Example 4 and the photosensitive conductive layer in the laminate body for forming conductive layers were overlapped and laminated so that the surface of the PET substrate and the surface of the photosensitive conductive layer were brought into contact with each other, thereby forming a laminate body having a laminate structure of transfer base material/cushion layer/intermediate layer/photosensitive conductive layer/PET substrate.

Next, the transfer base material was detached from the laminate body.

(Exposure Step)

The photosensitive conductive layer on the PET substrate was exposed through the cushion layer, the intermediate layer and a mask using i rays (365 nm) from an ultrahigh pressure mercury lamp at an exposure value of 40 mJ/cm². Here, the mask had a uniformly exposed portion for evaluating conduction, optical characteristics and film strength and a stripe pattern (line/space=50 μm/50 μm) for evaluating patterning properties.

(Development Step)

A 1% triethanolamine aqueous solution was supplied to the exposed specimen so as to dissolve and remove the thermoplastic resin layer (cushion layer) and the intermediate layer. The shortest removal time in which the layers could be fully removed was 30 seconds.

Next, the photosensitive conductive layer was shower-developed at 20° C. for 30 seconds with a conic nozzle pressure of 0.15 MPa using a sodium carbonate-based development liquid (containing 0.06 mole/liter of sodium hydrogen carbonate, the same concentration of sodium carbonate, 1% sodium dibutylnaphthalene sulfonate, an anionic surfactant, a defoamer and a stabilizer, T-CD1; trade name, manufactured by FUJIFILM Corporation), and dried at room temperature. Next, a heat treatment was carried out at 100° C. for 15 minutes. Thereby, a conductive layer including a conductive area and a non-conductive area was formed. The thickness of the conductive area was 0.011 μm.

<<Formation of a Protective Layer>>

The same sol-gel coating liquid as the sol-gel coating liquid obtained in Example 1 was coated on the patterned conductive layer so that the coating amount of the solid content became 0.50 g/m², then, dried at 140° C. for 1 minute, and a sol-gel reaction was caused so as to form a protective layer, thereby obtaining a conductive member of Example 46. The thickness of the protective layer was 0.13 μm.

### Examples 47 to 61

Conductive members of Examples 47 to 61 were obtained in a manner substantially similar to the preparation of the conductive member in Example 46 except that both 3-glycidoxypropyltrimethoxysilane and tetraethoxysilane, which were included in the sol-gel coating liquid used to form the protective layer in Example 46, were changed to (one or two) compounds described below with changed amounts in Examples 47 to 61. The respective thicknesses of the protective layers in the obtained conductive members will also be described below.

| | | | |
|---|---|---|---|
| Example 47: | 3-Glycidoxypropyltrimethoxysilane | 12.7 | parts |
| | (Thickness: 0.14 μm) | | |
| Example 48: | Tetraethoxysilane | 12.7 | parts |
| | (Thickness: 0.12 μm) | | |
| Example 49: | 3-Glycidoxypropyltrimethoxysilane | 0.6 | parts |
| | Tetraethoxysilane | 12.1 | parts |
| | (Thickness: 0.13 μm) | | |
| Example 50: | 3-Glycidoxypropyltrimethoxysilane | 1.3 | parts |
| | Tetraethoxysilane | 11.4 | parts |
| | (Thickness: 0.13 μm) | | |
| Example 51: | 3-Glycidoxypropyltrimethoxysilane | 3.8 | parts |
| | Tetraethoxysilane | 8.9 | parts |
| | (Thickness: 0.13 μm) | | |
| Example 52: | 3-Glycidoxypropyltrimethoxysilane | 6.35 | parts |
| | Tetraethoxysilane | 6.35 | parts |
| | (Thickness: 0.13 μm) | | |
| Example 53: | 3-Glycidoxypropyltrimethoxysilane | 10.2 | parts |
| | Tetraethoxysilane | 2.5 | parts |
| | (Thickness: 0.13 μm) | | |
| Example 54: | 3-Glycidoxypropyltrimethoxysilane | 12.5 | parts |
| | Tetraethoxysilane | 0.2 | parts |
| | (Thickness: 0.13 μm) | | |
| Example 55: | Tetrapropoxy titanate | 12.7 | parts |
| | (Thickness: 0.12 μm) | | |
| Example 56: | Tetraethoxy zirconate | 12.7 | parts |
| | (Thickness: 0.12 μm) | | |
| Example 57: | 2-(3,4-Epoxycyclohexyl)ethyltrimethoxy- | 5.9 | parts |
| | silane | | |
| | Tetramethoxysilane | 6.8 | parts |
| | (Thickness: 0.14 μm) | | |
| Example 58: | Ureidopropyltriethoxysilane | 5.9 | parts |
| | Tetraethoxysilane | 6.8 | parts |
| | (Thickness: 0.14 μm) | | |
| Example 59: | Diethyldimethoxysilane | 5.9 | parts |
| | Tetraethoxysilane | 6.8 | parts |
| | (Thickness: 0.13 μm) | | |
| Example 60: | Propyltriethoxy titanate | 5.9 | parts |
| | Tetraisopropoxy titanate | 6.8 | parts |
| | (Thickness: 0.12 μm) | | |
| Example 61: | Ethyltriethoxy zirconate | 5.9 | parts |
| | Tetrapropoxy zirconate | 6.8 | parts |
| | (Thickness: 0.12 μm) | | |

### Examples 62 to 66

Conductive members of Examples 62 to 66 were prepared in a manner substantially similar to that in Example 46 except that a coated solid amount of the sol-gel coating liquid for forming a protective layer in Example 46 was respectively changed as listed below in Examples 62 to 66. The resulting thickness of each protective layer was respectively such as described below.

Example 62: 1.00 g/m² (Thickness: 0.250 μm)

Example 63: 0.35 g/m² (Thickness: 0.092 μm)

Example 64: 0.15 g/m² (Thickness: 0.040 μm)

Example 65: 0.10 g/m² (Thickness: 0.026 μm)

Example 66: 0.05 g/m² (Thickness: 0.013 μm)

### Examples 67 to 71

Conductive members of Examples 67 to 71 were prepared in a manner substantially similar to that in Example 48 except that a coated solid amount of the sol-gel coating liquid for forming a protective layer in Example 48 was respectively changed as listed below in Examples 67 to 71. The resulting thickness of each protective layer was respectively such as described below.

Example 67: 1.00 g/m² (Thickness: 0.245 μm)

Example 68: 0.35 g/m² (Thickness: 0.090 μm)

Example 69: 0.15 g/m² (Thickness: 0.039 μm)

Example 70: 0.10 g/m² (Thickness: 0.025 μm)

Example 71: 0.05 g/m² (Thickness: 0.013 μm)

### Examples 72 to 75

Conductive members of Examples 72 to 75 were prepared by using the same coating liquid for forming the photopolymerizable conductive layer used in Example 46 in a manner substantially similar to that in Example 46 except that a coated solid amount of the photopolymerizable composition and a coated silver amount in Example 46 were respectively changed as listed below in Examples 72 to 75. The resulting thickness of each protective layer was respectively such as described below.

| | | |
|---|---|---|
| Example 72: | Coated solid amount of the photopolymeriz- | 0.500 g/m² |
| | able composition: | |
| | Silver amount: | 0.100 g/m² |
| | (Thickness: 0.028 μm) | |
| Example 73: | Coated solid amount of the photopolymeriz- | 0.100 g/m² |
| | able composition: | |
| | Silver amount: | 0.020 g/m² |
| | (Thickness: 0.006 μm) | |
| Example 74: | Coated solid amount of the photopolymeriz- | 0.050 g/m² |
| | able composition: | |
| | Silver amount: | 0.010 g/m² |
| | (Thickness: 0.003 μm) | |
| Example 75: | Coated solid amount of the photopolymeriz- | 0.025 g/m² |
| | able composition: | |
| | Silver amount: | 0.005 g/m² |
| | (Thickness: 0.001 μm) | |

### Examples 76 to 81

Conductive members of Examples 76 to 81 were prepared by using the same coating liquid for forming the photopolymerizable conductive layer used in Example 46 in a manner substantially similar to that in Example 46 except that a mixing ratio of the photopolymerizable composition, the dispersion liquid of silver nanowire in PEGMEA (1) and the solvent (PGMEA/MEK=1/1) in Example 46 were respectively changed so as to become the coated solid amount of the photopolymerizable composition and the coated silver amount as listed below in Examples 76 to 81. The resulting thickness of each protective layer was respectively such as described below.

| | | |
|---|---|---|
| Example 76: | Coated solid amount of the photopolymeriz- | 0.280 g/m² |
| | able composition: | |
| | Silver amount: | 0.035 g/m² |
| | (Thickness: 0.015 μm) | |
| Example 77: | Coated solid amount of the photopolymeriz- | 0.210 g/m² |
| | able composition: | |
| | Silver amount: | 0.035 g/m² |
| | (Thickness: 0.012 μm) | |
| Example 78: | Coated solid amount of the photopolymeriz- | 0.160 g/m² |
| | able composition: | |
| | Silver amount: | 0.020 g/m² |
| | (Thickness: 0.009 μm) | |
| Example 79: | Coated solid amount of the photopolymeriz- | 0.120 g/m² |
| | able composition: | |
| | Silver amount: | 0.020 g/m² |
| | (Thickness: 0.007 μm) | |
| Example 80: | Coated solid amount of the photopolymeriz- | 0.120 g/m² |
| | able composition: | |
| | Silver amount: | 0.015 g/m² |
| | (Thickness: 0.007 μm) | |
| Example 81: | Coated solid amount of the photopolymeriz- | 0.090 g/m² |
| | able composition: | |
| | Silver amount: | 0.015 g/m² |
| | (Thickness: 0.005 μm) | |

### Example 82

Conductive members of Example 82 was prepared in a manner substantially similar to that in Example 46 except that PET substrate in Example 46 was changed to the glass substrate formed in Preparation Example 3 in Example 82.

### Examples 83 to 90

Conductive members of Examples 83 to 90 were prepared in a manner substantially similar to that in Example 46 except that the dispersion liquid of silver nanowire in PEGMEA (1) (Silver nanowire PEGMEA dispersion) in Example 46 was respectively changed to the silver nanowire PEGMEA dispersion (2) to (9) respectively used in Examples 37 to 44.

Example 83: Silver nanowire PEGMEA dispersion (2)

Example 84: Silver nanowire PEGMEA dispersion (3)

Example 85: Silver nanowire PEGMEA dispersion (4)

Example 86: Silver nanowire PEGMEA dispersion (5)

Example 87: Silver nanowire PEGMEA dispersion (6)

Example 88: Silver nanowire PEGMEA dispersion (7)

Example 89: Silver nanowire PEGMEA dispersion (8)

Example 90: Silver nanowire PEGMEA dispersion (9)

### Comparative Example 2

A conductive member of Comparative Example 2 was obtained in a manner substantially similar to the preparation of the conductive member in Example 46 except that the protective layer in Example 46 was changed to the protective layer C1 of Comparative Example 1.

<<Evaluation>>

For the respective conductive members, the surface resistivity, optical characteristics (light transmittance, haze), film strength, abrasion resistance, heat resistance, moisture and heat resistance and bendability were evaluated using the same methods as used above. The results are described in Tables 4 and 5.

Meanwhile, Tables 4 and 5 describe the evaluation ranks of the surface resistivity of the respective conductive members before the formation of the protective layer as reference data.

TABLE 4

| | Performance Evaluation | | | | | | | | | | |
|---|---|---|---|---|---|---|---|---|---|---|---|
| Example | S.R. | | | | Film | Abr. | Heat Resistance | | Moist. Heat Resistance | | Bend- |
| Number | (B.F.P.L.) | S.R. | L. Trans. | Haze | Strength | Resist. | C.R.S.R. | C.D. Haze | C.R.S.R. | C.D. Haze | ability |
| 46 | 4 | 5 | A | A | 5 | 1.18 | 1.31 | 0.20 | 1.24 | 0.29 | 1.01 |
| 47 | 4 | 5 | A | A | 5 | 1.21 | 1.30 | 0.21 | 1.26 | 0.26 | 1.00 |
| 48 | 4 | 5 | A | A | 5 | 1.13 | 1.27 | 0.19 | 1.20 | 0.21 | 1.02 |
| 49 | 4 | 5 | A | A | 5 | 1.26 | 1.33 | 0.21 | 1.27 | 0.28 | 1.04 |
| 50 | 4 | 5 | A | A | 5 | 1.22 | 1.31 | 0.18 | 1.24 | 0.24 | 1.01 |
| 51 | 4 | 5 | A | A | 5 | 1.18 | 1.26 | 0.18 | 1.22 | 0.20 | 1.03 |
| 52 | 4 | 5 | A | A | 5 | 1.19 | 1.28 | 0.20 | 1.22 | 0.23 | 1.01 |
| 53 | 4 | 5 | A | A | 5 | 1.19 | 1.28 | 0.19 | 1.27 | 0.24 | 1.04 |
| 54 | 4 | 5 | A | A | 5 | 1.17 | 1.26 | 0.20 | 1.22 | 0.21 | 1.02 |
| 55 | 4 | 5 | A | A | 5 | 1.25 | 1.30 | 0.18 | 1.31 | 0.27 | 1.03 |
| 56 | 4 | 5 | A | A | 5 | 1.24 | 1.33 | 0.21 | 1.32 | 0.30 | 1.03 |
| 57 | 4 | 5 | A | A | 5 | 1.22 | 1.28 | 0.20 | 1.29 | 0.26 | 1.02 |
| 58 | 4 | 5 | A | A | 5 | 1.23 | 1.28 | 0.21 | 1.25 | 0.26 | 1.04 |
| 59 | 4 | 5 | A | A | 5 | 1.27 | 1.34 | 0.22 | 1.30 | 0.31 | 1.02 |
| 60 | 4 | 5 | A | A | 5 | 1.28 | 1.37 | 0.26 | 1.29 | 0.30 | 1.03 |
| 61 | 4 | 5 | A | A | 5 | 1.26 | 1.33 | 0.24 | 1.28 | 0.30 | 1.01 |
| 62 | 4 | 5 | A | A | 5 | 1.03 | 1.20 | 0.21 | 1.15 | 0.20 | 1.01 |
| 63 | 4 | 5 | A | A | 5 | 1.23 | 1.32 | 0.23 | 1.22 | 0.27 | 1.03 |
| 64 | 4 | 5 | A | A | 5 | 1.29 | 1.33 | 0.26 | 1.27 | 0.29 | 1.04 |
| 65 | 4 | 5 | A | A | 5 | 1.39 | 1.32 | 0.26 | 1.31 | 0.31 | 1.03 |
| 66 | 4 | 5 | A | A | 5 | 1.53 | 1.37 | 0.27 | 1.35 | 0.33 | 1.02 |
| 67 | 4 | 5 | A | A | 5 | 1.03 | 1.18 | 1.23 | 1.13 | 0.17 | 1.04 |
| 68 | 4 | 5 | A | A | 5 | 1.17 | 1.28 | 1.33 | 1.22 | 0.20 | 1.00 |

TABLE 5

| | Performance Evaluation | | | | | | | | | | |
|---|---|---|---|---|---|---|---|---|---|---|---|
| Example | S.R. | | | | Film | Abr. | Heat Resistance | | Moist. Heat Resistance | | Bend- |
| Number | (B.F.P.L.) | S.R. | L. Trans. | Haze | Strength | Resist. | C.R.S.R. | C.D. Haze | C.R.S.R. | C.D. Haze | ability |
| 69 | 4 | 5 | A | A | 5 | 1.23 | 1.27 | 1.32 | 1.25 | 0.24 | 1.02 |
| 70 | 4 | 5 | A | A | 5 | 1.32 | 1.30 | 1.35 | 1.26 | 0.29 | 1.01 |
| 71 | 4 | 5 | A | A | 5 | 1.49 | 1.33 | 1.38 | 1.32 | 0.31 | 1.02 |
| 72 | 5 | 5 | B | B | 5 | 1.16 | 1.23 | 0.21 | 1.21 | 0.23 | 1.01 |
| 73 | 4 | 5 | A | B | 5 | 1.19 | 1.24 | 0.23 | 1.22 | 0.28 | 1.04 |
| 74 | 3 | 4 | A | A | 5 | 1.31 | 1.35 | 0.26 | 1.30 | 0.27 | 1.04 |
| 75 | 2 | 3 | A | A | 5 | 1.38 | 1.40 | 0.28 | 1.38 | 0.31 | 1.01 |
| 76 | 4 | 5 | A | A | 5 | 1.15 | 1.23 | 0.23 | 1.24 | 0.25 | 1.04 |
| 77 | 4 | 5 | A | A | 5 | 1.15 | 1.24 | 0.24 | 1.26 | 0.27 | 1.06 |
| 78 | 4 | 4 | A | A | 5 | 1.19 | 1.29 | 0.27 | 1.28 | 0.26 | 1.04 |
| 79 | 4 | 4 | A | A | 5 | 1.22 | 1.28 | 0.29 | 1.27 | 0.26 | 1.04 |
| 80 | 3 | 4 | A | A | 5 | 1.21 | 1.34 | 0.29 | 1.30 | 0.29 | 1.02 |
| 81 | 3 | 4 | A | A | 5 | 1.26 | 1.32 | 0.31 | 1.31 | 0.28 | 1.02 |
| 82 | 4 | 5 | A | B | 5 | 1.17 | 1.31 | 0.22 | 1.25 | 0.26 | 1.03 |
| 83 | 4 | 5 | A | C | 5 | 1.18 | 1.39 | 0.30 | 1.22 | 0.21 | 1.02 |
| 84 | 3 | 3 | A | C | 5 | 1.19 | 1.35 | 0.22 | 1.23 | 0.24 | 1.01 |
| 85 | 4 | 4 | A | B | 5 | 1.16 | 1.31 | 0.19 | 1.23 | 0.23 | 1.02 |
| 86 | 4 | 4 | A | A | 5 | 1.21 | 1.28 | 0.21 | 1.30 | 0.26 | 1.03 |
| 87 | 4 | 4 | A | B | 5 | 1.19 | 1.41 | 0.28 | 1.28 | 0.26 | 1.01 |
| 88 | 4 | 4 | A | C | 5 | 1.22 | 1.38 | 0.24 | 1.27 | 0.26 | 1.04 |
| 89 | 3 | 3 | A | C | 5 | 1.17 | 1.35 | 0.19 | 1.23 | 0.22 | 1.01 |
| 90 | 4 | 4 | A | B | 5 | 1.20 | 1.29 | 0.17 | 1.23 | 0.21 | 1.01 |
| Co. Ex. 2 | 4 | 1 | A | B | 3 | 33.5 | 8.12 | 0.62 | 6.65 | 0.45 | 2.44 |

In Tables 4 and 5, the abbreviation “Co. Ex.” denotes “Comparative Example numb er”, the abbreviation “S.R.” denotes “Surface resistivity”, the abbreviation “B.F.P.L.” denotes “before formation of Protective layer”, the abbreviation “L. Trans.” denotes “Light transmittance”, the abbreviation “Abr. Resist.” denotes “Abrasion resistance”, the abbreviation “Moist. H eat Resistance” denotes “Moisture and heat resistance”, the abbreviation “C.R.S.R.” denotes “Change rate of surface resistivity”, and the abbreviation “C.D.Haze” denotes “Change degree of haze”.

From the results described in Tables 4 and 5, it can be understood that the conductive member in the invention is excellent in terms of conduction and transparency, excellent in terms of abrasion resistance, heat resistance, and moisture and heat resistance, and excellent in terms of bending resistance. Particularly, it is revealed that, when the protective layer is provided, significant effects that not only does the film strength significantly increase, but the surface resistivity also remains similar or improves to a lower value compared with conductive members not provided with the protective layer are exhibited.

### Example 91

<<Formation of a Conductive Layer>>

A solution of an alkoxide compound having the following composition was stirred at 60° C. for 1 hour, and was confirmed to be homogeneous. The obtained solution of an alkoxide compound (3.52 parts) and the silver nanowire aqueous dispersion liquid (1) obtained in Preparation Example 1 (16.56 parts) were mixed, and, furthermore, diluted using distilled water, thereby obtaining a silver-containing sol-gel coating liquid. A corona discharge treatment was carried out on the surface of a second adhesion layer 32 in the PET substrate 101, the silver-containing sol-gel coating liquid was coated on the surface using a bar coating method so that the amount of silver became 0.035 g/m² and the coating amount of the solid content of a sol-gel component in the silver-containing sol-gel coating liquid became 0.245 g/m², then, dried at 140° C. for 1 minute, and a sol-gel reaction was caused, thereby forming a conductive layer. The mass ratio of tetraethoxysilane to the metallic nanowires in the conductive layer became 7/1. In addition, the thickness of the conductive layer was 0.029 μm.

<Solution of an Alkoxide Compound>

| | |
|---|---|
| Tetraethoxysilane | 5.0 parts |
| (KBM-04; trade name, manufactured by SHIN-ETSU | |
| CHEMICAL Co., Ltd.) | |
| 1% aqueous solution of acetic acid | 10.0 parts |
| Distilled water | 4.0 parts |

<<Formation of a Protective Layer>>

The same sol-gel coating liquid as the sol-gel coating liquid for forming protective layers used in Example 1 was coated on the conductive layer so that the coating amount of the solid content became 0.50 g/m², then, dried at 140° C. for 1 minute, and a sol-gel reaction was caused so as to form a protective layer, thereby obtaining a conductive member including a non-patterned conductive layer. The thickness of the protective layer was 0.13 μm.

<<Patterning>>

A patterning treatment was carried out on the conductive member obtained above using the following method. WHT-3 and SQUEEGEE No. 4 YELLOW; trade name, manufactured by MINO GROUP Co., Ltd. were used in screen printing. A silver nanowire solution for forming patterns was formed by mixing a CP-48S-A liquid, a CP-48S-B liquid (all manufactured by FUJIFILM Corporation) and pure water so that the proportions became 1:1:1, and thickening the mixture using hydroxyethyl cellulose, and used as an ink for screen printing. A pattern mesh with a stripe pattern (line/space=50 μm/50 μm) was used. The patterning treatment was carried out, thereby forming a conductive layer including a conductive area and a non-conductive area. Thereby, a conductive member of Example 91 was obtained.

### Examples 92 to 106

Conductive members of Examples 92 to 106 were obtained in a manner substantially similar to the preparation of the conductive member in Example 91 except that both 3-glycidoxypropyltrimethoxysilane and tetraethoxysilane, which were included in the sol-gel coating liquid used to form the protective layer in Example 91, were changed to (one or two) compounds described below with changed amounts in Examples 92 to 106.

| | | | |
|---|---|---|---|
| Example 92: | 3-Glycidoxypropyltrimethoxysilane | 12.7 | parts |
| | (Thickness: 0.14 μm) | | |
| Example 93: | Tetraethoxysilane | 12.7 | parts |
| | (Thickness: 0.12 μm) | | |
| Example 94: | 3-Glycidoxypropyltrimethoxysilane | 0.6 | parts |
| | Tetraethoxysilane | 12.1 | parts |
| | (Thickness: 0.13 μm) | | |
| Example 95: | 3-Glycidoxypropyltrimethoxysilane | 1.3 | parts |
| | Tetraethoxysilane | 11.4 | parts |
| | (Thickness: 0.13 μm) | | |
| Example 96: | 3-Glycidoxypropyltrimethoxysilane | 3.8 | parts |
| | Tetraethoxysilane | 8.9 | parts |
| | (Thickness: 0.13 μm) | | |
| Example 97: | 3-Glycidoxypropyltrimethoxysilane | 6.35 | parts |
| | Tetraethoxysilane | 6.35 | parts |
| | (Thickness: 0.13 μm) | | |
| Example 98: | 3-Glycidoxypropyltrimethoxysilane | 10.2 | parts |
| | Tetraethoxysilane | 2.5 | parts |
| | (Thickness: 0.13 μm) | | |
| Example 99: | 3-Glycidoxypropyltrimethoxysilane | 12.5 | parts |
| | Tetraethoxysilane | 0.2 | parts |
| | (Thickness: 0.13 μm) | | |
| Example 100: | Tetrapropoxy titanate | 12.7 | parts |
| | (Thickness: 0.12 μm) | | |
| Example 101: | Tetraethoxy zirconate | 12.7 | parts |
| | (Thickness: 0.12 μm) | | |
| Example 102: | 2-(3,4-Epoxycyclohexyl)ethyltrimethoxy- | 5.9 | parts |
| | silane | | |
| | Tetramethoxysilane | 6.8 | parts |
| | (Thickness: 0.14 μm) | | |
| Example 103: | Ureidopropyltriethoxysilane | 5.9 | parts |
| | Tetraethoxysilane | 6.8 | parts |
| | (Thickness: 0.14 μm) | | |
| Example 104: | Diethyldimethoxysilane | 5.9 | parts |
| | Tetraethoxysilane | 6.8 | parts |
| | (Thickness: 0.13 μm) | | |
| Example 105: | Propyltriethoxy titanate | 5.9 | parts |
| | Tetraisopropoxy titanate | 6.8 | parts |
| | (Thickness: 0.12 μm) | | |
| Example 106: | Ethyltriethoxy zirconate | 5.9 | parts |
| | Tetrapropoxy zirconate | 6.8 | parts |
| | (Thickness: 0.12 μm) | | |

### Examples 107 to 111

Conductive members of Examples 107 to 111 were prepared in a manner substantially similar to that in Example 91 except that a coated solid amount of the sol-gel coating liquid for forming a protective layer in Example 91 was respectively changed as listed below in Examples 107 to 111. The resulting thickness of each protective layer was respectively such as described below.

Example 107: 1.00 g/m² (Thickness: 0.250 μm)

Example 108: 0.35 g/m² (Thickness: 0.092 μm)

Example 109: 0.15 g/m² (Thickness: 0.040 μm)

Example 110: 0.10 g/m² (Thickness: 0.026 μm)

Example 111: 0.05 g/m² (Thickness: 0.013 μm)

### Examples 112 to 116

Conductive members of Examples 112 to 116 were prepared in a manner substantially similar to that in Example 93 except that a coated solid amount of the sol-gel coating liquid for forming a protective layer in Example 93 was respectively changed as listed below in Examples 112 to 116. The resulting thickness of each protective layer was respectively such as described below.

Example 112: 1.00 g/m² (Thickness: 0.245 μm)

Example 113: 0.35 g/m² (Thickness: 0.090 μm)

Example 114: 0.15 g/m² (Thickness: 0.039 μm)

Example 115: 0.10 g/m² (Thickness: 0.025 μm)

Example 116: 0.05 g/m² (Thickness: 0.013 μm)

### Examples 117 to 120

Conductive members of Examples 117 to 120 were prepared by using the same sol-gel coating liquid containing silver nanowire used in Example 91 in a manner substantially similar to that in Example 91 except that a coated solid amount of the sol-gel component (tetraethoxysilane) in the sol-gel coating liquid containing silver nanowire and a coated silver amount in Example 91 were respectively changed as listed below in Examples 117 to 120. The resulting thickness of each protective layer was respectively such as described below.

| | | |
|---|---|---|
| Example 117: | Coated solid amount of the sol-gel | 0.700 g/m² |
| | component: | |
| | Silver amount: | 0.100 g/m² |
| | (Thickness: 0.185 μm) | |
| Example 118: | Coated solid amount of the sol-gel | 0.140 g/m² |
| | component: | |
| | Silver amount: | 0.020 g/m² |
| | (Thickness: 0.037 μm) | |
| Example 119: | Coated solid amount of the sol-gel | 0.070 g/m² |
| | component: | |
| | Silver amount: | 0.010 g/m² |
| | (Thickness: 0.018 μm) | |
| Example 120: | Coated solid amount of the sol-gel | 0.035 g/m² |
| | component: | |
| | Silver amount: | 0.005 g/m² |
| | (Thickness: 0.009 μm) | |

### Examples 121 to 126

Conductive members of Examples 121 to 126 were prepared in a manner substantially similar to that in Example 91 except that a mixing ratio of the alkoxide compound solution, the silver nanowire aqueous dispersion liquid (1) and the solvent (distilled water) in the sol-gel coating liquid containing the silver nanowire for forming the conductive layer used in Example 91 were respectively changed so as to become the coated solid amount of the sol-gel component (tetraethoxysilane) and the coated silver amount as listed below in Examples 121 to 126. The resulting thickness of each conductive layer was respectively such as described below.

| | | |
|---|---|---|
| Example 121: | Coated solid amount of the sol-gel | 0.350 g/m² |
| | component: | |
| | Silver amount: | 0.035 g/m² |
| | (Thickness: 0.092 μm) | |
| Example 122: | Coated solid amount of the sol-gel | 0.280 g/m² |
| | component: | |
| | Silver amount: | 0.035 g/m² |
| | (Thickness: 0.073 μm) | |
| Example 123: | Coated solid amount of the sol-gel | 0.200 g/m² |
| | component: | |
| | Silver amount: | 0.020 g/m² |
| | (Thickness: 0.052 μm) | |
| Example 124: | Coated solid amount of the sol-gel | 0.160 g/m² |
| | component: | |
| | Silver amount: | 0.020 g/m² |
| | (Thickness: 0.042 μm) | |
| Example 125: | Coated solid amount of the sol-gel | 0.150 g/m² |
| | component: | |
| | Silver amount: | 0.015 g/m² |
| | (Thickness: 0.040 μm) | |
| Example 126: | Coated solid amount of the sol-gel | 0.120 g/m² |
| | component: | |
| | Silver amount: | 0.015 g/m² |
| | (Thickness: 0.032 μm) | |

### Example 127

Conductive members of Example 127 was prepared in a manner substantially similar to that in Example 91 except that PET substrate in Example 91 was changed to the glass substrate formed in Preparation Example 3 in Example 127.

### Examples 128 to 135

Conductive members of Examples 128 to 135 were prepared in a manner substantially similar to that in Example 91 except that the aqueous dispersion liquid of silver nanowire (1) in the sol-gel coating liquid containing the silver nanowire for forming the conductive layer used in Example 91 were respectively changed to the aqueous dispersion liquid of silver nanowire (2) to (9), in which the average length of short axis and the average length of long axis of the silver nanowire thereof respectively as listed in table 6 below, in Examples 121 to 126.

TABLE 6

| Example | Silver nanowire aqueous dispersion liquid | | |
|---|---|---|---|
| Number | Number | Long axis length (μm) | Short axis length (nm) |
| 128 | (2) | 21.5 | 30.5 |
| 129 | (3) | 24.4 | 42.8 |
| 130 | (4) | 17.9 | 61.1 |
| 131 | (5) | 15.1 | 20.0 |
| 132 | (6) | 7.9 | 17.9 |
| 133 | (7) | 10.2 | 28.9 |
| 134 | (8) | 8.8 | 45.1 |
| 135 | (9) | 8.6 | 59.3 |

<<Evaluation>>

For the respective conductive members, the surface resistivity, optical characteristics (light transmittance, haze), film strength, abrasion resistance, heat resistance, moisture and heat resistance and bendability were evaluated using the same methods as used above. The results are described in Tables 7 and 8.

Meanwhile, Tables 7 and 8 describe the evaluation ranks of the surface resistivity of the respective conductive members before the formation of the protective layer as reference data.

TABLE 7

| | Performance Evaluation | | | | | | | | | | |
|---|---|---|---|---|---|---|---|---|---|---|---|
| Example | S.R. | | | | Film | Abr. | Heat Resistance | | Moist. Heat Resistance | | Bend- |
| Number | (B.F.P.L.) | S.R. | L. Trans. | Haze | Strength | Resist. | C.R.S.R. | C.D. Haze | C.R.S.R. | C.D. Haze | ability |
| 91 | 4 | 5 | A | A | 5 | 1.11 | 1.18 | 0.08 | 1.09 | 0.08 | 1.02 |
| 92 | 4 | 5 | A | A | 5 | 1.14 | 1.17 | 0.09 | 1.11 | 0.05 | 1.01 |
| 93 | 4 | 5 | A | A | 5 | 1.06 | 1.14 | 0.07 | 1.05 | 0.03 | 1.03 |
| 94 | 4 | 5 | A | A | 5 | 1.16 | 1.20 | 0.09 | 1.12 | 0.07 | 1.02 |
| 95 | 4 | 5 | A | A | 5 | 1.12 | 1.18 | 0.06 | 1.09 | 0.03 | 1.05 |
| 96 | 4 | 5 | A | A | 5 | 1.08 | 1.13 | 0.06 | 1.07 | 0.04 | 1.04 |
| 97 | 4 | 5 | A | A | 5 | 1.09 | 1.12 | 0.08 | 1.07 | 0.02 | 1.02 |
| 98 | 4 | 5 | A | A | 5 | 1.09 | 1.12 | 0.07 | 1.12 | 0.03 | 1.02 |
| 99 | 4 | 5 | A | A | 5 | 1.07 | 1.10 | 0.08 | 1.07 | 0.00 | 1.02 |
| 100 | 4 | 5 | A | A | 5 | 1.15 | 1.14 | 0.06 | 1.16 | 0.06 | 1.01 |
| 101 | 4 | 5 | A | A | 5 | 1.14 | 1.17 | 0.09 | 1.17 | 0.09 | 1.02 |
| 102 | 4 | 5 | A | A | 5 | 1.12 | 1.15 | 0.08 | 1.14 | 0.05 | 1.02 |
| 103 | 4 | 5 | A | A | 5 | 1.13 | 1.15 | 0.09 | 1.10 | 0.05 | 1.04 |
| 104 | 4 | 5 | A | A | 5 | 1.17 | 1.21 | 0.10 | 1.15 | 0.10 | 1.02 |
| 105 | 4 | 5 | A | A | 5 | 1.18 | 1.24 | 0.14 | 1.14 | 0.09 | 1.03 |
| 106 | 4 | 5 | A | A | 5 | 1.16 | 1.20 | 0.12 | 1.13 | 0.09 | 1.02 |
| 107 | 4 | 5 | A | A | 5 | 0.96 | 1.07 | 0.07 | 1.00 | 0.04 | 1.02 |
| 108 | 4 | 5 | A | A | 5 | 1.16 | 1.19 | 0.09 | 1.07 | 0.06 | 1.02 |
| 109 | 4 | 5 | A | A | 5 | 1.22 | 1.20 | 0.12 | 1.12 | 0.08 | 1.05 |
| 110 | 4 | 5 | A | A | 5 | 1.32 | 1.19 | 0.12 | 1.16 | 0.10 | 1.04 |
| 111 | 4 | 5 | A | A | 5 | 1.46 | 1.24 | 0.13 | 1.20 | 0.12 | 1.06 |
| 112 | 4 | 5 | A | A | 5 | 1.00 | 1.05 | 0.06 | 1.00 | 0.01 | 1.03 |
| 113 | 4 | 5 | A | A | 5 | 1.10 | 1.15 | 0.10 | 1.07 | 0.04 | 1.01 |

TABLE 8

| | Performance Evaluation | | | | | | | | | | |
|---|---|---|---|---|---|---|---|---|---|---|---|
| Example | S.R. | | | | Film | Abr. | Heat Resistance | | Moist. Heat Resistance | | Bend- |
| Number | (B.F.P.L.) | S.R. | L. Trans. | Haze | Strength | Resist. | C.R.S.R. | C.D. Haze | C.R.S.R. | C.D. Haze | ability |
| 114 | 4 | 5 | A | A | 5 | 1.16 | 1.14 | 0.12 | 1.10 | 0.03 | 1.03 |
| 115 | 4 | 5 | A | A | 5 | 1.25 | 1.17 | 0.13 | 1.11 | 0.08 | 1.02 |
| 116 | 4 | 5 | A | A | 5 | 1.42 | 1.20 | 0.13 | 1.17 | 0.10 | 1.03 |
| 117 | 5 | 5 | B | B | 5 | 1.09 | 1.10 | 0.09 | 1.06 | 0.02 | 1.02 |
| 118 | 4 | 5 | A | B | 5 | 1.12 | 1.11 | 0.11 | 1.07 | 0.07 | 1.05 |
| 119 | 3 | 4 | A | A | 5 | 1.24 | 1.22 | 0.12 | 1.15 | 0.06 | 1.02 |
| 120 | 2 | 3 | A | A | 5 | 1.31 | 1.27 | 0.14 | 1.23 | 0.10 | 1.04 |
| 121 | 4 | 5 | A | A | 5 | 1.08 | 1.10 | 0.09 | 1.09 | 0.04 | 1.05 |
| 122 | 4 | 5 | A | A | 5 | 1.08 | 1.11 | 0.10 | 1.11 | 0.06 | 1.07 |
| 123 | 4 | 4 | A | A | 5 | 1.12 | 1.16 | 0.13 | 1.13 | 0.05 | 1.05 |
| 124 | 4 | 4 | A | A | 5 | 1.15 | 1.15 | 0.15 | 1.12 | 0.05 | 1.05 |
| 125 | 3 | 4 | A | A | 5 | 1.14 | 1.21 | 0.15 | 1.15 | 0.08 | 1.03 |
| 126 | 3 | 4 | A | A | 5 | 1.19 | 1.19 | 0.17 | 1.16 | 0.07 | 1.04 |
| 127 | 4 | 5 | A | B | 5 | 1.10 | 1.18 | 0.08 | 1.10 | 0.05 | 1.04 |
| 128 | 4 | 5 | A | C | 5 | 1.08 | 1.26 | 0.18 | 1.07 | 0.05 | 1.02 |
| 129 | 3 | 3 | A | C | 5 | 1.09 | 1.22 | 0.10 | 1.08 | 0.03 | 1.02 |
| 130 | 4 | 4 | A | B | 5 | 1.06 | 1.18 | 0.07 | 1.08 | 0.02 | 1.02 |
| 131 | 4 | 4 | A | A | 5 | 1.11 | 1.15 | 0.09 | 1.15 | 0.05 | 1.01 |
| 132 | 4 | 4 | A | B | 5 | 1.09 | 1.28 | 0.16 | 1.13 | 0.05 | 1.02 |
| 133 | 4 | 4 | A | C | 5 | 1.12 | 1.25 | 0.12 | 1.12 | 0.05 | 1.05 |
| 134 | 3 | 3 | A | C | 5 | 1.07 | 1.22 | 0.07 | 1.08 | 0.01 | 1.02 |
| 135 | 4 | 4 | A | B | 3 | 1.10 | 1.16 | 0.05 | 1.08 | 0.02 | 1.02 |

In Tables 7 and 8, the abbreviation “S.R.” denotes “Surface resistivity”, the abbreviation “B.F.P.L.” denotes “before formation of Protective layer”, the abbreviation “L. Trans.” denotes “Light transmittance”, the abbreviation “Abr. Resist.” denotes “Abrasion resistance”, the abbreviation “Moist. Heat Resistance” denotes “Moisture and heat resistance”, the abbreviation “C.R.S.R.” denotes “Change rate of surface resistivity”, and the abbreviation “C.D.Haze” denotes “Change degree of haze”.

From the results described in Tables 7 and 8, it can be understood that the conductive member in the invention is excellent in terms of conduction and transparency, excellent in terms of abrasion resistance, heat resistance, and moisture and heat resistance, and excellent in terms of bending resistance. Particularly, it is revealed that, when the protective layer is provided, significant effects that not only does the film strength significantly increase, but the surface resistivity also remains similar or improves to a lower value compared with conductive members not provided with the protective layer are exhibited.

### Examples 136 to 139

Conductive members of Examples 136 to 139 were obtained in a manner substantially similar to that of the conductive member in Example 109 except that the sol-gel coating liquid for forming protective layers in Example 109 was adjusted under the following conditions in Examples 136 to 139. The thicknesses of the respective protective layers were as follows. The weight average molecular weight (Mw) of the partial condensate of the alkoxide compound included in the sol-gel coating liquid was measured using GPC (in terms of polystyrene).

Example 109: stirred at 60° C. for 1.0 hour, thickness: 0.040 μm, Mw: 3,500

Example 136: stirred at 60° C. for 1.5 hours; thickness: 0.042 μm; Mw:9,600

Example 137: stirred at 60° C. for 2.0 hours; thickness: 0.043 μm; Mw:19,000

Example 138: stirred at 60° C. for 2.5 hours; thickness: 0.044 μm; Mw:37,000

Example 139: stirred at 60° C. for 3.0 hours; thickness: 0.046 μm; Mw:70,000

### Examples 140 to 143

Conductive members of Examples 140 to 143 were prepared in a manner substantially similar to that in Example 114 except that the conditions for preparing the sol-gel coating liquid for forming the protective layer used in Example 114 were respectively changed to the conditions described below in Examples 140 to 143. The resulting thickness of each conductive layer and the weight average molecular weight (Mw) of the partial condensation product of the alkoxide compound contained in the sol-gel coating liquid were respectively such as described below.

Example 114: stirred at 60° C. for 1.0 hour; thickness: 0.039 μm; Mw:4,400

Example 140: stirred at 60° C. for 1.5 hours; thickness: 0.040 μm; Mw:12,000

Example 141: stirred at 60° C. for 2.0 hours; thickness: 0.041 μm; Mw:24,000

Example 142: stirred at 60° C. for 2.5 hours; thickness: 0.042 μm; Mw:46,000

Example 143: stirred at 60° C. for 3.0 hours; thickness: 0.044 μm; Mw:87,000

<<Evaluation>>

For the respective conductive members, the surface resistivity, optical characteristics (light transmittance, haze), film strength, abrasion resistance, heat resistance, moisture and heat resistance and bendability were evaluated using the same methods as used above, and the etchability was evaluated in accordance with the following method.

<Etchability>

The obtained conductive members were immersed in an etchant (etchant temperature of 25° C.) with the following composition for different periods of from 30 seconds to 180 seconds, then, washed using flowing water, and dried. The surface resistivity was measured using LORESTA-GP MCP-T600; trade name, manufactured by MITSUBISHI CHEMICAL Corporation, and the haze was measured using a HAZE-GARD PLUS; trade name, manufactured by GARTNER, Inc. As the surface resistivity after the immersion in the etchant is larger and the Δ haze (change degree of haze; the difference in haze before and after the immersion) increases, the etchability is excellent. The time (immersion time) necessary for the surface resistivity to become 10⁸Ω/□ and for the haze difference obtained by subtracting the haze after the immersion from the haze before the immersion in the etchant to become 0.4% or more when immersing the conductive layer in the etchant at 25° C. was obtained, and rated using the following ranks.

[The Composition of the Etchant]: An Aqueous Solution Containing the Following Components

| | |
|---|---|
| Ferric ammonium ethylenediaminetetraacetate | 2.5% by mass |
| Thio ammonium sulfate | 7.5% by mass |
| Ammonium sulfite | 2.5% by mass |
| Ammonium bisulfite | 2.5% by mass |
| Water | 85.0% by mass |

Rank 5: the immersion time in the etchant is 30 seconds or less until the surface resistivity becomes 1.0×10⁸Ω/□ or more and the Δ haze becomes 0.4% or more, an extremely outstanding level

Rank 4: the time is from 30 seconds to less than 60 seconds, an outstanding level

Rank 3: the time is from 60 seconds to less than 120 seconds, a favorable level

Rank 2: the time is from 120 seconds to less than 180 seconds, a practically problematic level

Rank 1: the time is 180 seconds or longer, a practically problematic level

The results are described in Table 9.

Meanwhile, Table 9 describes the evaluation ranks of the surface resistivity of the respective conductive members before the formation of the protective layer as reference data.

TABLE 9

| | Performance Evaluation | | | | | | | | | | | |
|---|---|---|---|---|---|---|---|---|---|---|---|---|
| Example | S.R. | | | | Film | Abr. | Heat Resistance | | Moist. Heat Resistance | | Bend- | |
| Number | (B.F.P.L.) | S.R. | L. Trans. | Haze | Strength | Resist. | C.R.S.R. | C.D. Haze | C.R.S.R. | C.D. Haze | ability | Etch. |
| 109 | 4 | 5 | A | A | 5 | 1.22 | 1.20 | 0.12 | 1.12 | 0.08 | 1.05 | 3 |
| 136 | 4 | 5 | A | A | 5 | 1.23 | 1.21 | 0.11 | 1.11 | 0.09 | 1.06 | 4 |
| 137 | 4 | 5 | A | A | 5 | 1.25 | 1.19 | 0.10 | 1.10 | 0.10 | 1.03 | 4 |
| 138 | 4 | 5 | A | A | 5 | 1.29 | 1.18 | 0.12 | 1.12 | 0.09 | 1.04 | 5 |
| 139 | 4 | 5 | A | A | 4 | 1.35 | 1.21 | 0.13 | 1.12 | 0.09 | 1.03 | 5 |
| 114 | 4 | 4 | A | A | 5 | 1.16 | 1.14 | 0.12 | 1.10 | 0.03 | 1.03 | 3 |
| 140 | 4 | 5 | A | A | 5 | 1.17 | 1.16 | 0.11 | 1.08 | 0.05 | 1.01 | 4 |
| 141 | 4 | 5 | A | A | 5 | 1.18 | 1.15 | 0.12 | 1.06 | 0.04 | 1.02 | 4 |
| 142 | 4 | 5 | A | A | 5 | 1.20 | 1.13 | 0.11 | 1.10 | 0.03 | 0.99 | 5 |
| 143 | 4 | 4 | A | A | 4 | 1.22 | 1.14 | 0.13 | 1.09 | 0.05 | 1.00 | 5 |

In Table 9, the abbreviation “S.R.” denotes “Surface resistivity”, the abbreviation “B.F.P.L.” denotes “before formation of Protective layer”, the abbreviation “L. Trans.” denotes “Light transmittance”, the abbreviation “Abr. Resist.” denotes “Abrasion resistance”, the abbreviation “Moist. Heat Resistance” denotes “Moisture and heat resistance”, the abbreviation “C.R.S.R.” denotes “Change rate of surface resistivity”, the abbreviation “C.D.Haze” denotes “Change degree of haze”, and the abbreviation “Etch.” denotes “Etchability”.

### Manufacturing of Example 144

A conductive member 144 was obtained in a manner substantially similar to the preparation of the conductive member in Example 91 except that a silver nanowire dispersion liquid (10) obtained by diluting a silver nanowire dispersion liquid prepared according to Examples 1 and 2 described in Paragraphs [0151] to [0160] of the specification of U.S. Patent Application Publication No. 2011/0174190A1 to 0.85% using distilled water in Example 144 instead of the silver nanowire aqueous dispersion liquid (1) in Example 91.

### Examples 145 to 154

Conductive members of Examples 145 to 154 were prepared in a manner substantially similar to each of that in Examples 93, 96, 98, 109, 114, 118, and 123 to 126 except that a mixing ratio of the alkoxide compound solution, the aqueous dispersion liquid of silver nanowire (1) for forming the conductive member used in Example 91 were respectively changed to the aqueous dispersion liquid of silver nanowire (10) described above in Examples 145 to 154.

Examples 145: Examples 93

Examples 146: Examples 96

Examples 147: Examples 98

Examples 148: Examples 109

Examples 149: Examples 114

Examples 150: Examples 118

Examples 151: Examples 123

Examples 152: Examples 124

Examples 153: Examples 125

Examples 154: Examples 126

<<Evaluation>>

For the respective conductive members, the surface resistivity, optical characteristics (light transmittance, haze), film strength, abrasion resistance, heat resistance, moisture and heat resistance and bendability were evaluated using the same methods as used above. The results are described in Table 10.

TABLE 10

| | Performance Evaluation | | | | | | | | | | |
|---|---|---|---|---|---|---|---|---|---|---|---|
| Example | S.R. | | | | Film | Abr. | Heat Resistance | | Moist. Heat Resistance | | Bend- |
| Number | (B.F.P.L.) | S.R. | L. Trans. | Haze | Strength | Resist. | C.R.S.R. | C.D. Haze | C.R.S.R. | C.D. Haze | ability |
| 144 | 4 | 5 | A | A | 5 | 1.12 | 1.17 | 0.07 | 1.10 | 0.07 | 1.02 |
| 145 | 4 | 5 | A | A | 5 | 1.05 | 1.13 | 0.06 | 1.06 | 0.00 | 1.01 |
| 146 | 4 | 5 | A | A | 5 | 1.07 | 1.13 | 0.07 | 1.08 | 0.04 | 1.03 |
| 147 | 4 | 5 | A | A | 5 | 1.10 | 1.11 | 0.06 | 1.13 | 0.02 | 1.01 |
| 148 | 4 | 5 | A | A | 5 | 1.23 | 1.21 | 0.11 | 1.12 | 0.07 | 1.06 |
| 149 | 4 | 5 | A | A | 5 | 1.15 | 1.15 | 0.10 | 1.11 | 0.04 | 1.04 |
| 150 | 4 | 5 | A | B | 5 | 1.13 | 1.12 | 0.11 | 1.06 | 0.08 | 1.04 |
| 151 | 4 | 4 | A | A | 5 | 1.15 | 1.15 | 0.12 | 1.12 | 0.06 | 1.04 |
| 152 | 4 | 4 | A | A | 5 | 1.16 | 1.14 | 0.16 | 1.11 | 0.05 | 1.06 |
| 153 | 3 | 4 | A | A | 5 | 1.17 | 1.20 | 0.15 | 1.16 | 0.07 | 1.04 |
| 154 | 3 | 4 | A | A | 5 | 1.21 | 1.17 | 0.18 | 1.15 | 0.08 | 1.05 |

In Table 10, the abbreviation “S.R.” denotes “Surface resistivity”, the abbreviation “B.F.P.L.” denotes “before formation of Protective layer”, the abbreviation “L. Trans.” denotes “Light transmittance”, the abbreviation “Abr. Resist.” denotes “Abrasion resistance”, the abbreviation “Moist. Heat Resistance” denotes “Moisture and heat resistance”, the abbreviation “C.R.S.R.” denotes “Change rate of surface resistivity”, and the abbreviation “C.D.Haze” denotes “Change degree of haze”.

From the results described in Table 10, it is understood that the conductive member for which the silver nanowires described in US-A No. 2011/0174190A1 were used is also excellent in terms of light transmittance, haze, film strength and abrasion resistance.

### Example 155

A conductive member was obtained in a manner substantially similar to the preparation of the conductive member in Example 91 except that a protective layer was formed using a liquid for which a solution of an alkoxide compound (11.71 parts) and the silver nanowire aqueous dispersion liquid (1) (18.29 parts) were mixed. The thickness of the protective layer was 0.12 μm.

### Examples 156 and 157

Conductive members of Examples 156 and 157 were obtained in a manner substantially similar to the preparation of the conductive member in Example 155 except that the mixing amounts of the solution of an alkoxide compound and the silver nanowire aqueous solution (1) in Example 155 were changed as follows in Examples 156 and 157.

| | | |
|---|---|---|
| Example 156: | the solution of an alkoxide compound | 14.69 parts |
| | silver nanowire aqueous solution (1) | 15.31 parts |
| | (thickness: 0.13 μm) | |
| Example 157: | the solution of an alkoxide compound | 18.46 parts |
| | silver nanowire aqueous solution (1) | 11.54 parts |
| | (thickness: 0.12 μm) | |

<<Evaluation>>

For the respective conductive members, the surface resistivity, optical characteristics (light transmittance, haze), film strength, abrasion resistance, heat resistance, moisture and heat resistance and bendability were evaluated using the same methods as used above. The results are described in Table 11.

TABLE 11

| | Performance Evaluation | | | | | | | | | | |
|---|---|---|---|---|---|---|---|---|---|---|---|
| Example | S.R. | | | | Film | Abr. | Heat Resistance | | Moist. Heat Resistance | | Bend- |
| Number | (B.F.P.L.) | S.R. | L. Trans. | Haze | Strength | Resist. | C.R.S.R. | C.D. Haze | C.R.S.R. | C.D. Haze | ability |
| 155 | 5 | 5 | A | A | 5 | 1.13 | 1.12 | 0.05 | 1.08 | 0.07 | 1.02 |
| 156 | 5 | 5 | A | A | 5 | 1.15 | 1.12 | 0.05 | 1.06 | 0.06 | 1.02 |
| 157 | 5 | 5 | A | A | 5 | 1.17 | 1.10 | 0.04 | 1.05 | 0.05 | 1.04 |

In Table 11, the abbreviation “S.R.” denotes “Surface resistivity”, the abbreviation “B.F.P.L.” denotes “before formation of Protective layer”, the abbreviation “L. Trans.” denotes “Light transmittance”, the abbreviation “Abr. Resist.” denotes “Abrasion resistance”, the abbreviation “Moist. Heat Resistance” denotes “Moisture and heat resistance”, the abbreviation “C.R.S.R.” denotes “Change rate of surface resistivity”, and the abbreviation “C.D.Haze” denotes “Change degree of haze”.

### Example 158

<Manufacturing of an Integrated Solar Cell>

—Manufacturing of a (Super Straight-Type) Amorphous Solar Cell—

A conductive layer and a protective layer were formed on a glass substrate in a manner substantially similar to the preparation of the conductive member in Example 1, thereby manufacturing a conductive member of Example 158. Here, a patterning treatment was not carried out so that the transparent conductive layer with a uniform surface was formed. An approximately 15 nm-thick p-type amorphous silicon film, an approximately 350 nm-thick i-type amorphous silicon film, and an approximately 30 nm-thick n-type amorphous silicon film were formed on the top portion of the conductive member using a plasma CVD method, and a 20 nm-thick gallium-added zinc oxide layer and a 200 nm-thick silver layer were formed as rear surface reflection electrodes, thereby manufacturing a photoelectric conversion element 101.

<Manufacturing of a (Substrate-Type) GIGS Solar Cell>

An approximately 500 nm-thick molybdenum electrode, an approximately 2.5 μm-thick Cu(In_{0.6}Ga_{0.4})Se₂ thin film which is a chalcopyrite-based semiconductor material, and an approximately 50 nm-thick cadmium sulfide thin film were formed on a soda lime glass substrate using a direct current magnetron sputtering method, a vacuum deposition method and a solution precipitation method respectively.

The conductive layer and the protective layer of Example 1 were formed on the cadmium sulfide thin film, and a transparent conductive film was formed on a glass substrate, thereby manufacturing a photoelectric conversion element 201.

Pseudo solar light rays of AM 1.5, 100 mW/cm² were radiated on the respective solar cells, thereby measuring photoelectric conversion efficiencies. As a result, the photoelectric conversion element 101 exhibited a conversion efficiency of 10%, and the photoelectric conversion element 201 exhibited a conversion efficiency of 9%.

It is revealed that a high conversion efficiency is obtained in any of integrated solar cell methods.

### Example 159

—Manufacturing of a Touch Panel—

The conductive layer and the protective layer of Example 1 were formed, and a transparent conductive film was formed on a glass substrate. A touch panel was manufactured using the obtained transparent conductive film and a method described in “Advanced Touch Panel Technologies” (published on Jul. 6, 2009 by TECHNO TIMES Co., Ltd.), “Technology and Development of Touch Panels” edited by Yuuji Mitani, (CMC PUBLISHING Co., Ltd. (published in December 2004)), “FPD International 2009 Forum T-11 lecture textbook”, “CYPRESS SEMICONDUCTOR Corporation Application Note AN2292” and the like.

It was revealed that, in a case in which the manufactured touch panel is used, it is possible to manufacture a touch panel which is excellent in terms of visibility due to the improvement of light transmittance, and is excellent in terms of responsiveness to input of letters and the like or screen operation using at least one of a bare hand, a hand in a glove and a stylus due to the improvement of conduction.

The foregoing description of the exemplary embodiments of the present invention has been provided for the purposes of illustration and description. It is not intended to be exhaustive or to limit the invention to the precise forms disclosed. The embodiments were chosen and described in order to best explain the principles of the invention and its practical applications, thereby enabling others skilled in the art to understand the invention for various embodiments and with the various modifications as are suited to the particular use contemplated.

This application claims priority from Japanese Patent Application Nos. 2011-090346 filed on Apr. 14, 2011, 2011-263073 filed on Nov. 30, 2011, and 2012-068214 filed on Mar. 23, 2012, the disclosures of which are incorporated by reference herein. All publications, patent applications, and technical standards mentioned in this specification are herein incorporated by reference to the same extent as if such individual publication, patent application, or technical standard was specifically and individually indicated to be incorporated by reference. It will be obvious to those having skill in the art that many changes may be made in the above-described details of the preferred embodiments of the present invention. It is intended that the scope of the invention be defined by the following claims and their equivalents.

What is claimed is:

1. A conductive member comprising:
a base material;
a conductive layer provided on the base material, the conductive layer comprising
a metallic nanowire having an average short-axis length of 150 nm or less, and
a matrix; and
a protective layer comprising a three-dimensional crosslinked structure represented by the following Formula (I), sequentially in this order, and a surface resistivity of the conductive member measured at a surface of the protective layer being 1,000Ω/□ or less,
-M¹-O-M¹- Formula (I):
wherein, in Formula (I), M¹ represents an element selected from the group consisting of Si, Ti, Zr and Al.

2. The conductive member according to claim 1, wherein the matrix is a cured product of a photopolymerizable composition or a sol-gel cured product obtained by hydrolysis and condensation of at least one alkoxide compound of an element selected from the group consisting of Si, Ti, Zr and Al.

3. The conductive member according to claim 1, wherein the protective layer comprises a sol-gel cured product obtained by hydrolysis and condensation of at least one alkoxide compound of an element selected from the group consisting of Si, Ti, Zr and Al.

4. The conductive member according to claim 3, wherein the alkoxide compound in the protective layer comprises at least one selected from the group consisting of a compound represented by the following Formula (II) and a compound represented by the following Formula (III),
M²(OR¹)₄ Formula (II):
M³(OR²)ₐR³₄₋ₐ Formula (III):
wherein, in Formula (II), M² represents an element selected from the group consisting of Si, Ti and Zr, and each of a plurality of R¹ independently represents a hydrogen atom or a hydrocarbon group, and, in Formula (III), M³ represents an element selected from the group consisting of Si, Ti and Zr, and each of a plurality of R² and each of a plurality of R³ independently represents a hydrogen atom or a hydrocarbon group, and “a” represents an integer from 1 to 3.

5. The conductive member according to claim 4, wherein the alkoxide compound in the protective layer comprises (i) at least one of the compound represented by Formula (II), and (ii) at least one of the compound represented by Formula (III).

6. The conductive member according to claim 5, wherein a mass ratio of the compound (ii) to the compound (i) (the compound (ii)/the compound (i)) is in a range of from 0.01/1 to 100/1.

7. The conductive member according to claim 4, wherein both of M² in Formula (II) and M³ in Formula (III) are Si.

8. The conductive member according to claim 1, wherein the metallic nanowire is a silver nanowire.

9. The conductive member according to claim 1, wherein the surface resistivity of the conductive member after immersion for 120 seconds in an etching liquid having the following composition at a temperature of 25° C. is 10⁸Ω/□ or more, a percentage of a delta haze value, that is provided by subtraction of a haze value after the immersion from a haze value before the immersion, with respect to the haze value before the immersion, is 0.4% or more, and the protective layer is not removed after the immersion;
etching liquid composition:

| | | |
|---|---|---|
| an ethylenediamine tetra acetic acid salt of iron | 2.5% | by mass |
| and ammonium | | |
| ammonium thiosulfate | 7.5% | by mass |
| ammonium sulfite | 2.5% | by mass |
| ammonium bisulfite | 2.5% | by mass |
| and water | up to 85% | by mass. |

10. The conductive member according to claim 1, wherein the conductive layer comprises a conductive region and a nonconductive region, and at least the conductive region comprises the metallic nanowire.

11. The conductive member according to claim 1, wherein a ratio of a surface resistivity of the conductive layer (Ω/□) after an abrasion treatment to a surface resistivity of the conductive layer (Ω/□) before an abrasion treatment is 100 or less, the abrasion treatment being performed with a continuous loading scratching intensity tester in a round trip of 50 times on the surface of the protective layer by using a 20 mm×20 mm-sized gauze piece with a load of 500 g thereon.

12. The conductive member according to claim 1, wherein a ratio of a surface resistivity (Ω/□) of the conductive layer after a bending treatment to a surface resistivity (Ω/□) of the conductive layer before a bending treatment is 2 or less, the bending treatment being performed with a cylindrical mandrel bending tester to wind the conductive member 20 times onto a cylindrical mandrel having a diameter of 10 mm.

13. A production method of the conductive member according to claim 1, the method comprising:
(a) forming, on the base material, the conductive layer comprising a metallic nanowire having an average short-axis length of 150 nm or less and a matrix;
(b) forming, on the conductive layer, a liquid film of an aqueous solution by applying an aqueous solution comprising a partial condensate product obtained by hydrolysis and condensation of at least one alkoxide compound of an element selected from the group consisting of Si, Ti, Zr and Al; and
(c) forming a protective layer comprising a three-dimensional crosslinked structure represented by Formula (I) obtained by hydrolysis and condensation of the alkoxide compound in the liquid film of the aqueous solution.

14. The production method according to claim 13, further comprising drying the protective layer by heating after the process of (c).

15. The production method according to claim 13, wherein the matrix is a cured product of a photopolymerizable composition or a sol-gel cured product obtained by hydrolysis and condensation of at least one alkoxide compound of an element selected from the group consisting of Si, Ti, Zr and Al.

16. The production method according to claim 13, wherein the alkoxide compound in the process (b) comprises at least one selected from the group consisting of a compound represented by the following Formula (II) and a compound represented by the following Formula (III),
M²(OR¹)₄ Formula (II):
M³(OR²)ₐR³₄₋ₐ Formula (III):
wherein, in Formula (II), M² represents an element selected from the group consisting of Si, Ti and Zr, and each of a plurality of R¹ independently represents a hydrogen atom or a hydrocarbon group, and, in Formula (III), M³ represents an element selected from the group consisting of Si, Ti and Zr, and each of a plurality of R² and each of a plurality of R³ independently represents a hydrogen atom or a hydrocarbon group, and “a” represents an integer from 1 to 3.

17. The production method according to claim 16, wherein the alkoxide compound in the process (b) comprises (i) at least one selected from the compound represented by Formula (II), and (ii) at least one selected from the compound represented by Formula (III).

18. The production method according to claim 17, wherein a mass ratio of the compound (ii) to the compound (i) (the compound (ii)/the compound (i)) is in a range of from 0.01/1 to 100/1.

19. The production method according to claim 16, wherein both of M² in Formula (II) and M³ in Formula (III) are Si.

20. The production method according to claim 13, wherein a weight average molecular weight of the partial condensate product is in a range of from 4,000 to 90,000.

21. The production method according to claim 13, further comprising forming, in the conductive layer, a conductive region and a nonconductive region during the process (a) and the process (b).

22. A touch panel comprising the conductive member according to claim 1.

23. A solar cell comprising the conductive member according to claim 1.

24. The conductive member according to claim 2, wherein the protective layer comprises a sol-gel cured product obtained by hydrolysis and condensation of at least one alkoxide compound of an element selected from the group consisting of Si, Ti, Zr and Al.

25. The conductive member according to claim 24, wherein the alkoxide compound in the protective layer comprises at least one selected from the group consisting of a compound represented by the following Formula (II) and a compound represented by the following Formula (III),
M²(OR¹)₄ Formula (II):
M³(OR²)ₐR³₄₋ₐ Formula (III):
wherein, in Formula (II), M² represents an element selected from the group consisting of Si, Ti and Zr, and each of a plurality of R¹ independently represents a hydrogen atom or a hydrocarbon group, and, in Formula (III), M³ represents an element selected from the group consisting of Si, Ti and Zr, and each of a plurality of R² and each of a plurality of R³ independently represents a hydrogen atom or a hydrocarbon group, and “a” represents an integer from 1 to 3.

26. The conductive member according to claim 25, wherein the alkoxide compound in the protective layer comprises (i) at least one of the compound represented by Formula (II), and (ii) at least one of the compound represented by Formula (III).

27. The conductive member according to claim 26, wherein a mass ratio of the compound (ii) to the compound (i) (the compound (ii)/the compound (i)) is in a range of from 0.01/1 to 100/1.

28. The conductive member according to claim 27, wherein both of M² in Formula (II) and M³ in Formula (III) are Si.

29. The conductive member according to claim 28, wherein the metallic nanowire is a silver nanowire.

30. The conductive member according to claim 29, wherein the surface resistivity of the conductive member after immersion for 120 seconds in an etching liquid having the following composition at a temperature of 25° C. is 10⁸Ω/□ or more, a percentage of a delta haze value, that is provided by subtraction of a haze value after the immersion from a haze value before the immersion, with respect to the haze value before the immersion, is 0.4% or more, and the protective layer is not removed after the immersion;
etching liquid composition:

| | | |
|---|---|---|
| an ethylenediamine tetra acetic acid salt of iron and | 2.5% | by mass |
| ammonium | | |
| ammonium thiosulfate | 7.5% | by mass |
| ammonium sulfite | 2.5% | by mass |
| ammonium bisulfite | 2.5% | by mass |
| and water | 85% | by mass. |

31. The conductive member according to claim 30, wherein the conductive layer comprises a conductive region and a nonconductive region, and at least the conductive region comprises the metallic nanowire; a ratio of a surface resistivity of the conductive layer (Ω/□) after an abrasion treatment to a surface resistivity of the conductive layer (Ω/□) before an abrasion treatment is 100 or less, the abrasion treatment being performed with a continuous loading scratching intensity tester in a round trip of 50 times on the surface of the protective layer by using a 20 mm×20 mm-sized gauze piece with a load of 500 g thereon; and a ratio of a surface resistivity (Ω/□) of the conductive layer after a bending treatment to a surface resistivity (Ω/□) of the conductive layer before a bending treatment is 2 or less, the bending treatment being performed with a cylindrical mandrel bending tester to wind the conductive member 20 times onto a cylindrical mandrel having a diameter of 10 mm.
